(19) United States
(12) Patent Application Publication
(10) Pub. No.: US 2023/0232707 A1
(43) Pub. Date: Jul. 20, 2023

(54) LIGHT-EMITTING DEVICE, DISPLAY APPARATUS, ELECTRONIC DEVICE, LIGHT-EMITTING APPARATUS, AND LIGHTING DEVICE

(71) Applicant: SEMICONDUCTOR ENERGY LABORATORY CO., LTD., Atsugi-shi (JP)

(72) Inventors: Takeyoshi WATABE, Atsugi (JP); Takuya ISHIMOTO, Isehara (JP); Nobuharu OHSAWA, Zama (JP)

(21) Appl. No.: 18/150,264

(22) Filed: Jan. 5, 2023

(30) Foreign Application Priority Data
Jan. 14, 2022 (JP) 2022-004270

(51) Int. Cl. H10K 85/60; H10K 50/19; H10K 85/30

(52) U.S. Cl. CPC H10K 85/633; H10K 50/19; H10K 85/636; H10K 85/6576; H10K 85/657; H10K 85/6572; H10K 85/615; H10K 85/342; H10K 85/626; H10K 85/654; H10K 85/371; H10K 50/11

(57) ABSTRACT

A novel display apparatus that is highly convenient, useful, or reliable is provided. The display apparatus includes a first electrode, a second electrode, a first unit, a second unit, and a first intermediate layer; the first unit is located between the second electrode and the first electrode; and the first unit contains a first light-emitting material EM1. The second unit is located between the second electrode and the first unit and contains a second light-emitting material EM2. The first intermediate layer is located between the second unit and the first unit. The first intermediate layer includes a first layer and a second layer; the first layer is located between the second unit and the second layer; the first layer contains an organic compound having a halogen group or a cyano group or a transition metal oxide; and the second layer contains a first organic compound AM2 having an electron-accepting property, a second organic compound DM having an electron-donating property, and a third organic compound BM having basicity.

### BACKGROUND OF THE INVENTION

### 1. Field of the Invention

One embodiment of the present invention relates to a light-emitting device, a display apparatus, an electronic device, a light-emitting apparatus, a lighting device, or a semiconductor device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a light-emitting apparatus, a power storage device, a memory device, a driving method thereof, and a manufacturing method thereof.

### 2. Description of the Related Art

As an organic thin film with an excellent electron-injection property and electron-transport property when used as an electron-injection layer of an organic EL element, for example, a single film containing a hexahydropyrimidopyrimidine compound and a second material transporting an electron, and a stacked film of a film containing a hexahydropyrimidopyrimidine compound and a film containing the second material are known (Patent Document 1).

### REFERENCE

### Patent Document

[Patent Document 1] PCT International Publication No. WO2021/045178

### SUMMARY OF THE INVENTION

An object of one embodiment of the present invention is to provide a novel light-emitting device that is highly convenient, useful, or reliable. Another object is to provide a novel display apparatus that is highly convenient, useful, or reliable. Another object is to provide a novel electronic device that is highly convenient, useful, or reliable. Another object is to provide a novel light-emitting apparatus that is highly convenient, useful, or reliable. Another object is to provide a novel lighting device that is highly convenient, useful, or reliable. Another object is to provide a novel light-emitting device, a novel display apparatus, a novel electronic device, a novel light-emitting apparatus, a novel lighting device, or a novel semiconductor device.

Note that the description of these objects does not preclude the existence of other objects. One embodiment of the present invention does not need to achieve all these objects. Other objects will be apparent from and can be derived from the descriptions of the specification, the drawings, the claims, and the like.

(1) One embodiment of the present invention is a light-emitting device including a first electrode, a second electrode, a first unit, a second unit, and a first intermediate layer.

The first unit is located between the second electrode and the first electrode, and the first unit contains a first light-emitting material EM1. The second unit is located between the second electrode and the first unit and contains a second light-emitting material EM2.

The first intermediate layer is located between the second unit and the first unit. The first intermediate layer includes a first layer and a second layer, and the first layer is located between the second unit and the second layer.

The first layer contains an organic compound having a halogen group or a cyano group or a transition metal oxide.

The second layer contains a first organic compound AM2, a second organic compound DM, and a third organic compound BM.

The first organic compound AM2 has the lowest unoccupied molecular orbital level in a range higher than or equal to −3.5 eV and lower than or equal to −2.0 eV. The second organic compound DM has the highest occupied molecular orbital level in a range higher than or equal to −5.0 eV and lower than or equal to −4.0 eV. The third organic compound BM has an acid dissociation constant pKa higher than or equal to 1 and lower than or equal to 30.

(2) Another embodiment of the present invention is a light-emitting device including a first electrode, a second electrode, a first unit, a second unit, and a first intermediate layer.

The first unit is located between the second electrode and the first electrode, and the first unit contains the first light-emitting material EM1. The second unit is located between the second electrode and the first unit and contains the second light-emitting material EM2.

The first intermediate layer is located between the second unit and the first unit. The first intermediate layer includes a first layer and a second layer, and the first layer is located between the second unit and the second layer.

The first layer contains an organic compound having a halogen group or a cyano group or a transition metal oxide.

The second layer contains the first organic compound AM2, the second organic compound DM, and the third organic compound BM.

The first organic compound AM2 has the lowest unoccupied molecular orbital level in a range higher than or equal to −3.5 eV and lower than or equal to −2.0 eV. The second organic compound DM has the highest occupied molecular orbital level in a range higher than or equal to −5.0 eV and lower than or equal to −4.0 eV. The third organic compound BM has a structure represented by General Formula (G0) below.

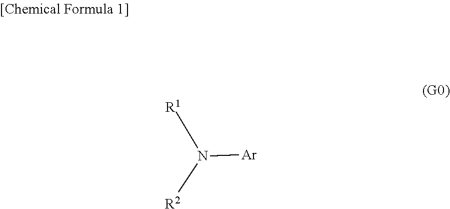

Note that in General Formula (G0) above, Ar represents a substituted or unsubstituted heteroaryl group containing nitrogen; R¹ and R² each independently represent a substituted or unsubstituted alkyl group having 1 to 12 carbon atoms, a substituted or unsubstituted cycloalkyl group having 3 to 12 carbon atoms, or a substituted or unsubstituted aliphatic amine having 1 to 12 carbon atoms; and R¹ and R² may be bonded to each other to form a hetero ring.

(3) One embodiment of the present invention is the above-described light-emitting device, in which the third organic compound BM has the structure represented by General Formula (G0) below.

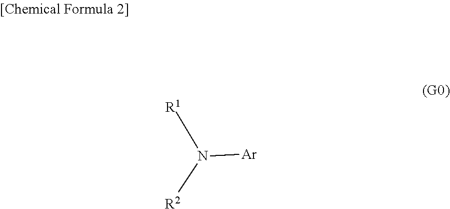

Note that in General Formula (G0) above, Ar has a phenanthroline skeleton or a pyridine skeleton.

(4) One embodiment of the present invention is the above-described light-emitting device, in which the third organic compound BM has the structure represented by General Formula (G0) below.

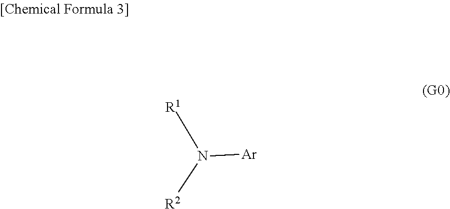

Note that in General Formula (G0) above, R¹ and R² are bonded to each other to form a pyrrolidine skeleton, a piperidine skeleton, or a hexahydropyrimidopyrimidine group.

(5) One embodiment of the present invention is the above-described light-emitting device, in which the second organic compound DM has a dihydroimidazole group or a tetrahydroimidazole group.

Therefore, the first intermediate layer can supply holes to the second unit and supply electrons to the first unit. Furthermore, the first intermediate layer can be formed without a substance with high activity such as an alkali metal or an alkaline earth metal. In addition, the resistance to the air or an impurity such as water can be increased. Moreover, the current efficiency in light emission can be increased. As a result, a novel light-emitting device that is highly convenient, useful, or reliable can be provided.

(6) One embodiment of the present invention is the above-described light-emitting device, in which the second layer includes a third layer and a fourth layer, and the fourth layer is located between the first layer and the third layer.

The third layer contains the first organic compound AM2 and the second organic compound DM, and the fourth layer contains the third organic compound BM.

(7) One embodiment of the present invention is the above-described light-emitting device, in which the second layer includes the third layer and the fourth layer, and the fourth layer is located between the first layer and the third layer

The third layer contains the third organic compound BM, and the fourth layer contains the first organic compound AM2 and the second organic compound DM.

(8) One embodiment of the present invention is the above-described light-emitting device, in which the first layer includes a fifth layer, and the fifth layer is located between the first layer and the second layer.

The fifth layer contains an electron-transport material.

(9) Another embodiment of the present invention is a display apparatus including a first light-emitting device and a second light-emitting device.

The first light-emitting device has the above-described structure, and the first layer contains an organic compound having a halogen group or a cyano group or a transition metal oxide.

The second light-emitting device is adjacent to the first light-emitting device, and the second light-emitting device includes a third electrode, a fourth electrode, and a second intermediate layer. A space is provided between the third electrode and the first electrode.

The second intermediate layer is located between the fourth electrode and the third electrode. The second intermediate layer includes a sixth layer and a seventh layer, and the sixth layer is located between the fourth electrode and the seventh layer.

The sixth layer contains an organic compound having a halogen group or a cyano group or a transition metal oxide. A first region that is thinner than the first layer is provided between the sixth layer and the first layer, and the first region overlaps with the space.

(10) One embodiment of the present invention is the above-described light-emitting apparatus, in which the second layer contains the first organic compound AM2, the second organic compound DM, and the third organic compound BM, and the seventh layer contains the first organic compound AM2, the second organic compound DM, and the third organic compound BM.

A second region that is thinner than the second layer is provided between the seventh layer and the second layer, and the second region overlaps with the space.

Therefore, for example, a current flowing through the first region can be inhibited. Furthermore, a current flowing between the first intermediate layer and the second intermediate layer can be inhibited. In addition, a phenomenon where the second light-emitting device that is adjacent to the first light-emitting device unintentionally emits light with the operation of the first light-emitting device can be inhibited. As a result, a novel display device that is highly convenient, useful, or reliable can be provided.

(11) One embodiment of the present invention is a display apparatus including the above-described light-emitting device and a transistor or a substrate.

(12) Another embodiment of the present invention is an electronic device including the above-described display apparatus, and a sensor, an operation button, a speaker, or a microphone.

(13) Another embodiment of the present invention is a light-emitting apparatus including the above-described light-emitting device and a transistor or a substrate.

(14) Another embodiment of the present invention is a lighting device including the above-described light-emitting apparatus and a housing.

Although the block diagram in drawings attached to this specification shows components classified based on their functions in independent blocks, it is difficult to classify actual components based on their functions completely, and one component can have a plurality of functions.

Note that the light-emitting apparatus in this specification includes, in its category, an image display device that uses a light-emitting device. The light-emitting apparatus may also include a module in which a light-emitting device is provided with a connector such as an anisotropic conductive film or a tape carrier package (TCP), a module in which a printed wiring board is provided at the end of a TCP, and a module in which an integrated circuit (IC) is directly mounted on a light-emitting device by a chip on glass (COG) method. Furthermore, a lighting apparatus or the like may include the light-emitting apparatus.

In this specification and the like, a device formed using a metal mask or a fine metal mask (FMM) is sometimes referred to as a device having a metal mask (MM) structure. In this specification and the like, a device formed without using a metal mask or an FMM may be referred to as a device having a metal maskless (MML) structure.

With one embodiment of the present invention, a novel light-emitting device that is highly convenient, useful, or reliable can be provided. Another embodiment of the present invention can provide a novel display apparatus that is highly convenient, useful, or reliable. Another embodiment of the present invention can provide a novel electronic device that is highly convenient, useful, or reliable. Another embodiment of the present invention can provide a novel light-emitting apparatus that is highly convenient, useful, or reliable. Another embodiment of the present invention can provide a novel lighting device that is highly convenient, useful, or reliable. Another embodiment of the present invention can provide a novel light-emitting device. A novel display apparatus can be provided. A novel electronic device can be provided. A novel light-emitting apparatus can be provided. A novel lighting device can be provided.

Note that the description of these effects does not preclude the existence of other effects. One embodiment of the present invention does not necessarily have all these effects. Other effects will be apparent from and can be derived from the descriptions of the specification, the drawings, the claims, and the like.

### BRIEF DESCRIPTION OF THE DRAWINGS

In the accompanying drawings:

FIGS. 1A and 1B show a structure of a light-emitting device of an embodiment;

FIGS. 2A and 2B illustrate structures of a light-emitting device of an embodiment;

FIG. 3 illustrates a structure of a display apparatus of an embodiment;

FIG. 4 illustrates a structure of a display apparatus of an embodiment;

FIGS. 5A to 5C illustrate a structure of an apparatus of one embodiment of the present invention;

FIG. 6 is a circuit diagram illustrating a structure of an apparatus of one embodiment of the present invention;

FIGS. 7A to 7C illustrate structures of an apparatus of one embodiment of the present invention;

FIGS. 8A and 8B illustrate an active matrix light-emitting apparatus of an embodiment;

FIGS. 9A and 9B illustrate active matrix light-emitting apparatuses of an embodiment;

FIG. 10 illustrates an active matrix light-emitting apparatus of an embodiment;

FIGS. 11A and 11B illustrate a passive matrix light-emitting apparatus of an embodiment;

FIGS. 12A and 12B illustrate a lighting device of an embodiment;

FIGS. 13A to 13D illustrate electronic devices of an embodiment;

FIGS. 14A to 14C illustrate electronic devices of an embodiment;

FIG. 15 illustrates a lighting device of an embodiment;

FIG. 16 illustrates a lighting device of an embodiment;

FIG. 17 illustrates in-vehicle display apparatuses and lighting devices of an embodiment;

FIGS. 18A to 18C illustrate an electronic device of an embodiment;

FIGS. 19A and 19B illustrate structures of a light-emitting device of an example;

FIG. 20 shows current density-luminance characteristics of light-emitting devices of an example;

FIG. 21 shows luminance-current efficiency characteristics of light-emitting devices of an example;

FIG. 22 shows voltage-luminance characteristics of light-emitting devices of an example;

FIG. 23 shows voltage-current characteristics of light-emitting devices of an example;

FIG. 24 shows emission spectra of light-emitting devices of an example;

FIG. 25 shows a change in normalized luminance over time of light-emitting devices of an example;

FIG. 26 shows current density-luminance characteristics of a light-emitting device of an example;

FIG. 27 shows luminance-current efficiency characteristics of a light-emitting device of an example;

FIG. 28 shows voltage-luminance characteristics of a light-emitting device of an example;

FIG. 29 shows voltage-current characteristics of a light-emitting device of an example; and

FIG. 30 shows an emission spectrum of a light-emitting device of an example.

### DETAILED DESCRIPTION OF THE INVENTION

A light-emitting device of one embodiment of the present invention includes the first electrode, the second electrode, the first unit, the second unit, and the first intermediate layer, and the first unit is located between the second electrode and the first electrode and contains the first light-emitting material EM1. The second unit is located between the second electrode and the first unit, and the second unit contains the second light-emitting material EM2. The first intermediate layer is located between the second unit and the first unit. The first intermediate layer includes the first layer and the second layer; the first layer is located between the second unit and the second layer; the first layer contains an organic compound having a halogen group or a cyano group or a transition metal oxide; the second layer contains the first organic compound AM2, the second organic compound DM, and the third organic compound BM. The first organic compound AM2 has the lowest unoccupied molecular orbital level in a range higher than or equal to −3.5 eV and lower than or equal to −2.0 eV; the second organic compound DM has the highest occupied molecular orbital level in a range higher than or equal to −5.0 eV and lower than or equal to −4.0 eV; and the third organic compound BM has an acid dissociation constant pKa higher than or equal to 1 and lower than or equal to 30.

Therefore, the first intermediate layer can supply holes to the second unit and supply electrons to the first unit. Furthermore, the first intermediate layer can be formed without a substance with high activity such as an alkali metal or an alkaline earth metal. In addition, the resistance to the air or an impurity such as water can be increased. Moreover, the current efficiency in light emission can be increased. As a result, a novel light-emitting device that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

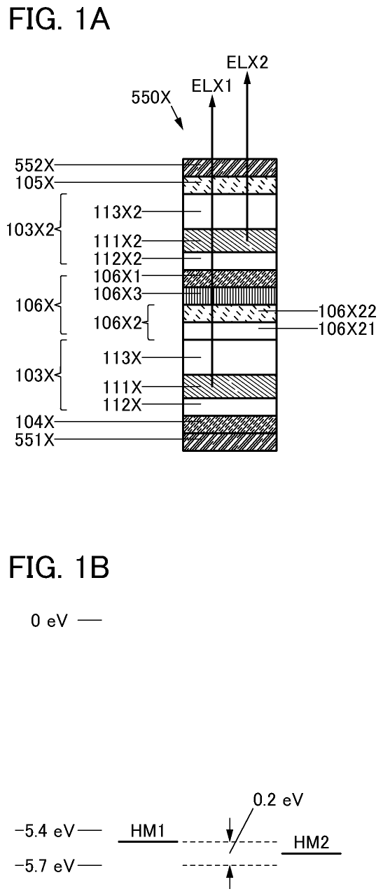

In this embodiment, a structure of a light-emitting device 550X of one embodiment of the present invention is described with reference to FIGS. 1A and 1B.

FIG. 1A is a cross-sectional view illustrating a structure of the light-emitting device 550X of one embodiment of the present invention. FIG. 1B shows a material used for the light-emitting device 550X of one embodiment of the present invention.

<Structure Example of Light-Emitting Device 550X>

The light-emitting device 550X described in this embodiment includes an electrode 551X, an electrode 552X, a unit 103X, a unit 103X2, and an intermediate layer 106X (see FIG. 1A).

The unit 103X is located between the electrode 552X and the electrode 551X and contains a light-emitting material EM1.

The unit 103X2 is located between the electrode 552X and the unit 103X and contains a light-emitting material EM2.

The intermediate layer 106X is located between the unit 103X2 and the unit 103X.

<<Structure Example of Intermediate Layer 106X>>

The intermediate layer 106X has a function of supplying electrons to the anode side and supplying holes to the cathode side when voltage is applied. The intermediate layer 106X can be referred to as a charge-generation layer.

The intermediate layer 106X includes a layer 106X1 and a layer 106X2, and the layer 106X1 is located between the unit 103X2 and the layer 106X2.

<<Structure Example 1 of Layer 106X1>>

For example, a material having a hole mobility lower than or equal to 1×10⁻³ cm²/Vs when the square root of the electric field strength [V/cm] is 600 can be used for the layer 106X1. A film having an electrical resistivity greater than or equal to 1×10⁴ [Ω·cm] and less than or equal to 1×10⁷ [Ω·cm] can be used as the layer 106X1. The electrical resistivity of the layer 106X1 is preferably greater than or equal to 5×10⁴ [Ω·cm] and less than or equal to 1×10⁷ [Ω·cm], further preferably greater than or equal to 1×10⁵ [Ω·cm] and less than or equal to 1×10⁷ [Ω·cm].

Specifically, an electron-accepting substance AM1 can be used for the layer 106X1.

[Electron-Accepting Substance AM1]

An organic compound or an inorganic compound can be used as the electron-accepting substance AM1. The electron-accepting substance AM1 can extract electrons from an adjacent hole-transport layer or a hole-transport material by the application of an electric field.

For example, a compound having an electron-withdrawing group (a halogen group or a cyano group) can be used for the electron-accepting substance AM1. An electron-accepting organic compound is easily evaporated, which facilitates film deposition. Thus, the productivity of the light-emitting device 550X can be increased.

Specifically, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylene-1,3,4,5,6,8,9,10-octafluoro-7H-pyren-2-ylidene)malononitrile, or the like can be used.

A compound in which electron-withdrawing groups are bonded to a condensed aromatic ring having a plurality of heteroatoms, such as HAT-CN, is particularly preferable because it is thermally stable.

A [3] radialene derivative having an electron-withdrawing group (in particular, a cyano group or a halogen group such as a fluoro group) has a very high electron-accepting property and thus is preferred.

Specifically, α,α′, α″-1,2,3-cyclopropanetriylidenetris[4-cyano-2,3,5,6-tetrafluorobenzeneacetonitrile], α,α′, α″-1,2,3-cyclopropanetriylidenetris[2,6-dichloro-3,5-difluoro-4-(trifluoromethyl)benzeneacetonitrile], α,α′, α″-1,2,3-cyclopropanetriylidenetris[2,3,4,5,6-pentafluorobenzeneacetonitrile], or the like can be used.

For the electron-accepting substance AM1, a transition metal oxide such as a molybdenum oxide, a vanadium oxide, a ruthenium oxide, a tungsten oxide, or a manganese oxide can be used.

It is possible to use any of the following materials: phthalocyanine-based complex compounds such as phthalocyanine (abbreviation: H₂Pc) and copper phthalocyanine (abbreviation: CuPc); and compounds each having an aromatic amine skeleton such as 4,4′-bis[N-(4-diphenylaminophenyl)-N-phenylamino]biphenyl (abbreviation: DPAB) and N,N′-bis[4-bis(3-methylphenyl)aminophenyl]-N,N′-diphenyl-4,4′-diaminobiphenyl (abbreviation: DNTPD).

In addition, high molecular compounds such as poly(3,4-ethylenedioxythiophene)/poly(styrenesulfonic acid) (abbreviation: PEDOT/PSS), and the like can be used.

[Structure Example 1 of Composite Material]

For example, a composite material containing an electron-accepting substance AM1 and a hole-transport material can be used for the layer 106X1.

For the hole-transport material in the composite material, for example, a compound having an aromatic amine skeleton, a carbazole derivative, an aromatic hydrocarbon, an aromatic hydrocarbon having a vinyl group, or a high molecular compound (such as an oligomer, a dendrimer, or a polymer) can be used. A material having a hole mobility of 1×10⁻⁶ cm²/Vs or higher can be suitably used as the hole-transport material in the composite material. For example, a hole-transport material that can be used for a layer 112X, which will be described in Embodiment 2, can be used for the composite material.

A substance having a relatively deep HOMO level can be suitably used for the hole-transport material in the composite material. Specifically, the HOMO level is preferably higher than or equal to −5.7 eV and lower than or equal to −5.4 eV. Accordingly, hole injection to the unit 103X2 can be facilitated. The reliability of the light-emitting device 550X can be increased.

As the compound having an aromatic amine skeleton, for example, N,N-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N-bis[4-bis(3-methylphenyl)aminophenyl]-N,N′-diphenyl-4,4′-diaminobiphenyl (abbreviation: DNTPD), or 1,3,5-tris[N-(4-diphenylaminophenyl)-N-phenylamino]benzene (abbreviation: DPA3B) can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), or 1,4-bis[4-(N-carbazolyl)phenyl]-2,3,5,6-tetraphenylbenzene can be used.

As the aromatic hydrocarbon, for example, 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, or coronene can be used.

As the aromatic hydrocarbon having a vinyl group, for example, 4,4′-bis(2,2-diphenylvinyl)biphenyl (abbreviation: DPVBi) or 9,10-bis[4-(2,2-diphenylvinyl)phenyl]anthracene (abbreviation: DPVPA) can be used.

As the high molecular compound, for example, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide](abbreviation: PTPDMA), or poly[N,N′-bis(4-butylphenyl)-N,N′-bis(phenyl)benzidine](abbreviation: Poly-TPD) can be used.

Furthermore, a substance having any of a carbazole skeleton, a dibenzofuran skeleton, a dibenzothiophene skeleton, and an anthracene skeleton can be suitably used as the hole-transport material in the composite material, for example. Moreover, a substance including any of the following can be used as the hole-transport material in the composite material: an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With the use of a substance having an N,N-bis(4-biphenyl)amino group, the reliability of the light-emitting device 550X can be increased.

Examples of these material include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6; 1′-binaphthyl-2-yl)triphenylamine (abbreviation: BBAαNβNB), 4,4′-diphenyl-4″-(7; 1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6; 2′-binaphthyl-2-yl)triphenylamine (abbreviation: BBA(βN2)B), 4,4′-diphenyl-4″-(7; 2′-binaphthyl-2-yl)triphenylamine (abbreviation: BBA(βN2)B-03), 4,4′-diphenyl-4″-(4; 2′-binaphthyl-1-yl)triphenylamine (abbreviation: BBAβNαNB), 4,4′-diphenyl-4″-(5; 2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi(9H-fluoren)-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(4-biphenyl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBAlBP), 4,4′-diphenyl-4″-(9-phenyl-9H-carbazol-3-yl)triphenylamine (abbreviation: PCBBilBP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

[Structure Example 2 of Composite Material]

For example, a composite material containing the electron-accepting substance AM1, a hole-transport material, and a fluoride of an alkali metal or a fluoride of an alkaline earth metal can be used. In particular, a composite material in which the proportion of fluorine atoms is higher than or equal to 20% can be suitably used. Thus, the refractive index of the layer 106X1 can be reduced. Alternatively, a layer with a low refractive index can be formed inside the light-emitting device 550X. Alternatively, the external quantum efficiency of the light-emitting device 550X can be improved.

<<Structure Example 1 of Layer 106X2>>

The layer 106X2 contains an electron-accepting organic compound AM2, an electron-donating organic compound DM, and a basic organic compound BM.

[Electron-Accepting Organic Compound AM2]

For example, the organic compound AM2 having the lowest unoccupied molecular orbital (LUMO) level in a range higher than or equal to −3.5 eV and lower than or equal to −2.0 eV, preferably lower than or equal to −2.5 eV, can be used for the layer 106X2.

Specifically, 2,9-di(naphthalen-2-yl)-4,7-diphenyl-1,10-phenanthroline (abbreviation: NBPhen), 4,7-diphenyl-1,10-phenanthroline (abbreviation: BPhen), 2,9-dimethyl-4,7-diphenyl-1,10-phenanthroline (abbreviation: BCP), 2,2′-(1,3-phenylene)bis(9-phenyl-1,10-phenanthroline) (abbreviation: mPPhen2P), 2-[3-(2,6-dimethyl-3-pyridinyl)-5-(9-phenanthrenyl)phenyl]-4,6-diphenyl-1,3,5-triazine (abbreviation: mPn-mDMePyPTzn), 2,2′-(pyridine-2,6-diyl)bis(4,6-diphenylpyrimidine) (abbreviation: 2,6(P2Pm)2Py), 2,2′-(pyridine-2,6-diyl)bis[4-(4-(2-naphthyl)phenyl)-6-phenylpyrimidine](abbreviation: 2,6(NP-PPm)2Py), 2,2′-(pyridine-2,6-diyl)bis(4-phenylbenzo[h]quinazoline) (abbreviation: 2,6(P-Bqn)2Py), 2,4-bis[4-(1-naphthyl)phenyl]-6-[4-(3-pyridyl)phenyl]pyrimidine (abbreviation: 2,4NP-6PyPPm), or the like can be used for the layer 106X2.

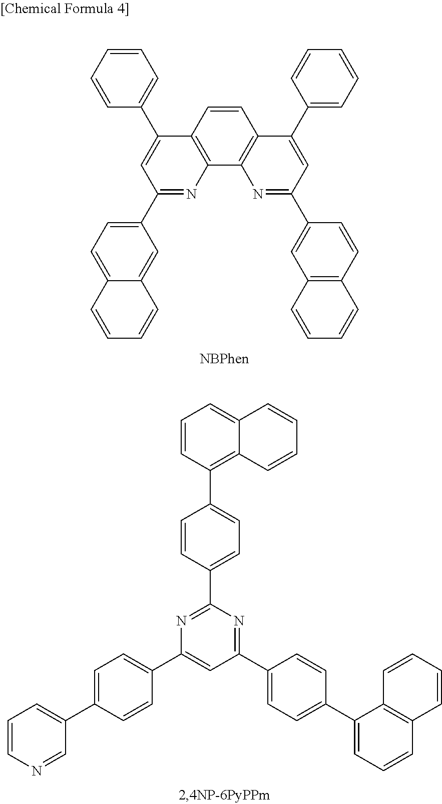 [SMILES: c1ccc(-c2cc(-c3ccc4ccccc4c3)nc3c2ccc2c(-c4ccccc4)cc(-c4ccc5ccccc5c4)nc23)cc1 ; c1cncc(-c2ccc(-c3cc(-c4ccc(-c5cccc6ccccc56)cc4)nc(-c4ccc(-c5cccc6ccccc56)cc4)n3)cc2)c1]

[Electron-Donating Organic Compound DM]

For example, the organic compound DM having the highest occupied molecular orbital (HOMO) level in a range higher than or equal to −5.0 eV and lower than or equal to −4.0 eV can be used for the layer 106X2. Specifically, an organic compound having a dihydroimidazole group or a tetrahydroimidazole group can be used as the organic compound DM. The organic compound DM has the highest occupied molecular orbital (HOMO) level in a range higher than or equal to −5.0 eV and lower than or equal to −4.0 eV, and thus oxidation can be inhibited. In addition, an electron-donating property can be exhibited. Therefore, the organic compound DM can exhibit an electron-donating property with oxidation inhibited. For example, the organic compound DM can have a smaller quality change, which is derived from a device manufacturing process, than an alkali metal such as lithium. Furthermore, work in process is easily handled in the device manufacturing process. In addition, a process performed in the air can be employed for the device manufacturing process.

Specifically, 4-(1,3-dimethyl-2,3-dihydro-1H-benzimidazol-2-yl)-N,N-diphenylaniline (abbreviation: TPABzi), 4-(1,3-dimethyl-2H-benzimidazol-2-yl)-N,N-dimethylaniline (abbreviation: N-DMBI), 4,4′, 5,5′-tetracyclohexyl-1,1′,2,2′, 3,3′-hexamethyl-2,2′,3,3′-tetrahydro-2,2′-biimidazole (abbreviation: Bisch2Dhim), or the like can be used for the layer 106X2.

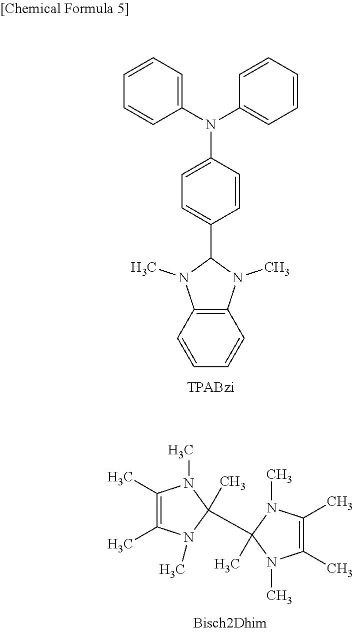

[Basic Organic Compound BM]

For example, the basic organic compound BM can be used for the layer 106X2. Specifically, an organic compound having an acid dissociation constant pKa higher than or equal to 1 and lower than or equal to 30, preferably higher than or equal to 5 and lower than or equal to 30, can be used as the organic compound BM. Therefore, the electron-donating property of the organic compound DM can be complemented. Furthermore, the electron-donating property of the organic compound DM with respect to the organic compound AM2 is increased by interaction between the basic organic compound BM and the organic compound DM. Moreover, charge separation easily occurs in the layer 106X2.

Accordingly, the intermediate layer 106X can function as a charge-generation layer without a material containing an alkali metal or an alkaline earth metal that is easily oxidized. Therefore, one embodiment of the present invention is a light-emitting device that does not contain, in the intermediate layer 106X, a material containing an alkali metal or an alkaline earth metal. Furthermore, one embodiment of the present invention is a light-emitting device that does not contain a material containing a metal in the layer 106X2.

For example, the basic organic compound BM has a structure represented by General Formula (G0) below.

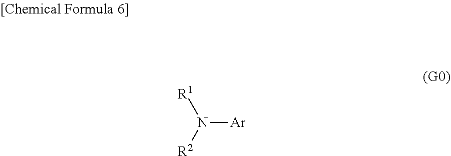

[Example of Ar]

In General Formula (G0) above, Ar represents a substituted or unsubstituted heteroaryl group containing nitrogen.

For example, any of substituents (Ar-1 to Ar-7) with structures shown below can be used as Ar. Specifically, a substituent having a pyridine skeleton (Ar-1), a pyrimidine skeleton (Ar-2), a pyrazine skeleton (Ar-3), a triazine skeleton (Ar-4), a bipyridine skeleton (Ar-5), a terpyridine skeleton (Ar-6), a phenanthroline skeleton (Ar-7), or the like can be used as Ar. Note that asterisks in structural formulae each represent a bond.

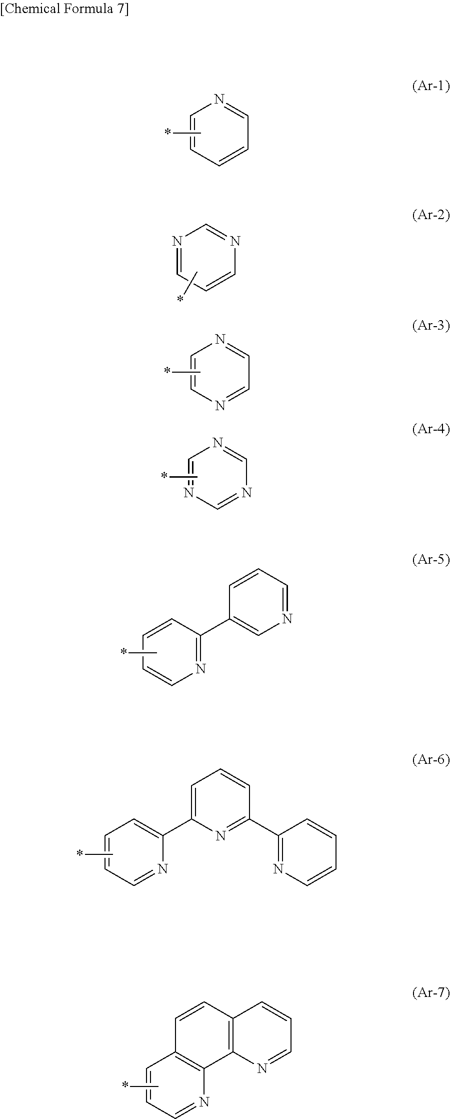

Note that as the substituent included in the heteroaryl group containing nitrogen, for example, an alkyl group having 1 to 4 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 2 to 30 carbon atoms can be used.

Examples of the alkyl group include a methyl group, an ethyl group, a propyl group, an isopropyl group, a butyl group, an isobutyl group, a tert-butyl group, and an n-hexyl group. Examples of the cycloalkyl group include a cyclopropyl group, a cyclobutyl group, a cyclopentyl group, a cyclohexyl group, and an adamantyl group.

As an aryl group included in the heteroaryl group containing nitrogen, a substituted or unsubstituted aromatic hydrocarbon group having 6 to 30 carbon atoms can be used, and examples thereof include a phenyl group, a naphthyl group, a biphenyl group, a fluorenyl group, and a spirofluorenyl group.

As a heteroaryl group included in the heteroaryl group containing nitrogen, a substituted or unsubstituted heteroaromatic ring having 1 to 30 carbon atoms can be used. Examples include a pyridine ring, a diazine ring (a pyrimidine ring, a pyrazine ring, or a pyridazine ring), a triazine ring, a quinoline ring, a quinoxaline ring, a quinazoline ring, a benzoquinazoline ring, a phenanthroline ring, an azafluoranthene ring, an imidazole ring, an oxazole ring, an oxadiazole ring, and a triazole ring.

[Example of R¹ and R²]

In General Formula (G0) above, R¹ and R² each independently represent a substituted or unsubstituted alkyl group having 1 to 12 carbon atoms, a substituted or unsubstituted cycloalkyl group having 3 to 12 carbon atoms, or a substituted or unsubstituted aliphatic amine having 1 to 12 carbon atoms.

For example, a skeleton (R-1) represents the case where a methyl group is used for each of R¹ and R², a skeleton (R-2) represents the case where an ethyl group is used for each of R¹ and R², and a skeleton (R-3) represents the case where an ethyl group and a propyl group are used. A skeleton (R-4) represents the case where an aminomethyl group and a propyl group are used, and a skeleton (R-5) represents the case where an aminoethyl group and an ethyl group are used.

Furthermore, R¹ and R² may be bonded to each other to form a hetero ring. Specifically, a pyrrolidine skeleton (R-2), a piperidine skeleton (R-3), a hydropyrimidine skeleton (R-4), a piperazine skeleton (R-5), or the like may be formed.

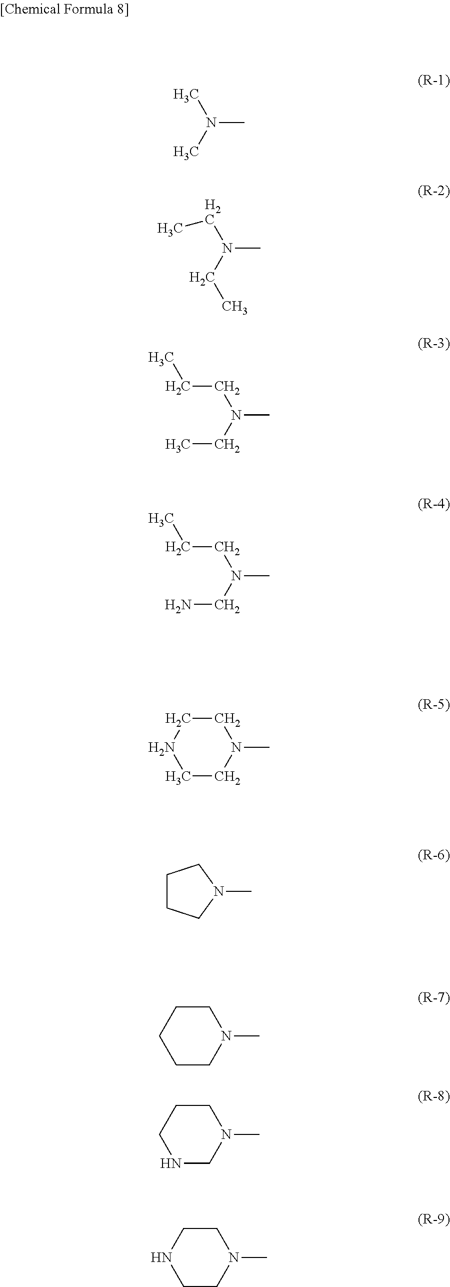

Note that as a substituent included in the hetero ring, for example, an alkyl group having 1 to 4 carbon atoms, a substituted or unsubstituted cycloalkyl group having 3 to 10 carbon atoms, an aliphatic amine having 1 to 4 carbon atoms, or an amine having a carbon-nitrogen double bond and 1 to 4 carbon atoms can be used.

Examples of the alkyl group include a methyl group, an ethyl group, a propyl group, an isopropyl group, a butyl group, an isobutyl group, a tert-butyl group, and an n-hexyl group. Examples of the cycloalkyl group include a cyclopropyl group, a cyclobutyl group, a cyclopentyl group, a cyclohexyl group, and an adamantyl group.

The hetero ring may have two or more substituents, and the two substituents included in the hetero ring may be bonded to each other to form a ring.

Specifically, the two substituents included in the hetero ring may be bonded to each other to form a spiro skeleton (a substituent (R-6)). Furthermore, the two substituents included in the hetero ring may share two elements of the hetero ring to form a plurality of rings. Specifically, an octahydroquinoline group (R-7), a hydrobenzo[de]quinoline group (R-8), and a 2,3,4,6,7,8-hexahydropyrimido[1,2-α]pyrimidine group (R-9) may be formed.

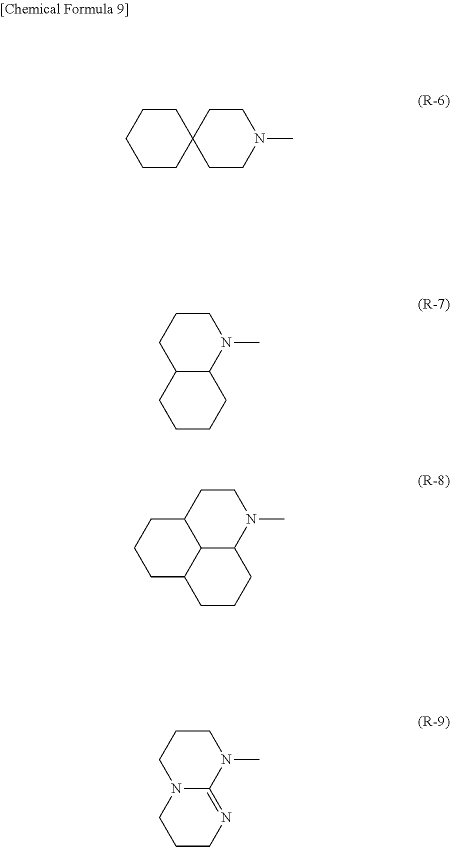

Therefore, the intermediate layer 106X can supply holes to the unit 103X2 and supply electrons to the unit 103X. Furthermore, the intermediate layer 106X can be formed without a substance with high activity such as an alkali metal or an alkaline earth metal. In addition, the resistance to the air or an impurity such as water can be increased. Moreover, the current efficiency in light emission can be increased. As a result, a novel light-emitting device that is highly convenient, useful, or reliable can be provided.

Specifically, 4,7-di-1-pyrrolidinyl-1,10-phenanthroline (abbreviation: Pyrrd-Phen), 1,1′-pyridine-2,6-diyl-bis(1,3,4,6,7,8-hexahydro-2H-pyrimido[1,2-α]pyrimidine) (abbreviation: hpp2Py), or the like can be used for the layer 106X2. Furthermore, an organic compound (BM-1 or BM-2) can be used for the layer 106X2.

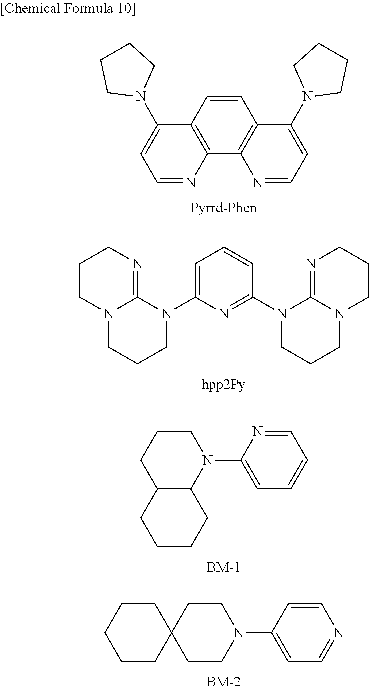 [SMILES: c1cc(N2CCCC2)c2ccc3c(N4CCCC4)ccnc3c2n1 ; c1cc(N2CCCN3CCCN=C32)nc(N2CCCN3CCCN=C32)c1 ; c1ccc(N2CCCC3CCCCC32)nc1 ; c1cc(N2CCC3(CCCCC3)CC2)ccn1]

Note that, for example, 1,2,3,4,6,7,8,9-octahydropyrimido[1,2-α]pyrimidin-5-ium (abbreviation: TBD) and 1-methyl-3,4,6,7,8,9-hexahydro-2H-pyrimido[1,2-α]pyrimidin-1-ium (abbreviation: MTBD) are each an organic compound having a 2,3,4,6,7,8-hexahydropyrimido[1,2-α]pyrimidine group, and the acid dissociation constant pKa is 15. Furthermore, hpp2Py also has a 2,3,4,6,7,8-hexahydropyrimido[1,2-α]pyrimidine group, so that the acid dissociation constant pKa can be estimated to be approximately 15.

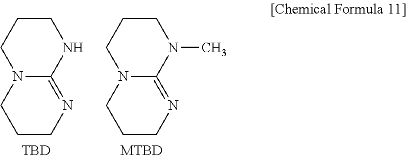

<<Structure Example 2 of Layer 106X2>>

The layer 106X2 includes a layer 106X21 and a layer 106X22, and the layer 106X22 is located between the layer 106X1 and the layer 106X21 (see FIG. 1A).

The layer 106X21 contains the electron-accepting organic compound AM2 and the electron-donating organic compound DM, and the layer 106X22 contains the basic organic compound BM.

<<Structure Example 3 of Layer 106X2>>

The layer 106X2 includes the layer 106X21 and the layer 106X22, and the layer 106X22 is located between the layer 106X1 and the layer 106X21 (see FIG. 1A).

The layer 106X21 contains the basic organic compound BM, and the layer 106X22 contains the electron-accepting organic compound AM2 and the electron-donating organic compound DM.

<<Structure Example 2 of Intermediate Layer 106X>>

The intermediate layer 106X includes a layer 106X3 that is located between the layer 106X1 and the layer 106X2 (see FIG. 1A).

The layer 106X3 contains an electron-transport material.

<<Structure Example of Layer 106X3>>

The layer 106X3 can be referred to as an electron-relay layer. With the layer 106X3, a layer that is on the anode side and in contact with the layer 106X3 can be distanced from a layer that is on the cathode side and in contact with the layer 106X3. Interaction between the layer that is on the anode side and in contact with the layer 106X3 and the layer that is on the cathode side and in contact with the layer 106X3 can be reduced. Electrons can be smoothly supplied to the layer that is on the anode side and in contact with the layer 106X3.

A substance whose LUMO level is between the LUMO level of the electron-accepting substance AM1 contained in the layer that is on the cathode side and in contact with the layer 106X3 and the LUMO level of the substance contained in the layer that is on the anode side and in contact with the layer 106X3 can be suitably used for the layer 106X3.

For example, a material having a LUMO level in a range higher than or equal to −5.0 eV, preferably higher than or equal to −5.0 eV and lower than or equal to −3.0 eV, can be used for the layer 106X3.

Specifically, a phthalocyanine-based material can be used for the layer 106X3. For example, copper phthalocyanine (abbreviation: CuPc) or a metal complex having a metal-oxygen bond and an aromatic ligand can be used for the layer 106X3.

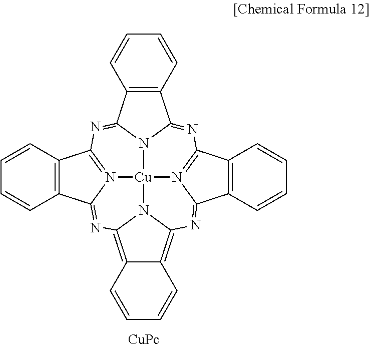

Note that this embodiment can be combined with any of the other embodiments in this specification as appropriate.

### Embodiment 2

In this embodiment, the structure of the light-emitting device 550X of one embodiment of the present invention is described with reference to FIGS. 1A and 1B.

<Structure Example 1 of Light-Emitting Device 550X>

The light-emitting device 550X described in this embodiment includes the electrode 551X, the electrode 552X, the unit 103X, the unit 103X2, and the intermediate layer 106X (see FIG. 1A).

The unit 103X is located between the electrode 552X and the electrode 551X and contains the light-emitting material EM1. The unit 103X has a function of emitting light ELX1. Although FIG. 1A illustrates an example where the light ELX1 is emitted through the electrode 552X, the light ELX1 may be emitted through the electrode 551X.

The unit 103X2 is located between the electrode 552X and the unit 103X and contains the light-emitting material EM2. The unit 103X2 has a function of emitting light ELX2.

In other words, the light-emitting device 550X includes the stacked units between the electrode 551X and the electrode 552X. The number of stacked units is not limited to two and may be three or more. A structure including the stacked units located between the electrode 551X and the electrode 552X and the intermediate layer 106X located between the units is referred to as a stacked light-emitting device or a tandem light-emitting device in some cases.

This structure enables high luminance emission while the current density is kept low. Reliability can be improved. The driving voltage can be reduced in comparison with that of the light-emitting device with the same luminance. The power consumption can be reduced.

<<Structure Example of Unit 103X>>

The unit 103X has a single-layer structure or a stacked-layer structure. The unit 103X includes a layer 111X, the layer 112X, and a layer 113X, for example (see FIG. 1A). The layer 111X is placed between the layer 112X and the layer 113X.

For example, a layer selected from functional layers such as a light-emitting layer, a hole-transport layer, an electron-transport layer, and a carrier-blocking layer can be used for the unit 103X. A layer selected from functional layers such as a hole-injection layer, an electron-injection layer, an exciton-blocking layer, and a charge-generation layer can also be used for the unit 103X.

<<Structure Example of Layer 112X>>

A hole-transport material can be used for the layer 112X, for example. The layer 112X can be referred to as a hole-transport layer. A material having a wider bandgap than the light-emitting material contained in the layer 111X is preferably used for the layer 112X. In that case, transfer of energy from excitons generated in the layer 111X to the layer 112X can be inhibited.

[Hole-Transport Material]

A material having a hole mobility of 1×10⁻⁶ cm²/Vs or higher can be suitably used as the hole-transport material.

As the hole-transport material, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. The compound having an aromatic amine skeleton and the compound having a carbazole skeleton are particularly preferable because these compounds are highly reliable and have high hole-transport properties to contribute to a reduction in driving voltage.

The following are examples that can be used as a compound having an aromatic amine skeleton: 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP) can be used.

As a compound having a thiophene skeleton, for example, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV) can be used.

As a compound having a furan skeleton, for example, 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II) can be used.

<<Structure Example of Layer 113X>>

An electron-transport material, a material having an anthracene skeleton, and a mixed material can be used for the layer 113X, for example. The layer 113X can be referred to as an electron-transport layer. A material having a wider bandgap than the light-emitting material contained in the layer 111X is preferably used for the layer 113X. In that case, energy transfer from excitons generated in the layer 111X to the layer 113X can be inhibited.

[Electron-Transport Material]

For example, a material having an electron mobility higher than or equal to 1×10⁻⁷ cm²/Vs and lower than or equal to 5×10⁻⁵ cm²/Vs when the square root of the electric field strength [V/cm] is 600 can be suitably used as the electron-transport material. In this case, the electron-transport property in the electron-transport layer can be suppressed. The amount of electrons injected into the light-emitting layer can be controlled. The light-emitting layer can be prevented from having excess electrons.

For example, a metal complex or an organic compound having a π-electron deficient heteroaromatic ring skeleton can be used as the electron-transport material.

As a metal complex, bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ) can be used, for example.

As an organic compound having a π-electron deficient heteroaromatic ring skeleton, a heterocyclic compound having a polyazole skeleton, a heterocyclic compound having a diazine skeleton, a heterocyclic compound having a pyridine skeleton, a heterocyclic compound having a triazine skeleton, or the like can be used, for example. In particular, the heterocyclic compound having a diazine skeleton or the heterocyclic compound having a pyridine skeleton has favorable reliability and thus is preferable. In addition, the heterocyclic compound having a diazine (pyrimidine or pyrazine) skeleton has a high electron-transport property to contribute to a reduction in driving voltage.

As a heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II) can be used, for example.

As a heterocyclic compound having a diazine skeleton, 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 4,8-bis[3-(dibenzothiophen-4-yl)phenyl]benzo[h]quinazoline (abbreviation: 4,8mDBtP2Bqn) can be used, for example.

As a heterocyclic compound having a pyridine skeleton, 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB) can be used, for example.

As a heterocyclic compound having a triazine skeleton, 2-[3′-(9,9-dimethyl-9H-fluoren-2-yl)biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), or 2-{3-[3-(benzo[b]naphtho[1,2-d]furan-6-yl)phenyl]phenyl}-4,6-diphenyl-1,3,5-triazine (abbreviation: mBnfBPTzn-02) can be used, for example.

[Material Having Anthracene Skeleton]

An organic compound having an anthracene skeleton can be used for the layer 113X. In particular, an organic compound having both an anthracene skeleton and a heterocyclic skeleton can preferably be used.

For example, an organic compound having both an anthracene skeleton and a nitrogen-containing five-membered ring skeleton can be used for the layer 113X. Alternatively, an organic compound having both an anthracene skeleton and a nitrogen-containing five-membered ring skeleton where two heteroatoms are included in a ring can be used for the layer 113X. Specifically, it is preferable to use, as the heterocyclic skeleton, a pyrazole ring, an imidazole ring, an oxazole ring, a thiazole ring, or the like.

For example, an organic compound having both an anthracene skeleton and a nitrogen-containing six-membered ring skeleton can be used for the layer 113X. Alternatively, an organic compound having both an anthracene skeleton and a nitrogen-containing six-membered ring skeleton where two heteroatoms are included in a ring can be used for the layer 113X. Specifically, it is preferable to use, as the heterocyclic skeleton, a pyrazine ring, a pyrimidine ring, a pyridazine ring, or the like.

[Structure Example of Mixed Material]

A material in which a plurality of kinds of substances are mixed can be used for the layer 113X. Specifically, a mixed material which contains an alkali metal, an alkali metal compound, or an alkali metal complex and an electron-transport substance can be used for the layer 113X. Note that the electron-transport material preferably has a HOMO level of −6.0 eV or higher.

The mixed material can be suitably used for the layer 113X in combination with a structure using a composite material, which is separately described, for a layer 104X. For example, a composite material of an electron-accepting substance and a hole-transport material can be used for the layer 104X. Specifically, a composite material of an electron-accepting substance and a substance having a relatively deep HOMO level HM1, which is higher than or equal to −5.7 eV and lower than or equal to −5.4 eV, can be used for the layer 104X (see FIG. 1B). Using the mixed material for the layer 113X in combination with the structure using such a composite material for the layer 104X leads to an increase in the reliability of the light-emitting device.

Furthermore, a structure using a hole-transport material for the layer 112X is preferably combined with the structure using the mixed material for the layer 113X and the composite material for the layer 104X. For example, a substance having a HOMO level HM2, which differs by −0.2 eV to 0 eV from the relatively deep HOMO level HMI1, can be used for the layer 112X (see FIG. 1B). This leads to an increase in the reliability of the light-emitting device. Note that in this specification and the like, the structure of the above-described light-emitting device may be referred to as a Recombination-Site Tailoring Injection structure (ReSTI structure).

The concentration of the alkali metal, the alkali metal compound, or the alkali metal complex preferably changes in the thickness direction of the layer 113X (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used.

As the metal complex having an 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

<<Structure Example 1 of Layer 111X>>

For example, a light-emitting material or a light-emitting material and a host material can be used for the layer 111X. The layer 111X can be referred to as a light-emitting layer. The layer 111X is preferably provided in a region where holes and electrons are recombined. This allows efficient conversion of energy generated by recombination of carriers into light and emission of the light.

Furthermore, the layer 111X is preferably provided apart from a metal used for the electrode or the like. In that case, a quenching phenomenon caused by the metal used for the electrode or the like can be inhibited.

It is preferable that a distance from an electrode or the like having reflectivity to the layer 111X be adjusted and the layer 111X be placed in an appropriate position in accordance with an emission wavelength. With this structure, the amplitude can be increased by utilizing an interference phenomenon between light reflected by the electrode or the like and light emitted from the layer 111X. Light with a predetermined wavelength can be intensified and the spectrum of the light can be narrowed. In addition, bright light emission colors with high intensity can be obtained. In other words, the layer 111X is placed in an appropriate position, for example, between electrodes and the like, and thus a microcavity structure can be formed.

For example, a fluorescent substance, a phosphorescent substance, or a substance exhibiting thermally activated delayed fluorescence (TADF) (also referred to as a TADF material) can be used for the light-emitting material. Thus, energy generated by recombination of carriers can be released as the light ELX1 from the light-emitting material (see FIG. 1A).

[Fluorescent Substance]

A fluorescent substance can be used for the layer 111X. For example, the following fluorescent substances can be used for the layer 111X. Note that fluorescent substances that can be used for the layer 111X are not limited to the following, and a variety of known fluorescent substances can be used.

Specifically, any of the following fluorescent substances can be used: 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N, 9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N′,N′-triphenyl-1,4-phenylenediamine](abbreviation: DPABPA), N, 9-diphenyl-N-[4-(9,10-diphenyl-2-anthryl)phenyl]-9H-carbazol-3-amine (abbreviation: 2PCAPPA), N,N-(pyrene-1,6-diyl)bis[(6,N-diphenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), 3,10-bis[N-(dibenzofuran-3-yl)-N-phenylamino]naphtho[2,3-b;6,7-b′]bisbenzofuran (abbreviation: 3,10FrA2Nbf(IV)-02), and the like.

Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

Other examples of fluorescent substances include N-[4-(9,10-diphenyl-2-anthryl)phenyl]-N,N′,N-triphenyl-1,4-phenylenediamine (abbreviation: 2DPAPPA), N,N,N,N,N″,N″,N″,N″-octaphenyldibenzo[g,p]chrysene-2,7,10,15-tetraamine (abbreviation: DBC1), coumarin 30, 9,10-diphenyl-2-[N-phenyl-N-(9-phenyl-carbazol-3-yl)-amino]-anthracene (abbreviation: 2PCAPA), N-[9,10-bis(1,1′-biphenyl-2-yl)-2-anthryl]-N, 9-diphenyl-9H-carbazol-3-amine (abbreviation: 2PCABPhA), N-(9,10-diphenyl-2-anthryl)-N,N,N′-triphenyl-1,4-phenylenediamine (abbreviation: 2DPAPA), N-[9,10-bis(1,1′-biphenyl-2-yl)-2-anthryl]-N,N,N-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracene-2-amine (abbreviation: 2YGABPhA), N,N, 9-triphenylanthracene-9-amine (abbreviation: DPhAPhA), coumarin 545T, N,N-diphenylquinacridone (abbreviation: DPQd), rubrene, and 5,12-bis(1,1′-biphenyl-4-yl)-6,11-diphenyltetracene (abbreviation: BPT).

Other examples of fluorescent substances include 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-α]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), and 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM).

[Phosphorescent Substance]

A phosphorescent substance can be used for the layer 111X. For example, phosphorescent substances described below as examples can be used for the layer 111X. Note that phosphorescent substances that can be used for the layer 111X are not limited to the following, and a variety of known phosphorescent substances can be used for the layer 111X.

For example, any of the following can be used for the layer 111X: an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, a platinum complex, and the like.

[Phosphorescent Substance (Blue)]

As an organometallic iridium complex having a 4H-triazole skeleton or the like, tris{2-[5-(2-methylphenyl)-4-(2,6-dimethylphenyl)-4H-1,2,4-triazol-3-yl-KN²]phenyl-KC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

As an organometallic iridium complex having a 1H-triazole skeleton or the like, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato]iridium(III) (abbreviation: [Ir(Prptz1-Me)₃]), or the like can be used.

As an organometallic iridium complex having an imidazole skeleton or the like, fac-tris[1-(2,6-diisopropylphenyl)-2-phenyl-1H-imidazole]iridium(III) (abbreviation: [Ir(iPrpmi)₃]), tris[3-(2,6-dimethylphenyl)-7-methylimidazo[1,2-f]phenanthridinato]iridium(III) (abbreviation: [Ir(dmpimpt-Me)₃]), or the like can be used.

As an organometallic iridium complex having a phenylpyridine derivative with an electron-withdrawing group as a ligand, or the like, bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²]iridium(III) picolinate (abbreviation: FIrpic), bis{2-[3′,5′-bis(trifluoromethyl)phenyl]pyridinato-N,C²′}iridium(III) picolinate (abbreviation: Ir(CF₃ppy)₂(pic)), bis[2-(4′,6′-difluorophenyl)pyridinato-N,C²′]iridium(III) acetylacetonate (abbreviation: FIracac), or the like can be used.

These substances are compounds exhibiting blue phosphorescent light and having an emission wavelength peak at 440 nm to 520 nm.

[Phosphorescent Substance (Green)]

As an organometallic iridium complex having a pyrimidine skeleton or the like, tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), or the like can be used.

As an organometallic iridium complex having a pyrazine skeleton or the like, (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), or the like can be used.

As an organometallic iridium complex having a pyridine skeleton or the like, tris(2-phenylpyridinato-N,C²)iridium(III) (abbreviation: [Ir(ppy)₃]), bis(2-phenylpyridinato-N,C²)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²)iridium(III) (abbreviation: [Ir(pq)₃]), bis(2-phenylquinolinato-N,C²)iridium(III) acetylacetonate (abbreviation: [Ir(pq)₂(acac)]), [2-d₃-methyl-8-(2-pyridinyl-cN)benzofuro[2,3-b]pyridine-KC]bis[2-(5-d₃-methyl-2-pyridinyl-KN²)phenyl-KC]iridium(III) (abbreviation: [Ir(5mppy-d₃)2(mbfpypy-d₃)]), [2-d₃-methyl-(2-pyridinyl-cN)benzofuro[2,3-b]pyridine-xC]bis[2-(2-pyridinyl-xN)phenyl-xC]iridium(III) (abbreviation: [Ir(ppy)2(mbfpypy-d3)]), or the like can be used.

Examples of a rare earth metal complex are tris(acetylacetonato) (monophenanthroline)terbium(III) (abbreviation: [Tb(acac)₃(Phen)]), and the like.

These are compounds that mainly exhibit green phosphorescent light and have an emission wavelength peak at 500 nm to 600 nm. Note that an organometallic iridium complex having a pyrimidine skeleton has distinctively high reliability or emission efficiency.

[Phosphorescent Substance (Red)]

As an organometallic iridium complex having a pyrimidine skeleton or the like, (diisobutyrylmethanato)bis [4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III) (abbreviation: [Ir(d1npm)₂(dpm)]), or the like can be used.

As an organometallic iridium complex having a pyrazine skeleton or the like, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), or the like can be used.

As an organometallic iridium complex having a pyridine skeleton or the like, tris(1-phenylisoquinolinato-N,C²′)iridium(III) (abbreviation: [Ir(piq)₃]), bis(1-phenylisoquinolinato-N,C²′)iridium(III) acetylacetonate (abbreviation: [Ir(piq)₂(acac)]), or the like can be used.

As a rare earth metal complex or the like, tris(1,3-diphenyl-1,3-propanedionato)(monophenanthroline)europium(III) (abbreviation: [Eu(DBM)3(Phen)]), tris[1-(2-thenoyl)-3,3,3-trifluoroacetonato](monophenanthroline)europium(III) (abbreviation: [Eu(TTA)3(Phen)]), or the like can be used.

As a platinum complex or the like, 2,3,7,8,12,13,17,18-octaethyl-21H, 23H-porphyrin platinum(II) (abbreviation: PtOEP) or the like can be used.

These compounds emit red phosphorescent light having an emission peak at 600 nm to 700 nm. Furthermore, the organometallic iridium complexes having a pyrazine skeleton can provide red light emission with chromaticity favorably used for display apparatuses.

[Substance Exhibiting Thermally Activated Delayed Fluorescence (TADF)]

A TADF material can be used for the layer 111X. When a TADF material is used as the light-emitting substance, the S1 level of the host material is preferably higher than that of the TADF material. In addition, the T1 level of the host material is preferably higher than that of the TADF material.

For example, any of the TADF materials enumerated below can be used as the light-emitting material. Note that without being limited thereto, a variety of known TADF materials can be used.

In the TADF material, the difference between the S1 level and the T1 level is small, and reverse intersystem crossing (upconversion) from the triplet excited state into the singlet excited state can be achieved by a small amount of thermal energy. Thus, the singlet excited state can be efficiently generated from the triplet excited state. In addition, the triplet excitation energy can be converted into luminescence.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used for the TADF material.

Specifically, the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

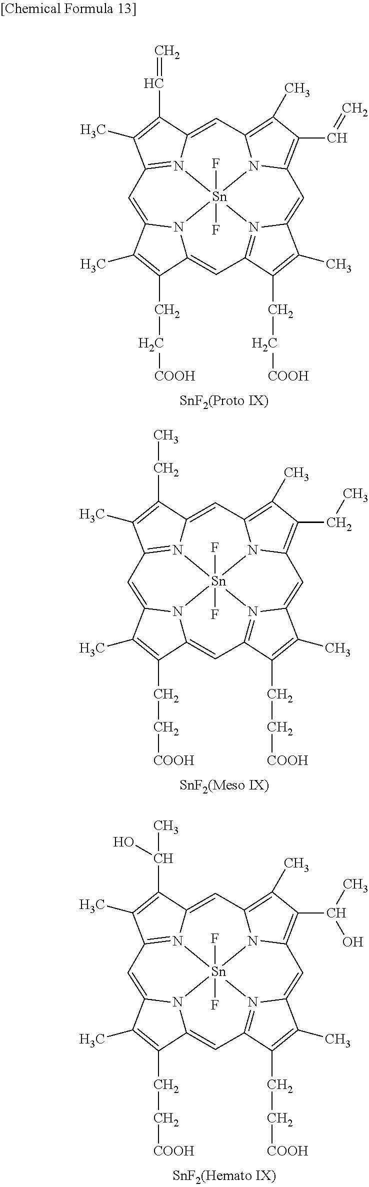

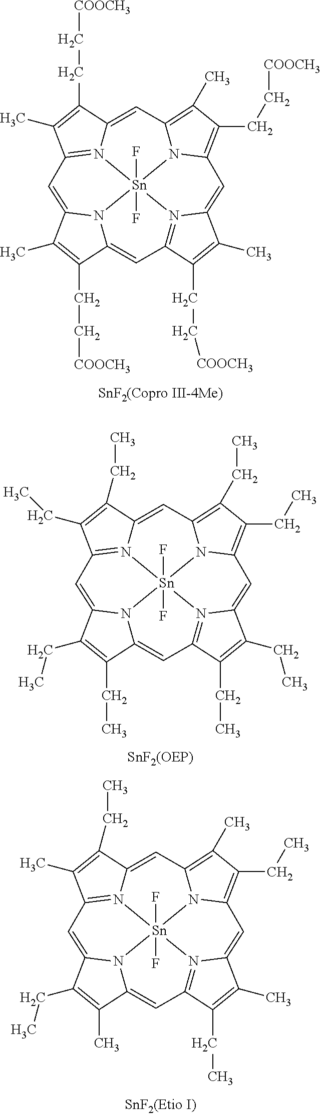

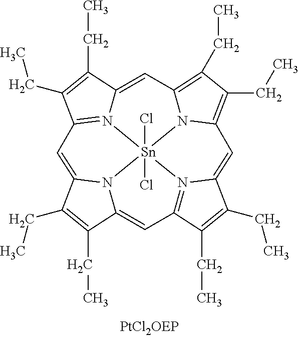

Furthermore, a heterocyclic compound including one or both of a 7r-electron rich heteroaromatic ring and a π-electron deficient heteroaromatic ring can be used, for example, as the TADF material.

Specifically, the following compounds whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H, 9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazine-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H, 10′H-spiro[acridin-9,9′-anthracen]-10′-one (abbreviation: ACRSA), and the like.

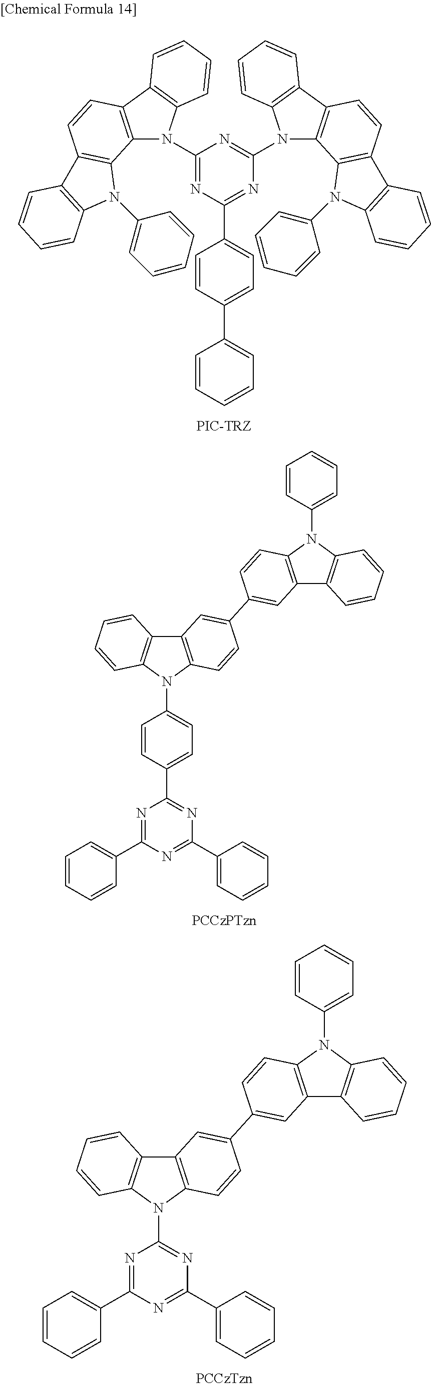 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

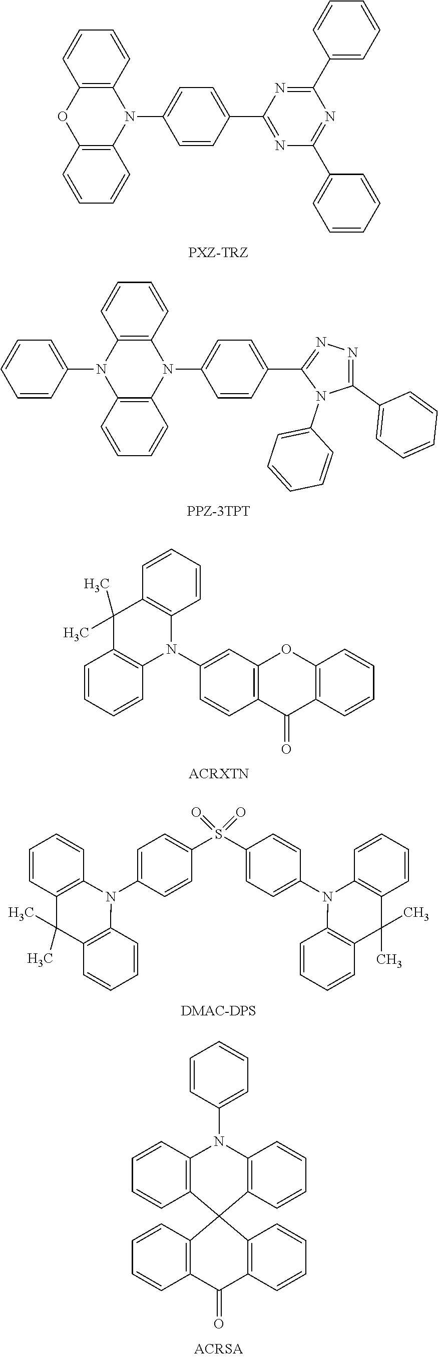 [SMILES: c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high electron-accepting properties and high reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane and boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the π-electron rich heteroaromatic ring.

<<Structure Example 2 of Layer 111X>>

A carrier-transport material can be used as the host material. For example, a hole-transport material, an electron-transport material, a substance exhibiting thermally activated delayed fluorescence (TADF), a material having an anthracene skeleton, or a mixed material can be used as the host material. A material having a wider bandgap than the light-emitting material contained in the layer 111X is preferably used as the host material. Thus, transfer of energy from excitons generated in the layer 111X to the host material can be inhibited.

[Hole-Transport Material]

A material having a hole mobility of 1×10⁻⁶ cm²/Vs or higher can be suitably used as the hole-transport material. For example, a hole-transport material that can be used for the layer 112X can be used for the host material.

[Electron-Transport Material]

A metal complex or an organic compound having a it-electron deficient heteroaromatic ring skeleton can be used as the electron-transport material. For example, an electron-transport material that can be used for the layer 113X can be used for the host material.

[Material Having Anthracene Skeleton]

An organic compound having an anthracene skeleton can be used as the host material. An organic compound having an anthracene skeleton is particularly preferable in the case where a fluorescent substance is used as a light-emitting substance. Thus, a light-emitting device with high emission efficiency and high durability can be obtained.

Among the organic compounds having an anthracene skeleton, an organic compound having a diphenylanthracene skeleton, in particular, a 9,10-diphenylanthracene skeleton, is chemically stable and thus is preferable. The host material preferably has a carbazole skeleton because the hole-injection and hole-transport properties are improved. In particular, the host material preferably has a dibenzocarbazole skeleton because the HOMO level thereof is shallower than that of carbazole by approximately 0.1 eV so that holes enter the host material easily, the hole-transport property is improved, and the heat resistance is increased. Note that in terms of the hole-injection and hole-transport properties, instead of a carbazole skeleton, a benzofluorene skeleton or a dibenzofluorene skeleton may be used.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferable as the host material.

Examples of the substances that can be used include 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), 9-(1-naphthyl)-10-[4-(2-naphthyl)phenyl]anthracene (abbreviation: aN-ONPAnth), 9-phenyl-3-[4-(10-phenyl-9-anthryl)phenyl]-9H-carbazole (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 3-[4-(1-naphthyl)-phenyl]-9-phenyl-9H-carbazole (abbreviation: PCPN), and the like.

In particular, CzPA, cgDBCzPA, 2mBnfPPA, and PCzPA have excellent characteristics.

[Substance Exhibiting Thermally Activated Delayed Fluorescence (TADF)]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than that of the fluorescent substance in order that high emission efficiency be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance; therefore, the TADF material and the luminophore of the fluorescent substance can be made away from each other with little influence on carrier transportation or carrier recombination.

Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, and a phenothiazine skeleton. In particular, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

For example, the TADF material that can be used as the light-emitting material can be used as the host material.

[Structure Example 1 of Mixed Material]

A material in which a plurality of kinds of substances are mixed can be used as the host material. For example, a material which includes an electron-transport material and a hole-transport material can be used as the mixed material. The weight ratio between the hole-transport material and the electron-transport material contained in the mixed material may be (the hole-transport material/the electron-transport material)=(1/19) or more and (19/1) or less. Thus, the carrier-transport property of the layer 111X can be easily adjusted and a recombination region can be easily controlled.

[Structure Example 2 of Mixed Material]

In addition, a material mixed with a phosphorescent substance can be used as the host material. When a fluorescent substance is used as the light-emitting substance, a phosphorescent substance can be used as an energy donor for supplying excitation energy to the fluorescent substance.

[Structure Example 3 of Mixed Material]

A mixed material containing a material to form an exciplex can be used as the host material. For example, a material in which an emission spectrum of a formed exciplex overlaps with a wavelength of the absorption band on the lowest energy side of the light-emitting substance can be used as the host material. This enables smooth energy transfer and improves emission efficiency. The driving voltage can be suppressed. With such a structure, light emission can be efficiently obtained by exciplex-triplet energy transfer (ExTET), which is energy transfer from the exciplex to the light-emitting substance (phosphorescent material).

A phosphorescent substance can be used as at least one of the materials forming an exciplex. Accordingly, reverse intersystem crossing can be used. Triplet excitation energy can be efficiently converted into singlet excitation energy.

Combination of an electron-transport material and a hole-transport material whose HOMO level is higher than or equal to that of the electron-transport material is preferable for forming an exciplex. The LUMO level of the hole-transport material is preferably higher than or equal to the LUMO level of the electron-transport material. Thus, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of the mixed film in which the hole-transport material and the electron-transport material are mixed is shifted to the longer wavelength side than the emission spectra of each of the materials (or has another peak on the longer wavelength side) observed by comparison of the emission spectra of the hole-transport material, the electron-transport material, and the mixed film of these materials, for example. Alternatively, the formation of an exciplex can be confirmed by a difference in transient response, such as a phenomenon in which the transient PL lifetime of the mixed film has longer lifetime components or a larger proportion of delayed components than that of each of the materials, observed by comparison of transient photoluminescence (PL) of the hole-transport material, the electron-transport material, and the mixed film of these materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of these materials.

<<Structure Example 1 of Unit 103X2>>

The unit 103X2 includes a layer 111X2, a layer 112X2, and a layer 113X2. The layer 111X2 is placed between the layer 112X2 and the layer 113X2.

The structure that can be employed for the unit 103X can be employed for the unit 103X2. For example, the same structure as the unit 103X can be employed for the unit 103X2.

<<Structure Example 2 of Unit 103X2>>

The structure that is different from the structure of the unit 103X can be employed for the unit 103X2. For example, the unit 103X2 can have a structure emitting light whose hue is different from that of light emitted from the unit 103X.

Specifically, a stack including the unit 103X emitting red light and green light and the unit 103X2 emitting blue light can be employed. With this structure, a light-emitting device emitting light of a desired color can be provided. A light-emitting device emitting white light can be provided, for example.

<Method for Fabricating Light-Emitting Device 550X>

For example, each of the electrode 551X, the electrode 552X, the unit 103X, the intermediate layer 106X, and the unit 103X2 can be formed by a dry process, a wet process, an evaporation method, a droplet discharging method, a coating method, a printing method, or the like. A formation method may differ between structures of the device.

Specifically, the light-emitting device 550X can be manufactured with a vacuum evaporation machine, an ink-jet machine, a coating machine such as a spin coater, a gravure printing machine, an offset printing machine, a screen printing machine, or the like.

For example, the electrode can be formed by a wet process or a sol-gel method using a paste of a metal material. In addition, an indium oxide-zinc oxide film can be formed by a sputtering method using a target obtained by adding indium zinc to indium oxide at a concentration higher than or equal to 1 wt % and lower than or equal to 20 wt %. Furthermore, an indium oxide film containing tungsten oxide and zinc oxide (IWZO) can be formed by a sputtering method using a target containing, with respect to indium oxide, tungsten oxide at a concentration higher than or equal to 0.5 wt % and lower than or equal to 5 wt % and zinc oxide at a concentration higher than or equal to 0.1 wt % and lower than or equal to 1 wt %.

Note that this embodiment can be combined with any of the other embodiments in this specification as appropriate.

### Embodiment 3

In this embodiment, the structure of the light-emitting device 550X of one embodiment of the present invention is described with reference to FIGS. 1A and 1B.

<Structure Example of Light-Emitting Device 550X>

The light-emitting device 550X described in this embodiment includes the electrode 551X, the electrode 552X, the unit 103X, the unit 103X2, and the intermediate layer 106X (see FIG. 1A). For example, the structures described in Embodiments 1 and 2 can be employed for the unit 103X, the unit 103X2, and the intermediate layer 106X.

The light-emitting device 550X includes the layer 104X, and the layer 104X is located between the electrode 551X and the unit 103X.

<<Structure Example of Electrode 551X>>

For example, a conductive material can be used for the electrode 551X. Specifically, a single layer or a stack using a metal, an alloy, or a film containing a conductive compound can be used for the electrode 551X.

A film that efficiently reflects light can be used for the electrode 551X, for example. Specifically, an alloy containing silver, copper, and the like, an alloy containing silver, palladium, and the like, or a metal film of aluminum or the like can be used for the electrode 551X.

For example, a metal film that transmits part of light and reflects another part of light can be used for the electrode 551X. Thus, a microcavity structure can be provided in the light-emitting device 550X. Alternatively, light with a predetermined wavelength can be extracted more efficiently than light with the other wavelengths. Alternatively, light with a narrow spectral half-width can be extracted. Alternatively, light of a bright color can be extracted.

A film having a visible-light-transmitting property can be used for the electrode 551X, for example. Specifically, a single layer or a stack using a metal film, an alloy film, a conductive oxide film, or the like that is thin enough to transmit light can be used for the electrode 551X.

In particular, a material having a work function higher than or equal to 4.0 eV can be suitably used for the electrode 551X.

For example, a conductive oxide containing indium can be used. Specifically, indium oxide, indium oxide-tin oxide (abbreviation: ITO), indium oxide-tin oxide containing silicon or silicon oxide (abbreviation: ITSO), indium oxide-zinc oxide, indium oxide containing tungsten oxide and zinc oxide (abbreviation: IWZO), or the like can be used.

For another example, a conductive oxide containing zinc can be used. Specifically, zinc oxide, zinc oxide to which gallium is added, zinc oxide to which aluminum is added, or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), or a nitride of a metal material (e.g., titanium nitride) can be used. Graphene can also be used.

<<Structure Example 1 of Layer 104X>>

A hole-injection material can be used for the layer 104X, for example. The layer 104X can be referred to as a hole-injection layer. This can facilitate the injection of holes from the electrode 551X, for example. Alternatively, the driving voltage of the light-emitting device 550X can be reduced.

[Electron-Accepting Substance]

An organic compound or an inorganic compound can be used as an electron-accepting substance. The electron-accepting substance can extract electrons from an adjacent hole-transport layer or a hole-transport material by the application of an electric field. For example, the electron-accepting substance AM1 that can be used for the layer 106X1 can be used of the layer 104X.

[Structure Example 1 of Composite Material]

For example, a composite material containing an electron-accepting substance and a hole-transport material can be used for the layer 104X. Accordingly, not only a material having a high work function but also a material having a low work function can also be used for the electrode 551X. Alternatively, a material used for the electrode 551X can be selected from a wide range of materials regardless of its work function.

For the hole-transport material in the composite material, for example, a compound having an aromatic amine skeleton, a carbazole derivative, an aromatic hydrocarbon, an aromatic hydrocarbon having a vinyl group, or a high molecular compound (such as an oligomer, a dendrimer, or a polymer) can be used. A material having a hole mobility of 1×10⁻⁶ cm²/Vs or higher can be suitably used as the hole-transport material in the composite material. For example, a hole-transport material that can be used for the layer 112X can be used for the composite material.

A substance having a relatively deep HOMO level can be suitably used for the hole-transport material in the composite material. Specifically, the HOMO level is preferably higher than or equal to −5.7 eV and lower than or equal to −5.4 eV. Accordingly, hole injection to the unit 103X can be facilitated. Hole injection to the layer 112X can be facilitated. The reliability of the light-emitting device 550X can be increased. For example, the composite material that can be used for the layer 106X1 can be used for the layer 104X.

[Structure Example 2 of Composite Material]

For example, a composite material containing an electron-accepting substance, a hole-transport material, and a fluoride of an alkali metal or a fluoride of an alkaline earth metal can be used as the hole-injection material. In particular, a composite material in which the proportion of fluorine atoms is higher than or equal to 20% can be suitably used. Thus, the refractive index of the layer 104X can be reduced. Alternatively, a layer with a low refractive index can be formed inside the light-emitting device 550X. Alternatively, the external quantum efficiency of the light-emitting device 550X can be improved.

Note that this embodiment can be combined with any of the other embodiments in this specification as appropriate.

### Embodiment 4

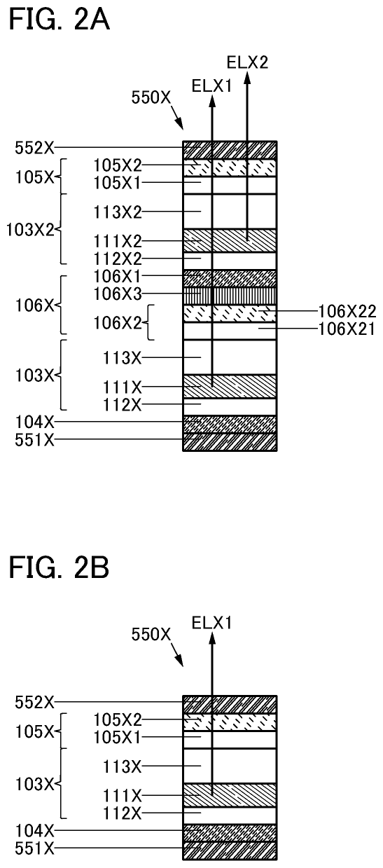

In this embodiment, the structure of the light-emitting device 550X of one embodiment of the present invention is described with reference to FIGS. 1A and 1B and FIGS. 2A and 2B.

FIG. 2A is a cross-sectional view illustrating a structure of the light-emitting device of one embodiment of the present invention. FIG. 2B is a cross-sectional view illustrating a structure of the light-emitting device of one embodiment of the present invention, which is different from that in FIG. 2A.

<Structure Example 1 of Light-Emitting Device 550X>

The light-emitting device 550X described in this embodiment includes the electrode 551X, the electrode 552X, the unit 103X, the unit 103X2, and the intermediate layer 106X (see FIG. 1A). For example, the structures described in Embodiments 1 and 2 can be employed for the unit 103X, the unit 103X2, and the intermediate layer 106X.

The light-emitting device 550X includes a layer 105X, and the layer 105X is located between the electrode 552X and the unit 103X2.

<<Structure Example of Electrode 552X>>

For example, a conductive material can be used for the electrode 552X. Specifically, a single layer or a stack using a metal, an alloy, or a film containing a conductive compound can be used for the electrode 552X.

For example, the material that can be used for the electrode 551X described in Embodiment 3 can be used for the electrode 552X. In particular, a material with a lower work function than the electrode 551X can be suitably used for the electrode 552X. Specifically, a material having a work function lower than or equal to 3.8 eV is preferably used.

For example, an element belonging to Group 1 of the periodic table, an element belonging to Group 2 of the periodic table, a rare earth metal, or an alloy containing any of these elements can be used for the electrode 552X.

Specifically, an element such as lithium (Li) or cesium (Cs), an element such as magnesium (Mg), calcium (Ca), or strontium (Sr), an element such as europium (Eu) or ytterbium (Yb), or an alloy containing any of these elements such as an alloy of magnesium and silver or an alloy of aluminum and lithium can be used for the electrode 552X.

<<Structure Example 1 of Layer 105X>>

An electron-injection material can be used for the layer 105X, for example. The layer 105X can be referred to as an electron-injection layer.

Specifically, an electron-donating substance can be used for the layer 105X. Alternatively, a material in which an electron-donating substance and an electron-transport material are combined can be used for the layer 105X. Alternatively, electride can be used for the layer 105X. This can facilitate the injection of electrons from the electrode 552X, for example. Alternatively, not only a material having a low work function but also a material having a high work function can also be used for the electrode 552X. Alternatively, a material used for the electrode 552X can be selected from a wide range of materials regardless of its work function. Specifically, Al, Ag, ITO, indium oxide-tin oxide containing silicon or silicon oxide, or the like can be used for the electrode 552X. Alternatively, the driving voltage of the light-emitting device 550X can be reduced.

[Electron-Donating Substance]

For example, an alkali metal, an alkaline earth metal, a rare earth metal, or a compound thereof (an oxide, a halide, a carbonate, or the like) can be used for the electron-donating substance. Alternatively, an organic compound such as tetrathianaphthacene (abbreviation: TTN), nickelocene, or decamethylnickelocene can be used for the electron-donating substance.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

[Structure Example 1 of Composite Material]

A material composed of two or more kinds of substances can be used as the electron-injection material. For example, an electron-donating substance and an electron-transport material can be used for the composite material.

[Electron-Transport Material]

For example, a material having an electron mobility higher than or equal to 1×10⁻⁷ cm²/Vs and lower than or equal to 5×10⁻⁵ cm²/Vs when the square root of the electric field strength [V/cm] is 600 can be suitably used as the electron-transport material. Therefore, the amount of electrons injected into the light-emitting layer can be controlled. Alternatively, the light-emitting layer can be prevented from having excess electrons.

A metal complex or an organic compound having a π-electron deficient heteroaromatic ring skeleton can be used as the electron-transport material. For example, an electron-transport material that can be used for the layer 113X can be used for the layer 105X.

[Structure Example 2 of Composite Material]

A material including a fluoride of an alkali metal in a microcrystalline state and an electron-transport material can be used for the composite material. Alternatively, a material including a fluoride of an alkaline earth metal in a microcrystalline state and an electron-transport material can be used for the composite material. In particular, a composite material including a fluoride of an alkali metal or an alkaline earth metal at 50 wt % or higher can be suitably used. Alternatively, a composite material including an organic compound having a bipyridine skeleton can be suitably used. Thus, the refractive index of the layer 105X can be reduced. The external quantum efficiency of the light-emitting device 550X can be improved.

[Structure Example 3 of Composite Material]

For example, a composite material of a first organic compound including an unshared electron pair and a first metal can be used for the layer 105X. The sum of the number of electrons of the first organic compound and the number of electrons of the first metal is preferably an odd number. The molar ratio of the first metal to 1 mol of the first organic compound is preferably greater than or equal to 0.1 and less than or equal to 10, more preferably greater than or equal to 0.2 and less than or equal to 2, further more preferably greater than or equal to 0.2 and less than or equal to 0.8.

Accordingly, the first organic compound including an unshared electron pair interacts with the first metal and thus can form a singly occupied molecular orbital (SOMO). Furthermore, in the case where electrons are injected from the electrode 552X into the layer 105X, a barrier therebetween can be reduced.

The layer 105X can adopt a composite material that allows the spin density measured by an electron spin resonance (ESR) method to be preferably greater than or equal to 1×10¹⁶ spins/cm³, more preferably greater than or equal to 5×10¹⁶ spins/cm³, further more preferably greater than or equal to 1×10¹⁷ spins/cm³.

[Organic Compound Including Unshared Electron Pair]

For example, an electron-transport material can be used for the organic compound including an unshared electron pair. For example, a compound having an electron deficient heteroaromatic ring can be used. Specifically, a compound with at least one of a pyridine ring, a diazine ring (a pyrimidine ring, a pyrazine ring, and a pyridazine ring), and a triazine ring can be used. Accordingly, the driving voltage of the light-emitting device 550X can be reduced.

Note that the lowest unoccupied molecular orbital (LUMO) level of the organic compound having an unshared electron pair is preferably higher than or equal to −3.6 eV and lower than or equal to −2.3 eV. In general, the HOMO level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a: 2′,3′-c]phenazine (abbreviation: HATNA), 2,4,6-tris[3′-(pyridin-3-yl)biphenyl-3-yl]-1,3,5-triazine (abbreviation: TmPPPyTz), 2,2′-(1,3-phenylene)bis(9-phenyl-1,10-phenanthroline) (abbreviation: mPPhen2P), or the like can be used as the organic compound having an unshared electron pair. Note that NBPhen has a higher glass transition point (Tg) than BPhen and thus has high heat resistance.

Alternatively, for example, copper phthalocyanine can be used for the organic compound including an unshared electron pair. The number of electrons of the copper phthalocyanine is an odd number.

[First Metal]

When the number of electrons of the first organic compound including an unshared electron pair is an even number, for example, a composite material of the first metal and the first organic compound, which belongs to an odd-numbered group in the periodic table, can be used for the layer 105X.

For example, manganese (Mn), which is a metal belonging to Group 7, cobalt (Co), which is a metal belonging to Group 9, copper (Cu), silver (Ag), and gold (Au), which are metals belonging to Group 11, aluminum (Al) and indium (In), which are metals belonging to Group 13 are odd-numbered groups in the periodic table. Note that elements belonging to Group 11 have a lower melting point than elements belonging to Group 7 or Group 9 and thus are suitable for vacuum evaporation. In particular, Ag is preferable because of its low melting point. When a metal having a low reactivity with water or oxygen is used as the first metal, the moisture resistance of the light-emitting device 550X can be improved.

The use of Ag for the electrode 552X and the layer 105X can increase the adhesion between the layer 105X and the electrode 552X.

When the number of electrons of the first organic compound including an unshared electron pair is an odd number, a composite material of the first metal and the first organic compound, which belongs to an even-numbered group in the periodic table, can be used for the layer 105X. For example, iron (Fe), which is a metal belonging to Group 8, is an element belonging to an even-numbered group in the periodic table.

[Electride]

For example, a substance obtained by adding electrons at high concentration to an oxide where calcium and aluminum are mixed can be used, for example, as the electron-injection material.

[Structure Example 4 of Composite Material]

A material composed of two or more kinds of substances can be used as the electron-injection material. For example, the electron-accepting organic compound AM2, the electron-donating organic compound DM, and the basic organic compound BM can be used for the composite material. Specifically, the structure that can be employed for the layer 106X2 described in Embodiment 1 can be used for the layer 105X.

<<Structure Example 2 of Layer 105X>>

For example, the layer 105X1 and the layer 105X2 can be used for the layer 105X (see FIG. 2A). The layer 105X2 is located between the electrode 552X and the layer 105X1.

The layer 105X1 contains the electron-accepting organic compound AM2 and the electron-donating organic compound DM, and the layer 105X2 contains the basic organic compound BM.

<<Structure Example 3 of Layer 105X>>

For example, the layer 105X1 and the layer 105X2 can be used for the layer 105X (see FIG. 2A). The layer 105X2 is located between the electrode 552X and the layer 105X1.

The layer 105X1 contains the basic organic compound BM, and the layer 105X2 contains the electron-accepting organic compound AM2 and the electron-donating organic compound DM.

<Structure Example 2 of Light-Emitting Device 550X>

The light-emitting device 550X described in this embodiment includes the electrode 551X, the electrode 552X, and the unit 103X (see FIG. 2B). The unit 103X is located between the electrode 551X and the electrode 552X. The light-emitting device 550X includes the layer 104X and the layer 105X, the layer 104X is located between the electrode 551X and the unit 103X, and the layer 105X is located between the electrode 552X and the unit 103X. Note that the light-emitting device 550X of one embodiment of the present invention described with reference to FIG. 2B does not include the intermediate layer 106X and the unit 103X2.

For example, the structure described in Embodiment 2 can be employed for the unit 103X. Furthermore, the structure described in Embodiment 3 can be employed for the electrode 551X and the layer 104X.

<<Structure Example 4 of Layer 105X>>

An electron-injection material can be used for the layer 105X, for example. A material composed of two or more kinds of substances can be used as the electron-injection material.

For example, the electron-accepting organic compound AM2, the electron-donating organic compound DM, and the basic organic compound BM can be used for the composite material. Specifically, the structure that can be employed for the layer 106X2 described in Embodiment 1 can be used for the layer 105X.

<<Structure Example 5 of Layer 105X>>

For example, the layer 105X1 and the layer 105X2 can be used for the layer 105X (see FIG. 2B). The layer 105X2 is located between the electrode 552X and the layer 105X1.

The layer 105X1 contains the electron-accepting organic compound AM2 and the electron-donating organic compound DM, and the layer 105X2 contains the basic organic compound BM.

<<Structure Example 6 of Layer 105X>>

For example, the layer 105X1 and the layer 105X2 can be used for the layer 105X (see FIG. 2B). The layer 105X2 is located between the electrode 552X and the layer 105X1.

The layer 105X1 contains the basic organic compound BM, and the layer 105X2 contains the electron-accepting organic compound AM2 and the electron-donating organic compound DM.

Note that this embodiment can be combined with any of the other embodiments in this specification as appropriate.

### Embodiment 5

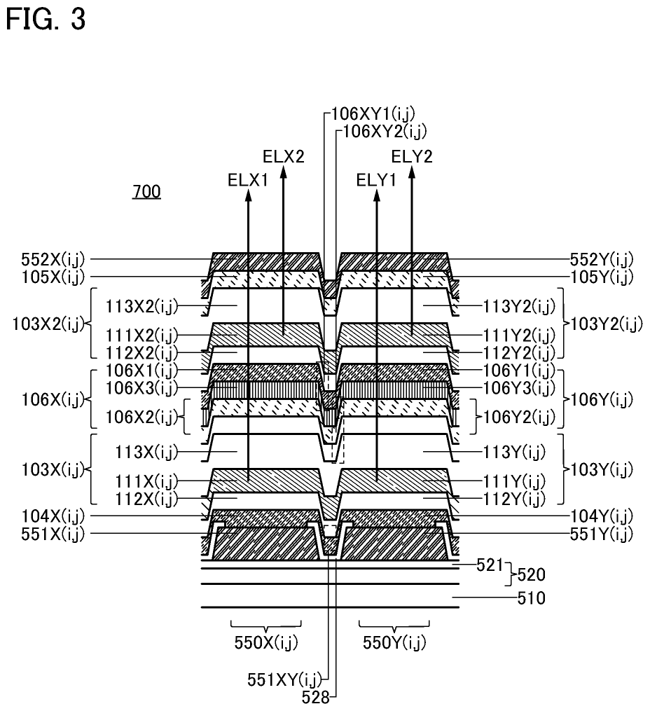

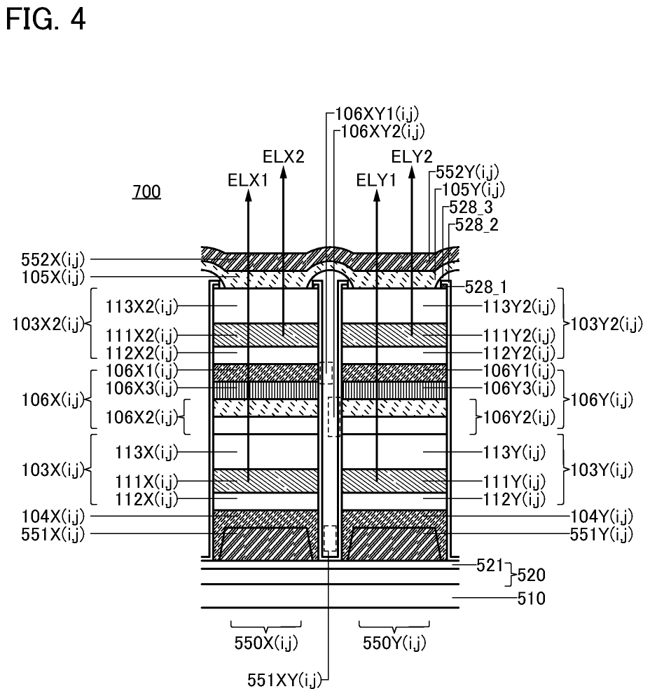

In this embodiment, the structures of a display apparatus 700 of one embodiment of the present invention will be described with reference to FIG. 3 and FIG. 4.

FIG. 3 is a cross-sectional view illustrating a structure of the display apparatus 700 of one embodiment of the present invention. FIG. 4 is a cross-sectional view illustrating a structure of the display apparatus 700 of one embodiment of the present invention, which is different from the structure described with reference to FIG. 3.

<Structure Example 1 of Display Apparatus 700>

The display apparatus 700 described in this embodiment includes a light-emitting device 550X(i,j) and a light-emitting device 550Y(i,j) (see FIG. 3). The light-emitting device 550Y(i,j) is adjacent to the light-emitting device 550X(i,j).

The display apparatus 700 includes a substrate 510 and a functional layer 520. The functional layer 520 includes an insulating film 521, and the light-emitting devices 550X(i,j) and 550Y(i,j) are formed over the insulating film 521. The functional layer 520 is located between the substrate 510 and the light-emitting device 550X(i,j).

<<Structure Example of Light-Emitting Device 550X(Ij)>>

The light-emitting device 550X(i,j) includes an electrode 551X(i,j), an electrode 552X(i,j), a unit 103X(i,j), a unit 103X2(i,j), and an intermediate layer 106X(i,j). A layer 104X(i,j) and a layer 105X(i,j) are further included.

For example, the light-emitting device 550X described in Embodiments 1 to 4 can be used as the light-emitting device 550X(i,j). Specifically, the structure that can be employed for the electrode 551X and the structure that can be employed for the electrode 552X can be respectively employed for the electrode 551X(i,j) and the electrode 552X(i,j). The structure that can be employed for the unit 103X and the structure that can be employed for the unit 103X2 can be respectively employed for the unit 103X(i,j) and the unit 103X2(i,j). For example, the structure that can be employed for the intermediate layer 106X can be employed for the intermediate layer 106X(i,j). The structure that can be employed for the layer 104X and a structure that can be employed for the layer 105X can be respectively employed for the layer 104X(i,j) and the layer 105X(i,j).

<<Structure Example of Light-Emitting Device 550Y(Ij)>>

The light-emitting device 550Y(i,j) includes an electrode 551Y(i,j), an electrode 552Y(i,j), a unit 103Y(i,j), a unit 103Y2(i,j), and an intermediate layer 106Y(i,j). A layer 104Y(i,j) and a layer 105Y(i,j) are further included.

The electrode 551Y(i,j) is adjacent to the electrode 551X(i,j), and a space 551XY(i,j) is provided between the electrode 551X(i,j) and the electrode 551Y(i,j). The potential supplied to the electrode 551Y(i,j) may be the same as or different from the potential supplied to the electrode 551X(i,j). By supplying a different potential, the light-emitting device 550Y(i,j) can be driven under conditions different from those for the light-emitting device 550X(i,j).

The electrode 552Y(i,j) overlaps with the electrode 551Y(i,j).

The unit 103Y(i,j) is located between the electrode 551Y(i,j) and the electrode 552Y(i,j), and the unit 103Y2(i,j) is located between the electrode 552Y(i,j) and the unit 103Y(i,j). The intermediate layer 106Y(i,j) is located between the unit 103Y2(i,j) and the unit 103Y(i,j).

The layer 104Y(i,j) is located between the unit 103Y(i,j) and the electrode 551Y(i,j), and the layer 105Y(i,j) is located between the electrode 552Y(i,j) and the unit 103Y2(i,j).

For example, the structure of the light-emitting device 550X described in Embodiments 1 to 4 can be employed for the light-emitting device 550Y(i,j). Specifically, the structure that can be employed for the electrode 551X and the structure that can be employed for the electrode 552X can be respectively employed for the electrode 551Y(i,j) and the electrode 552Y(i,j). The structure that can be employed for the unit 103X and the structure that can be employed for the unit 103X2 can be respectively employed for the unit 103Y(i,j) and the unit 103Y2(i,j). Furthermore, the structure that can be employed for the intermediate layer 106X can be employed for the intermediate layer 106Y(i,j). The structure that can be employed for the layer 104X and a structure that can be employed for the layer 105X can be respectively employed for the layer 104Y(i,j) and the layer 105Y(i,j).

Note that part of a structure of the light-emitting device 550X(i,j) can be employed as a structure of the light-emitting device 550Y(i,j). For example, part of a conductive film that can be used for the electrode 552X(i,j) can be used for the electrode 552Y(i,j). Thus, the structure can be used in common. In addition, the manufacturing process can be simplified.

Moreover, a structure emitting light with a hue that is different from the hue of light emitted from the light-emitting device 550X(i,j) can be employed for the light-emitting device 550Y(i,j). For example, the hue of light ELY1 emitted from the unit 103Y(i,j) can be different from the hue of the light ELX1. Furthermore, the hue of light ELY2 emitted from the unit 103Y2(i,j) can be different from the hue of the light ELX2.

Moreover, a structure emitting light having the same hue as the light emitted from the light-emitting device 550X(i,j) can be employed for the light-emitting device 550Y(i,j).

For example, both the light-emitting device 550X(i,j) and the light-emitting device 550Y(i,j) may emit white light. Note that a coloring layer is provided to overlap with the light-emitting device 550X(i,j), so that light with a predetermined hue can be extracted from the white light. Furthermore, another coloring layer is provided to overlap with the light-emitting device 550Y(i,j), so that light with another predetermined hue can be extracted from the white light.

For example, both the light-emitting device 550X(i,j) and the light-emitting device 550Y(i,j) may emit blue light. Note that a color conversion layer is provided to overlap with the light-emitting device 550X(i,j), so that the blue light can be converted into light with a predetermined hue. Furthermore, another color conversion layer is provided to overlap with the light-emitting device 550Y(i,j), so that the blue light can be converted into light with another predetermined hue. The blue light can be converted into green light or red light, for example.

<Structure Example 2 of Display Apparatus 700>

The display apparatus 700 described in this embodiment includes an insulating film 528 (see FIG. 3).

<<Structure Example of Insulating Film 528>>

The insulating film 528 has openings; one opening overlaps with the electrode 551X(i,j) and the other opening overlaps with the electrode 551Y(i,j). The insulating film 528 overlaps with the space 551XY(i,j).

<<Structure Example of Space 551XY(i,j)>>

The space 551XY(i,j) located between the electrode 551X(i,j) and the electrode 551Y(i,j) has a groove shape, for example. Thus, a step is formed along the groove. A deposited film is partly split or thinned between the space 551XY(i,j) and the electrode 551X(i,j).

For example, when an anisotropic deposition method such as a heating evaporation method is used, a split or thinned portion is formed in a region 106XY1(i,j) located between the layer 106X1(i,j) and the layer 106Y1(i,j) along the step. A split or thinned portion is further formed in a region 106XY2(i,j) located between the layer 106X2(i,j) and the layer 106Y2(i,j).

Therefore, for example, a current flowing through the region 106XY1(i,j) can be inhibited. Furthermore, a current flowing between the intermediate layer 106X(i,j) and the intermediate layer 106Y(i,j) can be inhibited. In addition, a phenomenon that the light-emitting device 550Y(i,j) that is adjacent to the light-emitting device 550X(i,j) unintentionally emits light in accordance with the operation of the light-emitting device 550X(i,j) can be inhibited.

<Structure Example 3 of Display Apparatus 700>

The display apparatus 700 described in this embodiment includes the light-emitting device 550X(i,j) and the light-emitting device 550Y(i,j) (see FIG. 4). The light-emitting device 550Y(i,j) is adjacent to the light-emitting device 550X(i,j).

The display apparatus 700 is different from the display apparatus 700 described with reference to FIG. 3 in that part or all of the structures of the light-emitting device 550X(i,j) or the light-emitting device 550Y(i,j) is removed in a portion overlapping with the space 551XY(i,j), and an insulating film 5281, an insulating film 528_2, and an insulating film 528_3 are included instead of the insulating film 528. Different parts will be described in detail below, and the above description is referred to for parts having the same structure as the above.

<Structure Example of Insulating Film 528_1>>

The insulating film 528_1 includes openings; one opening overlaps with the electrode 551X(i,j) and the other opening overlaps with the electrode 551Y(i,j) (see FIG. 4). The insulating film 528_1 further includes an opening overlapping with the space 551XY(i,j).

<<Structure Example of Insulating Film 528_2>>

The insulating film 528_2 includes openings; one opening overlaps with the electrode 551X(i,j) and the other opening overlaps with the electrode 551Y(i,j). The insulating film 528_2 overlaps with the space 551XY(i,j).

The insulating film 528_2 includes a region in contact with the layer 104X(i,j), the unit 103X(i,j), the intermediate layer 106X(i,j), and the unit 103X2(i,j).

The insulating film 528_2 includes a region in contact with the layer 104Y(i,j), the unit 103Y(i,j), the intermediate layer 106Y(i,j), and the unit 103Y2(i,j).

The insulating film 5282 includes a region in contact with the insulating film 521.

<Structure Example of Insulating Film 528_3>>

The insulating film 528_3 has openings; one opening overlaps with the electrode 551X(i,j) and the other opening overlaps with the electrode 551Y(i,j). The insulating film 528_3 fills the groove formed in a region overlapping with the space 551XY(i,j).

Therefore, for example, the intermediate layer 106X(i,j) and the intermediate layer 106Y(i,j) can be electrically insulated. For example, a current flowing through the region 106XY1(i,j) can be inhibited. A phenomenon that the light-emitting device 550Y(i,j) that is adjacent to the light-emitting device 550X(i,j) unintentionally emits light in accordance with the operation of the light-emitting device 550X(i,j) can be inhibited. The size of a step generated between a top surface of the unit 103X2(i,j) and a top surface of the unit 103Y2(i,j) can be reduced. A phenomenon that a split or thinned portion is formed can be inhibited between the electrode 552X(i,j) and the electrode 552Y(i,j). One conductive film can be used for the electrode 552X(i,j) and the electrode 552Y(i,j).

For example, part or all of the structures of the light-emitting device 550X(i,j) and the light-emitting device 550Y(i,j) can be removed from the portion overlapping with the space 551XY(i,j) by a photolithography method.

Specifically, in a first step, a first insulating film that is to be the insulating film 528_1 later is formed over a film that is to be the unit 103Y2(i,j) later.

In a second step, the opening overlapping with the space 551XY(i,j) is formed in the first insulating film by a photolithography method.

In a third step, part or all of the structures of the light-emitting device 550Y(i,j) is removed from the region overlapping with the space 551XY(i,j) using the insulating film as a resist. For example, a dry etching method can be used. Therefore, the groove is formed in the region overlapping with the space 551XY(i,j).

In a fourth step, for example, a second insulating film that is to be the insulating film 528_2 is formed by an ALD (Atomic Layer Deposition) method.

In a fifth step, for example, the insulating film 528_3 is formed using a photosensitive polymer to fill the groove formed in the region overlapping with the space 551XY(i,j).

In a sixth step, the opening overlapping with the electrode 551Y(i,j) is formed by a photolithography method in the first insulating film and the second insulating film to form the insulating film 528_1 and the insulating film 528_2.

In a seventh step, the layer 105Y(i,j) and the electrode 552Y(i,j) are consequently formed over the unit 103Y2(i,j).

Note that this embodiment can be combined with any of the other embodiments in this specification as appropriate.

### Embodiment 6

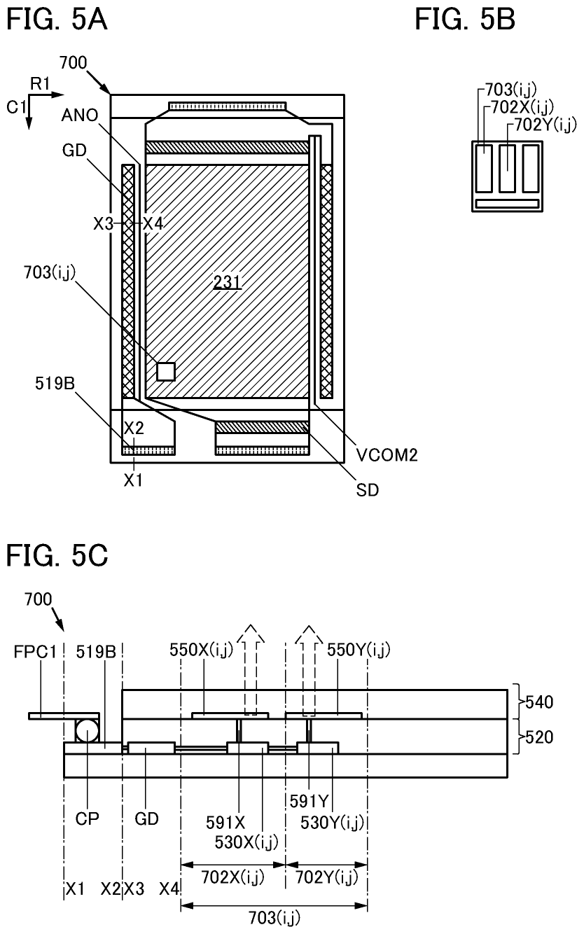

In this embodiment, a structure of an apparatus of one embodiment of the present invention will be described with reference to FIGS. 5A to 5C, FIG. 6, and FIGS. 7A to 7C.

FIGS. 5A to 5C illustrate the structure of the apparatus of one embodiment of the present invention. FIG. 5A is a top view of the apparatus of one embodiment of the present invention, and FIG. 5B is a top view illustrating part of FIG. 5A. FIG. 5C illustrates cross sections taken along cutting lines X1-X2 and X3-X4 in FIG. 5A and a cross section of a pixel set 703(i,j).

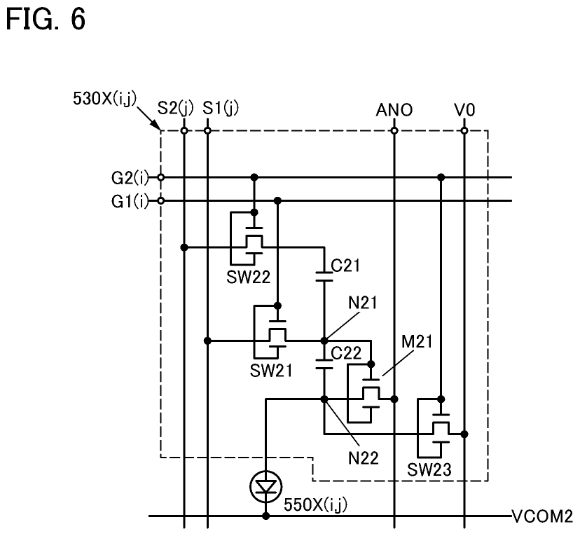

FIG. 6 is a circuit diagram illustrating the structure of the apparatus of one embodiment of the present invention.

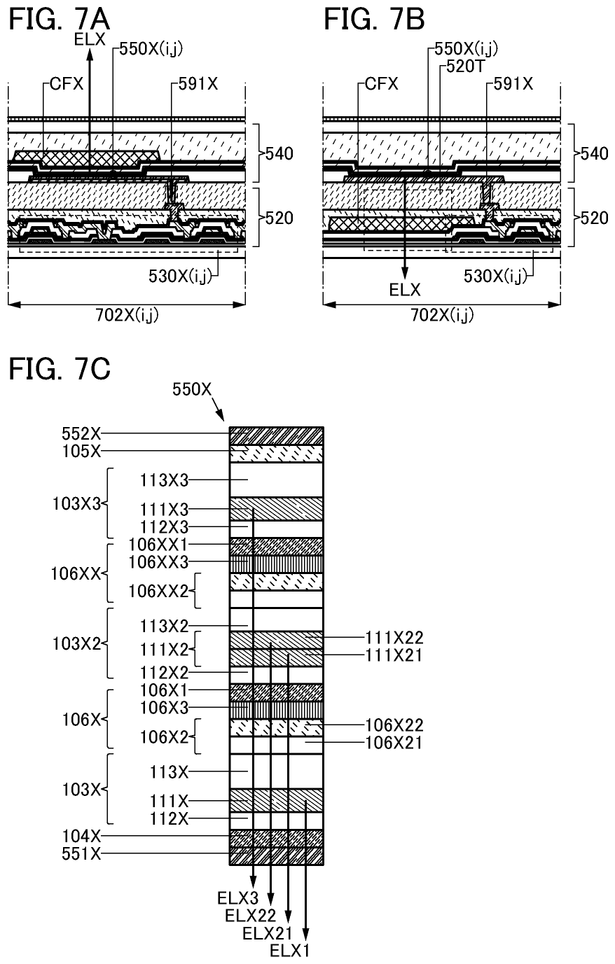

FIGS. 7A to 7C illustrate structures of the apparatus of one embodiment of the present invention. FIG. 7A is a cross-sectional view of the apparatus of one embodiment of the present invention, FIG. 7B is a cross-sectional view of the apparatus of one embodiment of the present invention having a structure different from the structure described with reference to FIG. 7A. FIG. 7C is a cross-sectional view of a light-emitting device that can be used for the apparatus illustrated in FIG. 7B.

In this specification, an integer variable of 1 or more may be used for reference numerals. For example, “(p)” where p is an integer variable of 1 or more may be used for part of a reference numeral that specifies any one of up to p components. For another example, “(m,n)” where each of m and n is an integer variable of 1 or more may be used for part of a reference numeral that specifies any one of up to m x n components.

<Structure Example 1 of Display Apparatus 700>

The display apparatus 700 of one embodiment of the present invention includes a region 231 (see FIG. 5A). The region 231 includes the pixel set 703(i,j).

<<Structure Example of Pixel Set 703(i,j)>>

The pixel set 703(i,j) includes a pixel 702X(i,j) (see FIGS. 5B and 5C).

The pixel 702X(i,j) includes a pixel circuit 530X(i,j) and the light-emitting device 550X(i,j). The light-emitting device 550X(i,j) is electrically connected to the pixel circuit 530X(i,j).

<<Structure Example 1 of Light-Emitting Device>>

For example, the light-emitting device described in any one of Embodiments 1 to 4 can be used as the light-emitting device 550X(i,j). The display apparatus 700 has a function of displaying an image.

(Structure Example 2 of Display Apparatus 700>

The display apparatus 700 of one embodiment of the present invention includes a functional layer 540 and the functional layer 520 (FIG. 5C). The functional layer 540 overlaps with the functional layer 520.

The functional layer 540 includes the light-emitting device 550X(i,j).

The functional layer 520 includes the pixel circuit 530X(i,j) and a wiring (see FIG. 5C). The pixel circuit 530X(i,j) is electrically connected to the wiring. For example, a conductive film provided in an opening 591X or an opening 591Y in the functional layer 520 can be used for the wiring. The wiring electrically connects a terminal 519B to the pixel circuit 530X(i,j). Note that a conductive material CP electrically connects the terminal 519B to a flexible printed circuit board FPC1.

<Structure Example 3 of Display Apparatus 700>

In addition, the display apparatus 700 of one embodiment of the present invention includes a driver circuit GD and a driver circuit SD (see FIG. 5A).

<<Structure Example of Driver Circuit GD>>

The driver circuit GD supplies a first selection signal and a second selection signal.

<<Structure Example of Driver Circuit SD>>

The driver circuit SD supplies a first control signal and a second control signal.

<<Structure Example of Wiring>>

As the wiring, a conductive film G1(i), a conductive film G2(i), a conductive film S1(j), a conductive film S2(j), a conductive film ANO, a conductive film VCOM2, and a conductive film V0 are included (see FIG. 6).

The conductive film G1(i) is supplied with the first selection signal, and the conductive film G2(i) is supplied with the second selection signal.

The conductive film S1(j) is supplied with the first control signal, and the conductive film S2(j) is supplied with the second control signal.

<<Structure Example 1 of Pixel Circuit 530X(i,j)>>

The pixel circuit 530X(i,j) is electrically connected to the conductive film G1(i) and the conductive film S1(j). The conductive film G1(i) supplies the first selection signal, and the conductive film S1(j) supplies the first control signal.

The pixel circuit 530X(i,j) drives the light-emitting device 550X(i,j) in response to the first selection signal and the first control signal. The light-emitting device 550X(i,j) emits light.

In the light-emitting device 550X(i,j), one of the electrodes is electrically connected to the pixel circuit 530X(i,j) and the other electrode is electrically connected to the conductive film VCOM2.

<<Structure Example 2 of Pixel Circuit 530X(i,j)>>

The pixel circuit 530X(i,j) includes a switch SW21, a switch SW22, a transistor M21, a capacitor C21, and a node N21.

The transistor M21 includes a gate electrode electrically connected to the node N21, a first electrode electrically connected to the light-emitting device 550X(i,j), and a second electrode electrically connected to the conductive film ANO.

The switch SW21 includes a first terminal electrically connected to the node N21, a second terminal electrically connected to the conductive film S1(j), and a gate electrode having a function of controlling an on/off state of the switch SW21 according to the potential of the conductive film G1(i).

The switch SW22 includes a first terminal electrically connected to the conductive film S2(j), and a gate electrode having a function of controlling an on/off state of the switch SW22 according to the potential of the conductive film G2(i).

The capacitor C21 includes a conductive film electrically connected to the node N21 and a conductive film electrically connected to a second electrode of the switch SW22.

Accordingly, an image signal can be stored in the node N21. Alternatively, the potential of the node N21 can be changed using the switch SW22. Alternatively, the intensity of light emitted from the light-emitting device 550X(i,j) can be controlled with the potential of the node N21. As a result, a novel device that is highly convenient, useful, or reliable can be provided.

<<Structure Example 3 of Pixel Circuit 530X(i,j)>>

The pixel circuit 530X(i,j) includes a switch SW23, a node N22, and a capacitor C22.

The switch SW23 includes a first terminal electrically connected to the conductive film V0, a second terminal electrically connected to the node N22, and a gate electrode having a function of controlling an on/off state of the switch SW23 according to the potential of the conductive film G2(i).

The capacitor C22 includes a conductive film electrically connected to the node N21 and a conductive film electrically connected to the node N22.

The first electrode of the transistor M21 is electrically connected to the node N22.

<<Structure Example 1 of Pixel 702X(i,j)>>

The pixel 702X(i,j) includes the light-emitting device 550X(i,j) and the pixel circuit 530X(i,j) (see FIG. 7A). The functional layer 540 includes the light-emitting device 550X(i,j) and a coloring layer CFX, and the functional layer 520 includes the pixel circuit 530X(i,j).

The light-emitting device 550X(i,j) is a top-emission light-emitting device and emits the light ELX to the side where the functional layer 520 is not provided.

The coloring layer CFX transmits part of the light emitted from the light-emitting device 550X(i,j). For example, part of white light is transmitted, and blue light, green light, or red light can be extracted. Note that a color conversion layer can be used instead of the coloring layer CFX. Therefore, light with a short wavelength can be converted into light with a long wavelength.

<<Structure Example 2 of Pixel 702X(i,j)>>

The pixel 702X(i,j) described with reference to FIG. 7B includes a bottom-emission light-emitting device. The light-emitting device 550X(i,j) emits the light ELX to the side where the functional layer 520 is provided.

The functional layer 520 includes a region 520T that transmits the light ELX. The functional layer 520 includes the coloring layer CFX that overlaps with the region 520T.

<<Structure Example 2 of Light-Emitting Device>>

For example, a light-emitting device having the same structure as the light-emitting device 550X described with reference to FIG. 7C can be used as the light-emitting device 550X(i,j).

The light-emitting device 550X described in this embodiment includes the electrode 551X, the electrode 552X, the unit 103X, the unit 103X2, a unit 103X3, the intermediate layer 106X, and an intermediate layer 106XX.

The unit 103X is located between the electrode 551X and the electrode 552X, the unit 103X2 is located between the electrode 552X and the unit 103X, and the unit 103X3 is located between the electrode 552X and the unit 103X2. The intermediate layer 106X is located between the unit 103X2 and the unit 103X, and the intermediate layer 106XX is located between the unit 103X3 and the unit 103X2.

The unit 103X has a function of emitting the light ELX1, the unit 103X2 has a function of emitting light ELX21 and light ELX22, and the unit 103X3 has a function of emitting light ELX3. The intermediate layer 106X has a function of supplying electrons to the unit 103X and supplying holes to the unit 103X2. The intermediate layer 106XX has a function of supplying electrons to the unit 103X2 and supplying holes to the unit 103X3.

Note that the structure that can be employed for the light-emitting device 550X described in Embodiments 1 to 4 can be employed for the electrode 551X, the electrode 552X, the unit 103X, and the unit 103X2. Furthermore, the structure that can be employed for the unit 103X can be employed for the unit 103X3, and the structure that can be employed for the intermediate layer 106X can be employed for the intermediate layer 106XX. For example, a light-emitting material that emits blue light can be used for the layer 111X and the layer 111X3.

<<Structure Example of Unit 103X2>>

For example, a layer 111X21 and a layer 111X22 can be used for the unit 103X2. The layer 111X21 and the layer 111X22 each contain a light-emitting material. For example, a light-emitting material that emits red light can be used for the layer 111X21. For example, a light-emitting material that emits yellow light can be used for the layer 111X22.

Note that this embodiment can be combined with any of the other embodiments in this specification as appropriate.

### Embodiment 7

In this embodiment, a light-emitting apparatus including the light-emitting device described in any one of Embodiments 1 to 4 will be described.

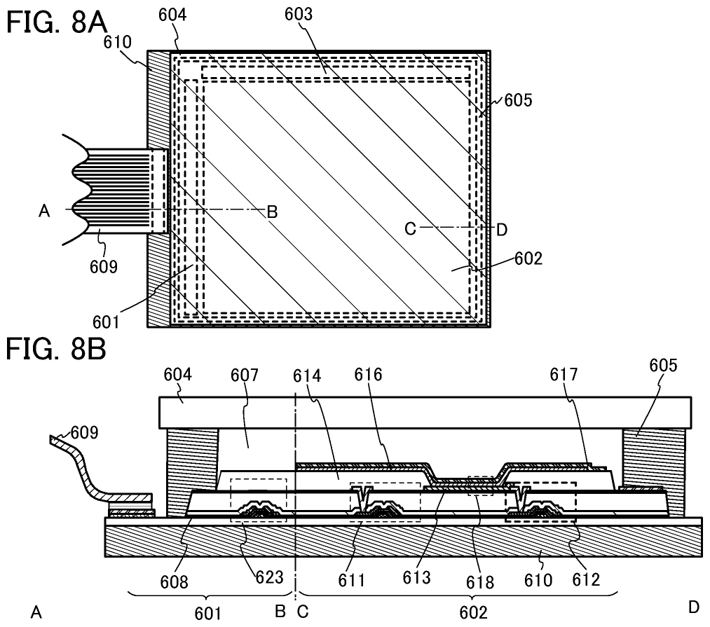

In this embodiment, the light-emitting apparatus fabricated using the light-emitting device described in any one of Embodiments 1 to 4 is described with reference to FIGS. 8A and 8B. Note that FIG. 8A is a top view of the light-emitting apparatus and FIG. 8B is a cross-sectional view taken along the lines A-B and C-D in FIG. 8A. This light-emitting apparatus includes a pixel portion 602 and a driver circuit portion (including a source line driver circuit 601 and a gate line driver circuit 603), which are to control light emission of the light-emitting device. The light-emitting apparatus is provided with a sealing substrate 604 and a sealing material 605, and a space 607 is surrounded by the sealing material 605.

A lead wiring 608 is a wiring for transmitting signals to be input to the source line driver circuit 601 and the gate line driver circuit 603 and receives signals such as a video signal, a clock signal, a start signal, and a reset signal from a flexible printed circuit (FPC) serving as an external input terminal 609. Although only the FPC is illustrated here, a printed wiring board (PWB) may be attached to the FPC. The light-emitting apparatus in this specification includes, in its category, not only the light-emitting apparatus itself but also the light-emitting apparatus provided with the FPC or the PWB.

Next, a cross-sectional structure is described with reference to FIG. 8B. The driver circuit portions and the pixel portion are formed over an element substrate 610; here, the source line driver circuit 601, which is a driver circuit portion, and one pixel in the pixel portion 602 are illustrated.

The element substrate 610 may be a substrate formed of glass, quartz, an organic resin, a metal, an alloy, or a semiconductor or a plastic substrate formed of fiber reinforced plastics (FRP), poly(vinyl fluoride) (PVF), polyester, an acrylic resin, or the like.

The structures of transistors used in pixels or driver circuits are not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, or gallium nitride can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable that a semiconductor having crystallinity be used, in which case deterioration of the transistor characteristics can be suppressed.

Here, an oxide semiconductor is preferably used for semiconductor devices such as the transistors provided in the pixels or driver circuits and transistors used for touch sensors described later, and the like. In particular, an oxide semiconductor having a wider band gap than silicon is preferably used. When an oxide semiconductor having a wider band gap than silicon is used, the off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed in each display region is maintained. As a result, an electronic device with extremely low power consumption can be obtained.

For stable characteristics or the like of the transistor, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is illustrated as a transistor formed in the source line driver circuit 601. In addition, the driver circuit may be formed with any of a variety of circuits such as a CMOS circuit, a PMOS circuit, or an NMOS circuit. Although a driver integrated type in which the driver circuit is formed over the substrate is illustrated in this embodiment, the driver circuit is not necessarily formed over the substrate, and the driver circuit can be formed outside.

The pixel portion 602 includes a plurality of pixels each including a switching FET 611, a current controlling FET 612, and a first electrode 613 electrically connected to a drain of the current controlling FET 612. One embodiment of the present invention is not limited to the structure. The pixel portion 602 may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an EL layer or the like which is formed later, the insulator 614 is formed to have a curved surface with curvature at its upper or lower end portion. For example, in the case where a positive photosensitive acrylic resin is used for a material of the insulator 614, only the upper end portion of the insulator 614 preferably has a surface with a curvature radius (greater than or equal to 0.2 μm and less than or equal to 3 μm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material having a high work function is desirably used. For example, a single-layer film of an ITO film, an indium tin oxide film containing silicon, an indium oxide film containing zinc oxide at 2 wt % to 20 wt %, a titanium nitride film, a chromium film, a tungsten film, a Zn film, a Pt film, or the like, a stack of a titanium nitride film and a film containing aluminum as its main component, or a stack of three layers of a titanium nitride film, a film containing aluminum as its main component, and a titanium nitride film can be used. The stacked-layer structure enables low wiring resistance, favorable ohmic contact, and a function as an anode.

The EL layer 616 is formed by any of a variety of methods such as an evaporation method using an evaporation mask, an inkjet method, and a spin coating method. The EL layer 616 has the structure described in any one of Embodiments 1 to 4. As another material included in the EL layer 616, a low molecular compound or a high molecular compound (including an oligomer or a dendrimer) may be used.

As a material used for the second electrode 617, which is formed over the EL layer 616 and functions as a cathode, a material having a low work function (e.g., Al, Mg, Li, and Ca, or an alloy or a compound thereof, such as MgAg, MgIn, and AlLi) is preferably used. In the case where light generated in the EL layer 616 passes through the second electrode 617, a stack including a thin metal film and a transparent conductive film (e.g., ITO, indium oxide containing zinc oxide at 2 wt % or higher and 20 wt % or lower, indium tin oxide containing silicon, or zinc oxide (ZnO)) is preferably used for the second electrode 617.

Note that the light-emitting device is formed with the first electrode 613, the EL layer 616, and the second electrode 617. The light-emitting device is the light-emitting device described in any one of Embodiments 1 to 4. In the light-emitting apparatus of this embodiment, the pixel portion, which includes a plurality of light-emitting devices, may include both the light-emitting device described in any one of Embodiments 1 to 4 and a light-emitting device having a different structure.

The sealing substrate 604 is attached to the element substrate 610 with the sealing material 605, so that a light-emitting device 618 is provided in the space 607 surrounded by the element substrate 610, the sealing substrate 604, and the sealing material 605. The space 607 may be filled with a filler, or may be filled with an inert gas (such as nitrogen or argon), or the sealing material. It is preferable that the sealing substrate be provided with a recessed portion and a drying agent be provided in the recessed portion, in which case degradation due to influence of moisture can be suppressed.

An epoxy-based resin or glass frit is preferably used for the sealing material 605. It is preferable that such a material not be permeable to moisture and oxygen as much as possible. As the sealing substrate 604, a glass substrate, a quartz substrate, or a plastic substrate formed of fiber reinforced plastics (FRP), poly(vinyl fluoride) (PVF), polyester, an acrylic resin, or the like can be used.

Although not illustrated in FIGS. 8A and 8B, a protective film may be provided over the second electrode. As the protective film, an organic resin film or an inorganic insulating film may be formed. The protective film may be formed so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material through which an impurity such as water does not permeate easily. Thus, diffusion of an impurity such as water from the outside into the inside can be effectively suppressed.

As a material of the protective film, an oxide, a nitride, a fluoride, a sulfide, a ternary compound, a metal, a polymer, or the like can be used. For example, a material containing aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, or indium oxide; a material containing aluminum nitride, hafnium nitride, silicon nitride, tantalum nitride, titanium nitride, niobium nitride, molybdenum nitride, zirconium nitride, or gallium nitride; or a material containing a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, or an oxide containing yttrium and zirconium can be used.

The protective film is preferably formed using a deposition method with favorable step coverage. One such method is an atomic layer deposition (ALD) method. A material that can be formed by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and rear surfaces of a touch panel.

As described above, the light-emitting apparatus fabricated using the light-emitting device described in any one of Embodiments 1 to 4 can be obtained.

The light-emitting apparatus in this embodiment is fabricated using the light-emitting device described in any one of Embodiments 1 to 4 and thus can have favorable characteristics. Specifically, since the light-emitting device described in any one of Embodiments 1 to 4 has high emission efficiency, the light-emitting apparatus can achieve low power consumption.

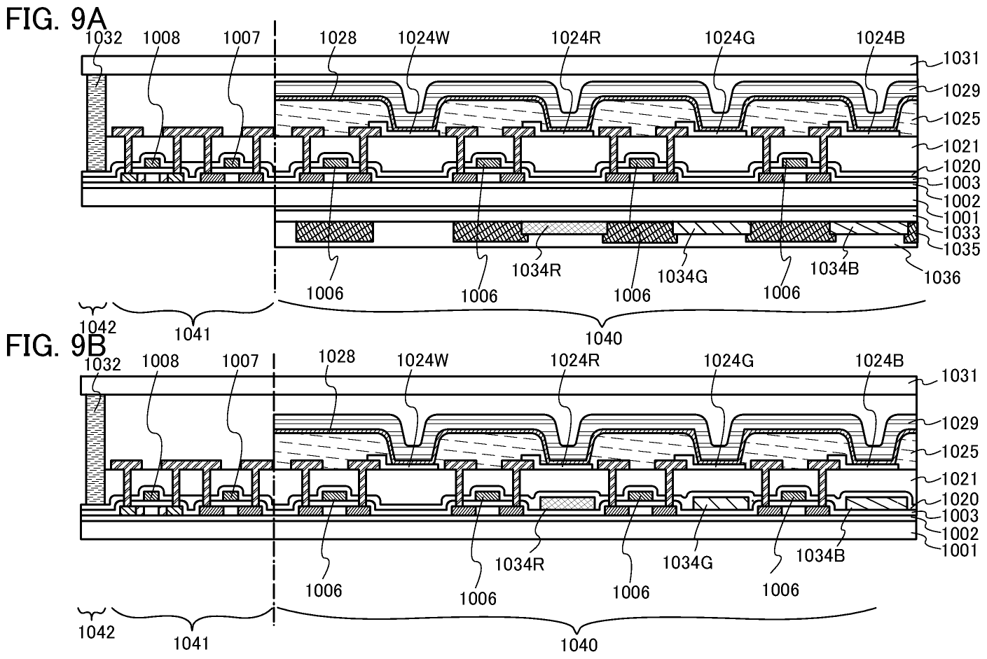

FIGS. 9A and 9B each illustrate an example of a light-emitting apparatus that includes a light-emitting device exhibiting white light emission, coloring layers (color filters), and the like to display a full-color image. In FIG. 9A, a substrate 1001, a base insulating film 1002, a gate insulating film 1003, a gate electrode 1006, a gate electrode 1007, and a gate electrode 1008, a first interlayer insulating film 1020, a second interlayer insulating film 1021, a peripheral portion 1042, a pixel portion 1040, a driver circuit portion 1041, electrodes 1024W, 1024R, 1024G, and 1024B of light-emitting devices, a partition 1025, an EL layer 1028, an electrode 1029 of the light-emitting devices, a sealing substrate 1031, a sealing material 1032, and the like are illustrated.

In FIG. 9A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is aligned and fixed to the substrate 1001. Note that the coloring layers and the black matrix 1035 are covered with an overcoat layer 1036. In FIG. 9A, light emitted from part of the light-emitting layer does not pass through the coloring layers, while light emitted from the other part of the light-emitting layer passes through the coloring layers. The light that does not pass through the coloring layers is white and the light that passes through any one of the coloring layers is red, green, or blue; thus, an image can be displayed using pixels of the four colors.

FIG. 9B shows an example in which the coloring layers (the red coloring layer 1034R, the green coloring layer 1034G, and the blue coloring layer 1034B) are provided between the gate insulating film 1003 and the first interlayer insulating film 1020. As in the structure, the coloring layers may be provided between the substrate 1001 and the sealing substrate 1031.

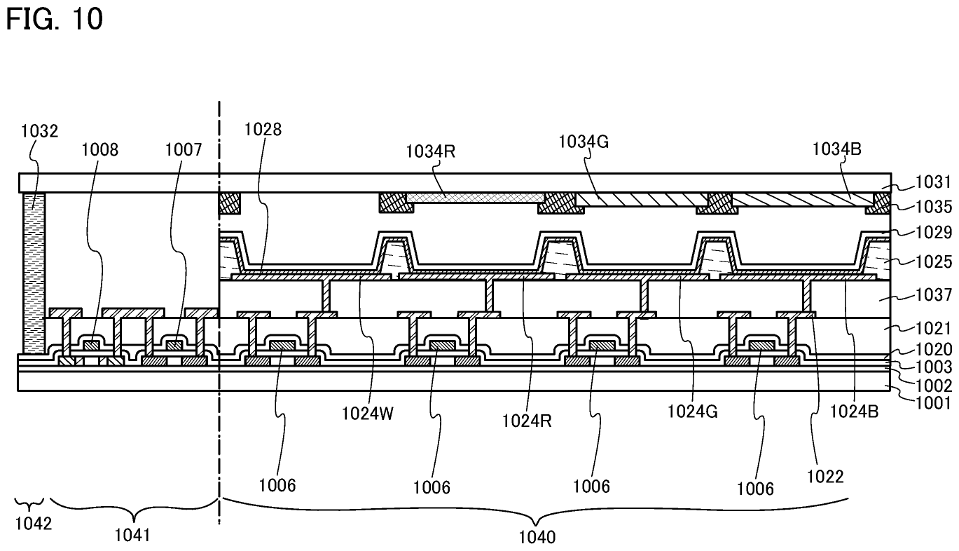

The above-described light-emitting apparatus has a structure in which light is extracted from the substrate 1001 side where FETs are formed (a bottom emission structure), but may have a structure in which light is extracted from the sealing substrate 1031 side (a top emission structure). FIG. 10 is a cross-sectional view of a light-emitting apparatus having a top emission structure. In this case, a substrate which does not transmit light can be used as the substrate 1001. The process up to the step of forming a connection electrode which connects the FET and the anode of the light-emitting device is performed in a manner similar to that of the light-emitting apparatus having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film, and can alternatively be formed using any of other known materials.

The electrodes 1024 W, 1024R, 1024G, and 1024B of the light-emitting devices each serve as an anode here, but may serve as a cathode. Furthermore, in the case of the top-emission light-emitting apparatus illustrated in FIG. 10, the electrodes are preferably reflective electrodes. The EL layer 1028 is formed to have a structure similar to the structure of the unit 103X, which is described in any one of Embodiments 1 to 4, with which white light emission can be obtained.

In the case of a top emission structure as illustrated in FIG. 10, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 which is positioned between pixels. The coloring layers (the red coloring layer 1034R, the green coloring layer 1034G, and the blue coloring layer 1034B) or the black matrix 1035 may be covered with the overcoat layer. Note that a light-transmitting substrate is used as the sealing substrate 1031. Although an example in which full color display is performed using four colors of red, green, blue, and white is shown here, there is no particular limitation and full color display using four colors of red, yellow, green, and blue or three colors of red, green, and blue may be performed.

In the light-emitting apparatus having a top emission structure, a microcavity structure can be favorably employed. A light-emitting device with a microcavity structure is formed with use of a reflective electrode as the first electrode and a semi-transmissive and semi-reflective electrode as the second electrode. The light-emitting device with a microcavity structure includes at least an EL layer between the reflective electrode and the semi-transmissive and semi-reflective electrode, which includes at least a light-emitting layer serving as a light-emitting region.

Note that the reflective electrode has a visible light reflectivity of 40% to 100%, preferably 70% to 100%, and a resistivity of 1×10⁻² Ω·cm or less. In addition, the semi-transmissive and semi-reflective electrode has a visible light reflectivity of 20% to 80%, preferably 40% to 70%, and a resistivity of 1×10⁻² Ω·cm or less.

Light emitted from the light-emitting layer included in the EL layer is reflected and resonated by the reflective electrode and the semi-transmissive and semi-reflective electrode.

In the light-emitting device, by changing the thickness of the transparent conductive film, the composite material, the carrier-transport material, or the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is reflected back by the reflective electrode (first reflected light) considerably interferes with light that directly enters the semi-transmissive and semi-reflective electrode from the light-emitting layer (first incident light). For this reason, the optical path length between the reflective electrode and the light-emitting layer is preferably adjusted to (2n−1)λ/4 (n is a natural number of 1 or larger and λ is a wavelength of light to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer. The tandem light-emitting device described above may be combined with a plurality of EL layers; for example, a light-emitting device may have a structure in which a plurality of EL layers are provided, a charge-generation layer is provided between the EL layers, and each EL layer includes a plurality of light-emitting layers or a single light-emitting layer.

With the microcavity structure, emission intensity with a specific wavelength in the front direction can be increased, whereby power consumption can be reduced. Note that in the case of a light-emitting apparatus which displays images with subpixels of four colors, red, yellow, green, and blue, the light-emitting apparatus can have favorable characteristics because the luminance can be increased owing to yellow light emission and each subpixel can employ a microcavity structure suitable for wavelengths of the corresponding color.

The light-emitting apparatus in this embodiment is fabricated using the light-emitting device described in any one of Embodiments 1 to 4 and thus can have favorable characteristics. Specifically, since the light-emitting device described in any one of Embodiments 1 to 4 has high emission efficiency, the light-emitting apparatus can achieve low power consumption.

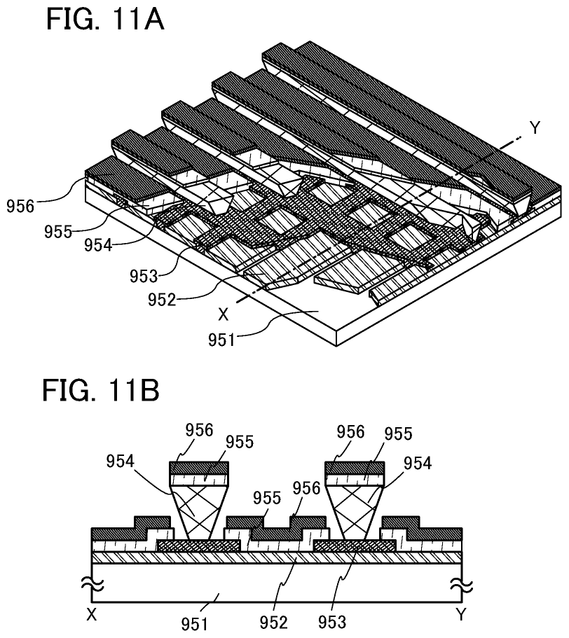

An active matrix light-emitting apparatus is described above, whereas a passive matrix light-emitting apparatus is described below. FIGS. 11A and 11B illustrate a passive matrix light-emitting apparatus manufactured using the present invention. Note that FIG. 11A is a perspective view of the light-emitting apparatus, and FIG. 11B is a cross-sectional view taken along the line X-Y in FIG. 11A. In FIGS. 11A and 11B, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. In other words, a cross section taken along the direction of the short side of the partition layer 954 is trapezoidal, and the lower side (a side of the trapezoid which is parallel to the surface of the insulating layer 953 and is in contact with the insulating layer 953) is shorter than the upper side (a side of the trapezoid which is parallel to the surface of the insulating layer 953 and is not in contact with the insulating layer 953). The partition layer 954 thus provided can prevent defects in the light-emitting device due to static electricity or others. The passive-matrix light-emitting apparatus also includes the light-emitting device described in any one of Embodiments 1 to 4; thus, the light-emitting apparatus can have high reliability or low power consumption.

Since many minute light-emitting devices arranged in a matrix in the light-emitting apparatus described above can each be controlled, the light-emitting apparatus can be suitably used as a display apparatus for displaying images.

This embodiment can be freely combined with any of the other embodiments.

### Embodiment 8

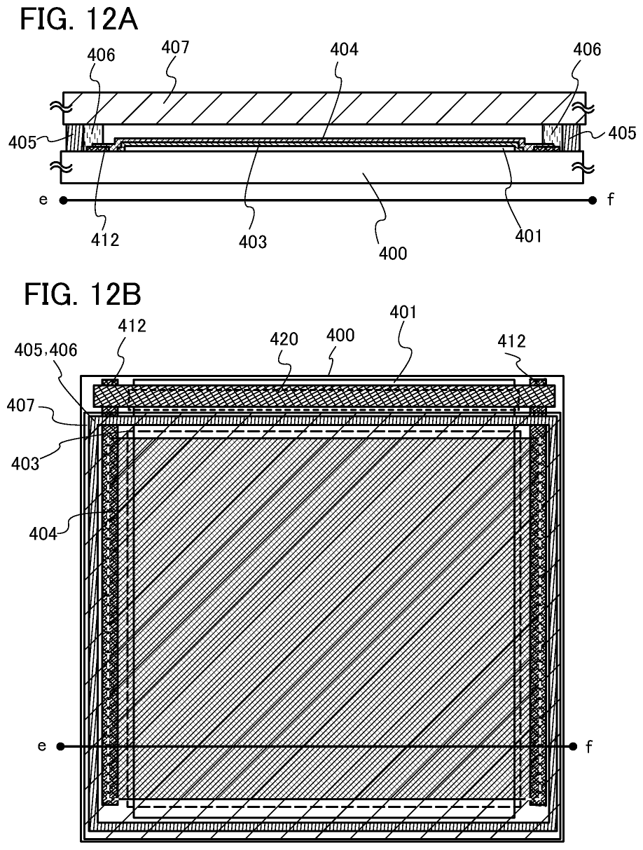

In this embodiment, an example in which the light-emitting device described in any one of Embodiments 1 to 4 is used for a lighting device will be described with reference to FIGS. 12A and 12B. FIG. 12B is a top view of the lighting device, and FIG. 12A is a cross-sectional view taken along the line e-f in FIG. 12B.

In the lighting device in this embodiment, a first electrode 401 is formed over a substrate 400 which is a support and has a light-transmitting property. The first electrode 401 corresponds to the electrode 551X in any one of Embodiments 1 to 4. When light is extracted from the first electrode 401 side, the first electrode 401 is formed using a material having a light-transmitting property.

A pad 412 for applying voltage to a second electrode 404 is provided over the substrate 400.

An EL layer 403 is formed over the first electrode 401. The EL layer 403 corresponds to the structure in which the layer 104X, the unit 103X, and the layer 105X are combined, the structure in which the layer 104X, the unit 103X, the intermediate layer 106X, the unit 103X2, and the layer 105X are combined, or the like in any one of Embodiments 1 to 4. Refer to the corresponding description for these structures.

The second electrode 404 is formed to cover the EL layer 403. The second electrode 404 corresponds to the electrode 552X in any one of Embodiments 1 to 4. The second electrode 404 is formed using a material having high reflectance when light is extracted from the first electrode 401 side. The second electrode 404 is connected to the pad 412, whereby voltage is applied.

As described above, the lighting device described in this embodiment includes a light-emitting device including the first electrode 401, the EL layer 403, and the second electrode 404. Since the light-emitting device is a light-emitting device with high emission efficiency, the lighting device in this embodiment can be a lighting device with low power consumption.

The substrate 400 provided with the light-emitting device having the above structure is fixed to a sealing substrate 407 with sealing materials 405 and 406 and sealing is performed, whereby the lighting device is completed. It is possible to use only either the sealing material 405 or the sealing material 406. The inner sealing material 406 (not illustrated in FIG. 12B) can be mixed with a desiccant that enables moisture to be adsorbed, which results in improved reliability.

When parts of the pad 412 and the first electrode 401 are extended to the outside of the sealing materials 405 and 406, the extended parts can serve as external input terminals. An IC chip 420 mounted with a converter or the like may be provided over the external input terminals.

The lighting device described in this embodiment includes, as an EL element, the light-emitting device described in any one of Embodiments 1 to 4, and thus can be a lighting device with low power consumption.

### Embodiment 9

In this embodiment, examples of electronic devices each including the light-emitting device described in any one of Embodiments 1 to 4 will be described. The light-emitting device described in any one of Embodiments 1 to 4 has high emission efficiency and low power consumption. As a result, the electronic devices described in this embodiment can each include a light-emitting portion having low power consumption.

Examples of the electronic device including the above light-emitting device include television devices (also referred to as TV or television receivers), monitors for computers and the like, digital cameras, digital video cameras, digital photo frames, cellular phones (also referred to as mobile phones or mobile phone devices), portable game machines, portable information terminals, audio playback devices, and large game machines such as pachinko machines. Specific examples of these electronic devices are shown below.

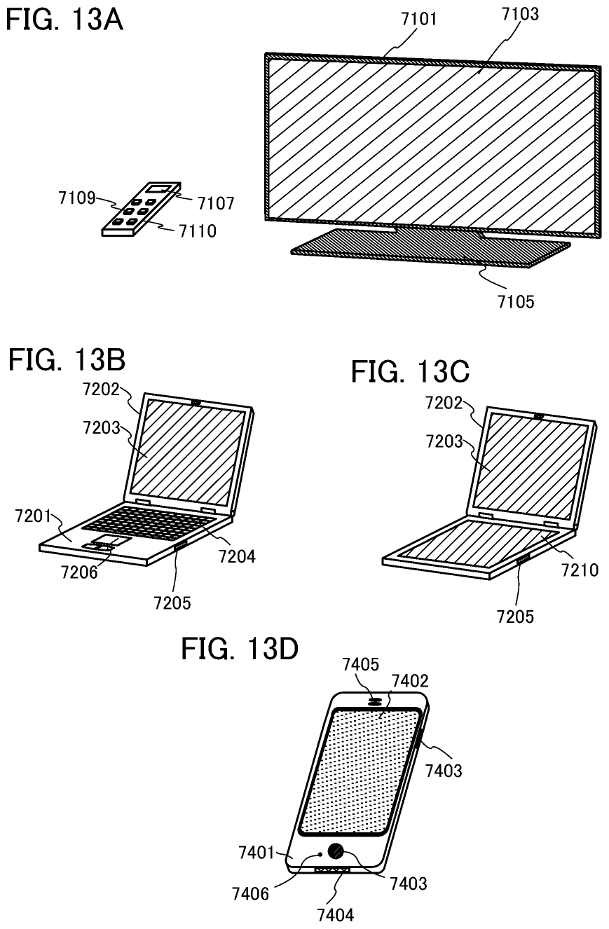

FIG. 13A shows an example of a television device. In the television device, a display portion 7103 is incorporated in a housing 7101. Here, the housing 7101 is supported by a stand 7105. Images can be displayed on the display portion 7103, and in the display portion 7103, the light-emitting devices described in any one of Embodiments 1 to 4 are arranged in a matrix.

The television device can be operated with an operation switch of the housing 7101 or a separate remote controller 7110. With operation keys 7109 of the remote controller 7110, channels or volume can be controlled and images displayed on the display portion 7103 can be controlled. Furthermore, the remote controller 7110 may be provided with a display portion 7107 and data output from the remote controller 7110 may be displayed on display portion 7107.

Note that the television device is provided with a receiver, a modem, or the like. With use of the receiver, a general television broadcast can be received. Moreover, when the television device is connected to a communication network with or without wires via the modem, one-way (from a sender to a receiver) or two-way (between a sender and a receiver or between receivers) data communication can be performed.

FIG. 13B illustrates a computer, which includes a main body 7201, a housing 7202, a display portion 7203, a keyboard 7204, an external connection port 7205, a pointing device 7206, and the like. Note that this computer is fabricated using the light-emitting devices described in any one of Embodiments 1 to 4 and arranged in a matrix in the display portion 7203. The computer illustrated in FIG. 13B may have a structure illustrated in FIG. 13C. A computer illustrated in FIG. 13C is provided with a second display portion 7210 instead of the keyboard 7204 and the pointing device 7206. The second display portion 7210 is a touch panel, and input operation can be performed by touching display for input on the second display portion 7210 with a finger or a dedicated pen. The second display portion 7210 can also display images other than the display for input. The display portion 7203 may also be a touch panel. Connecting the two screens with a hinge can prevent troubles; for example, the screens can be prevented from being cracked or broken while the computer is being stored or carried.

FIG. 13D shows an example of a portable terminal. The portable terminal is provided with a display portion 7402 incorporated in a housing 7401, operation buttons 7403, an external connection port 7404, a speaker 7405, a microphone 7406, and the like. Note that the portable terminal has the display portion 7402 including the light-emitting devices described in any one of Embodiments 1 to 4 and arranged in a matrix.

When the display portion 7402 of the portable terminal illustrated in FIG. 13D is touched with a finger or the like, data can be input into the portable terminal. In this case, operations such as making a call and creating an e-mail can be performed by touching the display portion 7402 with a finger or the like.

The display portion 7402 has mainly three screen modes. The first mode is a display mode mainly for displaying images. The second mode is an input mode mainly for inputting information such as text. The third mode is a display-and-input mode in which the two modes, the display mode and the input mode, are combined.

For example, in the case of making a call or creating an e-mail, a text input mode mainly for inputting text is selected for the display portion 7402 so that text displayed on the screen can be input. In this case, it is preferable to display a keyboard or number buttons on almost the entire screen of the display portion 7402.

When a sensing device including a sensor such as a gyroscope sensor or an acceleration sensor for detecting inclination is provided inside the portable terminal, display on the screen of the display portion 7402 can be automatically changed in direction by determining the orientation of the portable terminal (whether the portable terminal is placed horizontally or vertically).

The screen modes are switched by touching the display portion 7402 or operating the operation buttons 7403 of the housing 7401. Alternatively, the screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal sensed by an optical sensor in the display portion 7402 is sensed, the screen mode may be controlled so as to be switched from the input mode to the display mode.

The display portion 7402 may also function as an image sensor. For example, an image of a palm print, a fingerprint, or the like is taken when the display portion 7402 is touched with the palm or the finger, whereby personal authentication can be performed. Furthermore, by providing a backlight or a sensing light source which emits near-infrared light in the display portion, an image of a finger vein, a palm vein, or the like can be taken.

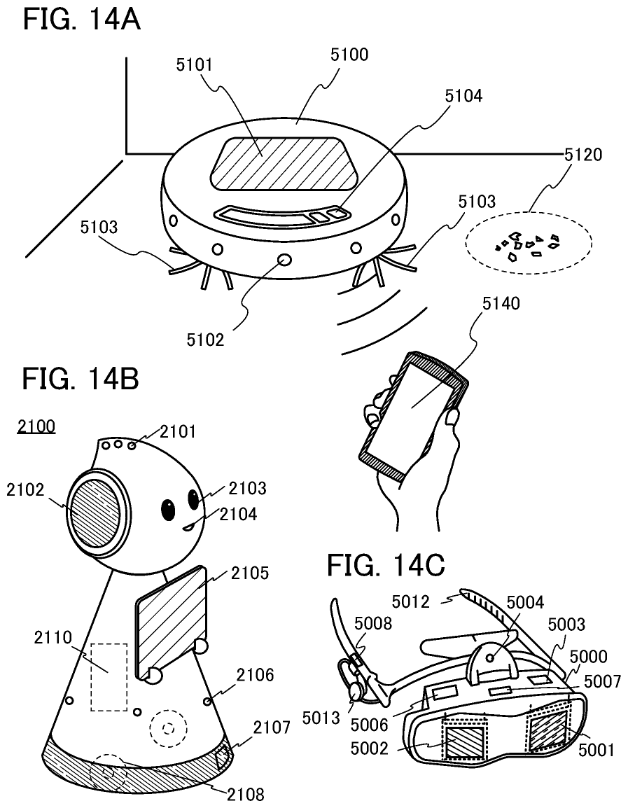

FIG. 14A is a schematic view showing an example of a cleaning robot.

A cleaning robot 5100 includes a display 5101 on its top surface, a plurality of cameras 5102 on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a wireless communication means.

The cleaning robot 5100 is self-propelled, detects dust 5120, and sucks up the dust through the inlet provided on the bottom surface.

The cleaning robot 5100 can determine whether there is an obstacle such as a wall, furniture, or a step by analyzing images taken by the cameras 5102. When the cleaning robot 5100 detects an object that is likely to be caught in the brush 5103 (e.g., a wire) by image analysis, the rotation of the brush 5103 can be stopped.

The display 5101 can display the remaining capacity of a battery, the amount of collected dust, or the like. The display 5101 may display a path on which the cleaning robot 5100 has run. The display 5101 may be a touch panel, and the operation buttons 5104 may be provided on the display 5101.

The cleaning robot 5100 can communicate with a portable electronic device 5140 such as a smartphone. The portable electronic device 5140 can display images taken by the cameras 5102. Accordingly, an owner of the cleaning robot 5100 can monitor his/her room even when the owner is not at home. The owner can also check the display on the display 5101 by the portable electronic device 5140 such as a smartphone.

The light-emitting apparatus of one embodiment of the present invention can be used for the display 5101.

A robot 2100 illustrated in FIG. 14B includes an arithmetic device 2110, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 also has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 14C shows an example of a goggle-type display. The goggle-type display includes, for example, a housing 5000, a display portion 5001, a speaker 5003, an LED lamp 5004, operation keys (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 5008, a display portion 5002, a support 5012, and an earphone 5013.

The light-emitting apparatus of one embodiment of the present invention can be used for the display portion 5001 and the display portion 5002.

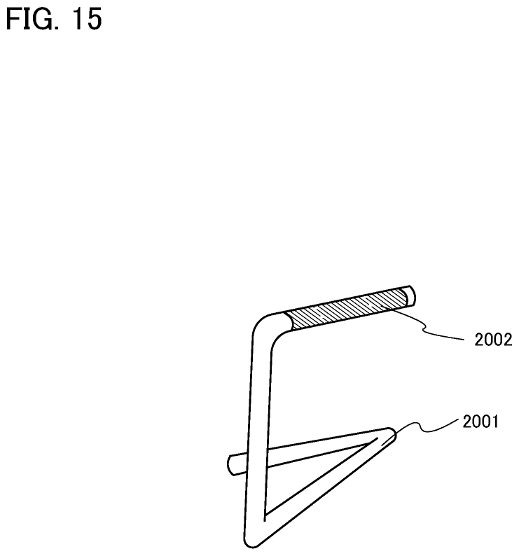

FIG. 15 shows an example in which the light-emitting device described in any one of Embodiments 1 to 4 is used for a table lamp which is a lighting device. The table lamp illustrated in FIG. 15 includes a housing 2001 and a light source 2002, and the lighting device described in Embodiment 8 may be used for the light source 2002.

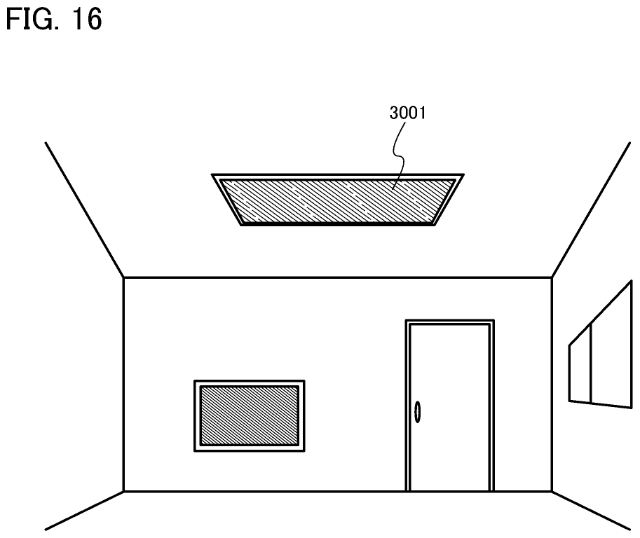

FIG. 16 shows an example in which the light-emitting device described in any one of Embodiments 1 to 4 is used for an indoor lighting device 3001. Since the light-emitting device described in any one of Embodiments 1 to 4 has high emission efficiency, the lighting device can have low power consumption. Furthermore, since the light-emitting device described in any one of Embodiments 1 to 4 can have a large area, the light-emitting device can be used for a large-area lighting device. Furthermore, since the light-emitting device described in any one of Embodiments 1 to 4 is thin, the light-emitting device can be used for a thin lighting device.

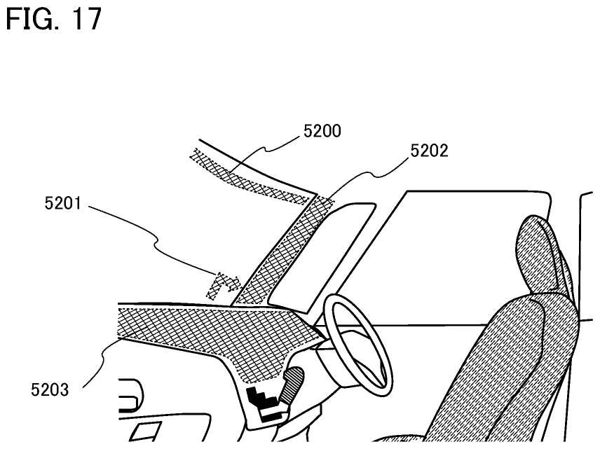

The light-emitting device described in any one of Embodiments 1 to 4 can also be used for an automobile windshield or an automobile dashboard. FIG. 17 illustrates one mode in which the light-emitting device described in any one of Embodiments 1 to 4 is used for an automobile windshield or an automobile dashboard. Display regions 5200 to 5203 each include the light-emitting device described in any one of Embodiments 1 to 4.

The display regions 5200 and 5201 are display apparatuses which are provided in the automobile windshield and in which the light-emitting device described in any one of Embodiments 1 to 4 is incorporated. The light-emitting device described in any one of Embodiments 1 to 4 can be formed into what is called a see-through light-emitting device, through which the opposite side can be seen, by including a first electrode and a second electrode having a light-transmitting property. Such see-through display devices can be provided even in the automobile windshield without hindering the view. In the case where a driving transistor or the like is provided, a transistor having a light-transmitting property, such as an organic transistor including an organic semiconductor material or a transistor including an oxide semiconductor, is preferably used.

A display apparatus incorporating the light-emitting device described in any one of Embodiments 1 to 4 is provided in the display region 5202 in a pillar portion. The display region 5202 can compensate for the view hindered by the pillar by displaying an image taken by an imaging unit provided in the car body. Similarly, the display region 5203 provided in the dashboard portion can compensate for the view hindered by the car body by displaying an image taken by an imaging unit provided on the outside of the automobile. Thus, blind areas can be eliminated to enhance the safety. Images that compensate for the areas which a driver cannot see enable the driver to ensure safety easily and comfortably.

The display region 5203 can provide a variety of kinds of information by displaying navigation data, speed, a tachometer, a mileage, a fuel level, a gearshift state, air-condition setting, and the like. The content or layout of the display can be changed freely by a user as appropriate. Note that such information can also be displayed on the display regions 5200 to 5202. The display regions 5200 to 5203 can also be used as lighting devices.

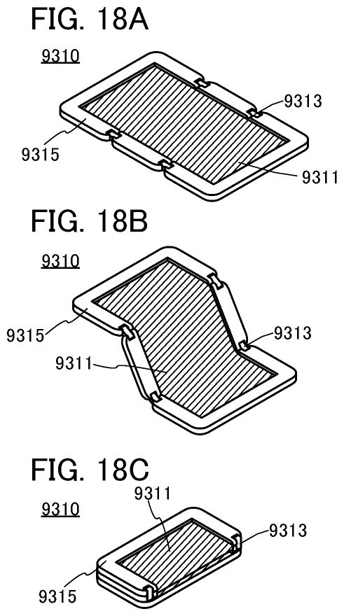

FIGS. 18A to 18C illustrate a foldable portable information terminal 9310. FIG. 18A illustrates the portable information terminal 9310 that is opened. FIG. 18B illustrates the portable information terminal 9310 in the middle of change from one of an opened state and a folded state to the other. FIG. 18C illustrates the portable information terminal 9310 that is folded. The portable information terminal 9310 is highly portable when folded. The portable information terminal 9310 is highly browsable when opened because of a seamless large display region.

A display panel 9311 is supported by three housings 9315 joined together by hinges 9313. Note that the display panel 9311 may be a touch panel (an input/output device) including a touch sensor (an input device). By folding the display panel 9311 at the hinges 9313 between two housings 9315, the portable information terminal 9310 can be reversibly changed in shape from the opened state to the folded state. The light-emitting apparatus of one embodiment of the present invention can be used for the display panel 9311.

Note that the structure described in this embodiment can be combined with any of the structures described in Embodiments 1 to 4 as appropriate.

As described above, the application range of the light-emitting apparatus including the light-emitting device described in any one of Embodiments 1 to 4 is wide, and thus the light-emitting apparatus can be applied to electronic devices in a variety of fields. By using the light-emitting device described in any one of Embodiments 1 to 4, an electronic device with low power consumption can be obtained.

Note that this embodiment can be combined with any of the other embodiments in this specification as appropriate.

### Example

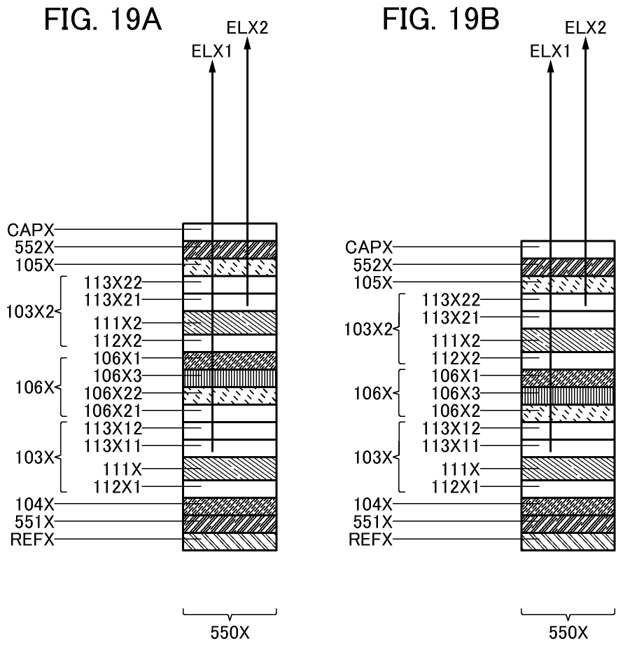

In this example, light-emitting devices of one embodiment of the present invention is described with reference to FIGS. 19A and 19B, FIG. 20, FIG. 21, FIG. 22, FIG. 23, FIG. 24, FIG. 25, FIG. 26, FIG. 27, FIG. 28, FIG. 29, and FIG. 30.

FIGS. 19A and 19B illustrate structures of the light-emitting device 550X.

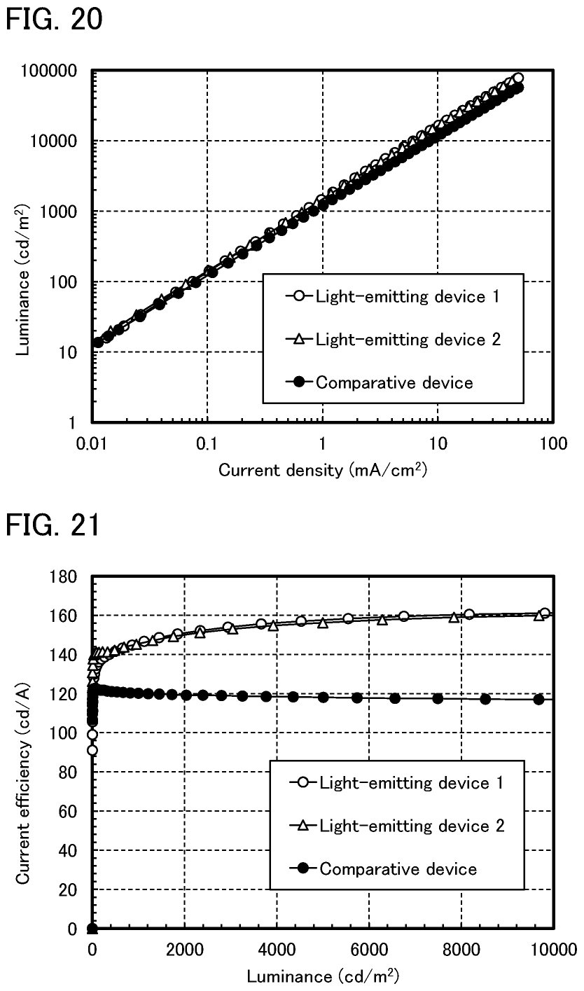

FIG. 20 shows current density-luminance characteristics of light-emitting devices.

FIG. 21 shows luminance-current efficiency characteristics of the light-emitting devices.

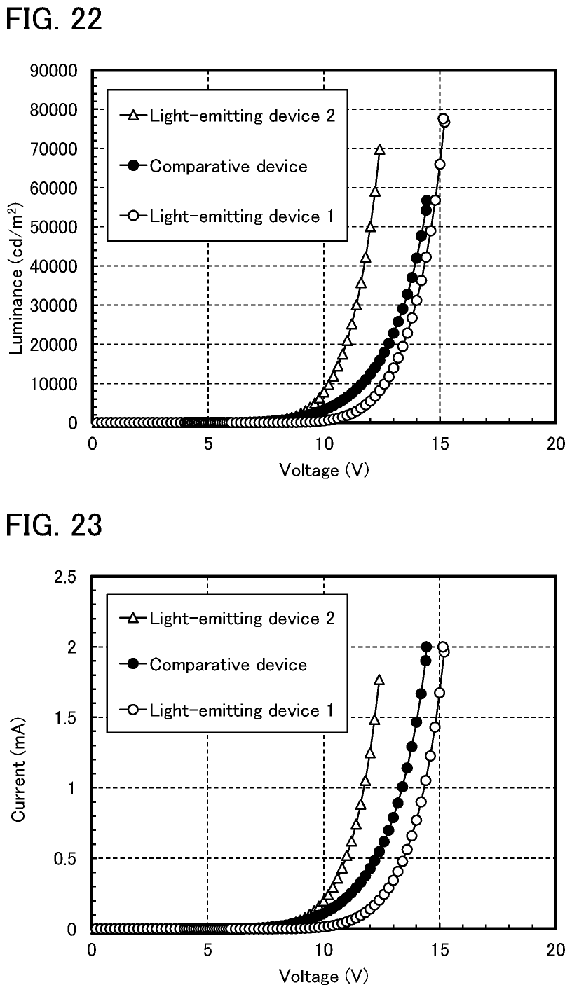

FIG. 22 shows voltage-luminance characteristics of the light-emitting devices.

FIG. 23 shows voltage-current characteristics of the light-emitting devices.

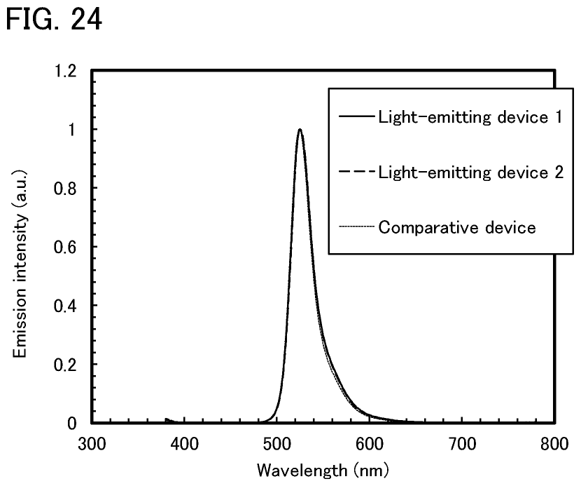

FIG. 24 shows emission spectra of the light-emitting devices each emitting light at a luminance of 1000 cd/m².

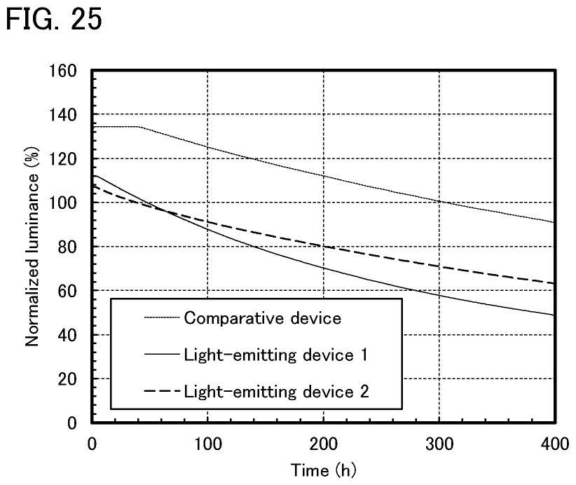

FIG. 25 shows a change in normalized luminance over time of the light-emitting devices each emitting light at a constant current density of 50 mA/cm².

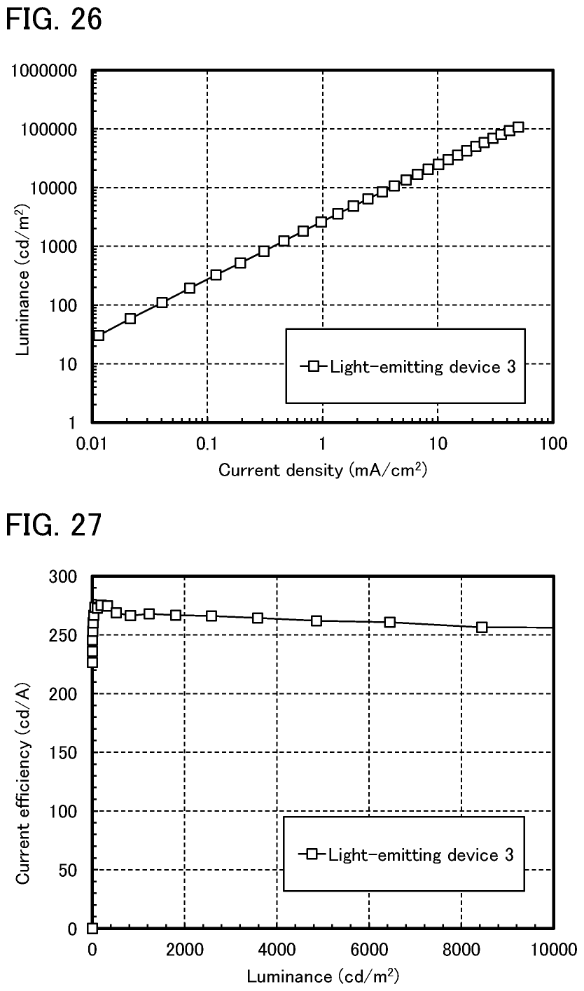

FIG. 26 shows current density-luminance characteristics of a light-emitting device 3.

FIG. 27 shows luminance-current efficiency characteristics of the light-emitting device 3.

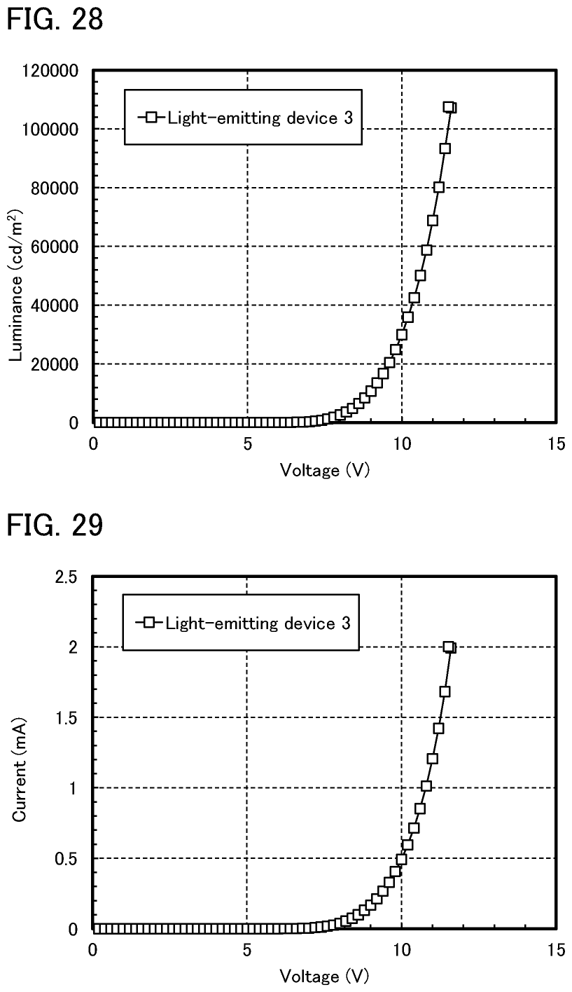

FIG. 28 shows voltage-luminance characteristics of the light-emitting device 3.

FIG. 29 shows voltage-current characteristics of the light-emitting device 3.

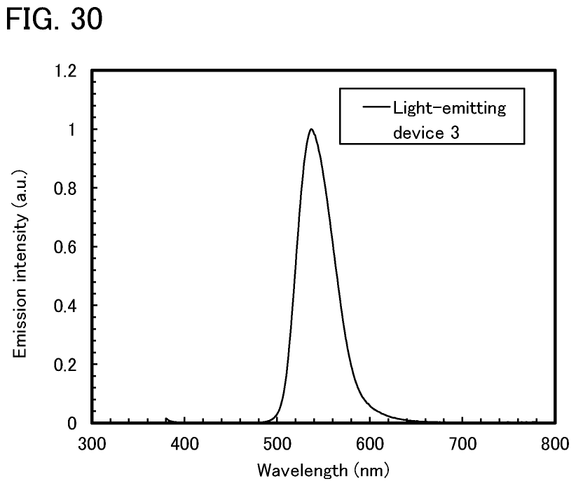

FIG. 30 shows an emission spectrum of the light-emitting device 3 emitting light at a luminance of 1000 cd/m².

<Light-Emitting Device 1 and Light-Emitting Device 2>

A fabricated light-emitting device 1 and a fabricated light-emitting device 2, which are described in this example, have a structure similar to that of the light-emitting device 550X (see FIG. 19A).

The light-emitting device 550X includes the electrode 551X, the electrode 552X, the unit 103X, the unit 103X2, and the intermediate layer 106X.

The unit 103X is located between the electrode 552X and the electrode 551X and contains the first light-emitting material EM1, and the unit 103X2 is located between the electrode 552X and the unit 103X and contains the second light-emitting material EM2.

The intermediate layer 106X is located between the unit 103X2 and the unit 103X and includes the layer 106X1 and the layer 106X2, and the layer 106X1 is located between the unit 103X2 and the layer 106X2.

The layer 106X1 contains an organic compound having a halogen group or a cyano group or a transition metal oxide.

The layer 106X2 contains the first organic compound AM2, the second organic compound DM, and the third organic compound BM. The first organic compound AM2 has the lowest unoccupied molecular orbital level in a range higher than or equal to −3.5 eV and lower than or equal to −2.0 eV, the second organic compound DM has the highest occupied molecular orbital level in a range higher than or equal to −5.0 eV and lower than or equal to −4.0 eV, and the third organic compound BM has the acid dissociation constant pKa higher than or equal to 1 and lower than or equal to 30.

<<Structure of Light-Emitting Device 1>>

Table 1 shows the structure of the light-emitting device 1. Structural formulae of materials used in the light-emitting devices described in this example are shown below. Note that in the tables in this example, subscript and superscript characters are written in ordinary size for convenience. For example, a subscript character in an abbreviation or a superscript character in a unit are written in ordinary size in the tables. The corresponding description in the specification gives an accurate reading of such notations in the tables.

TABLE 1

| | Reference | | Composition | Thickness/ |
|---|---|---|---|---|
| Structure | numeral | Material | ratio | nm |
| Layer | CAPX | DBT3P-II | | 70 |
| Electrode | 552X | Ag: Mg | 10:1 | 15 |
| Layer | 105X | LiF | | 1 |
| Layer | 113X22 | NBPhen | | 20 |
| Layer | 113X21 | 2mPCCzPDBq | | 10 |
| | | 4,8mDBtP2Bfpm: | | |
| Layer | 111X2 | βNCCP: | 0.5:0.5:0.1 | 40 |
| | | Ir(ppy)2(mbfpypy-d3) | | |
| Layer | 112X2 | PCBBiF | | 40 |
| Layer | 106X1 | PCBBiF: OCHD-003 | 1:0.15 | 10 |
| Layer | 106X3 | CuPc | | 2 |
| Layer | 106X22 | NBPhen: TPABzi | 0.9:0.1 | 10 |
| Layer | 106X21 | Pyrrd-Phen | | 1 |
| Layer | 113X12 | NBPhen | | 10 |
| Layer | 113X11 | 2mPCCzPDBq | | 10 |
| | | 4,8mDBtP2Bfpm: | | |
| Layer | 111X | βNCCP: | 0.5:0.5:0.1 | 40 |
| | | Ir(ppy)2(mbfpypy-d3) | | |
| Layer | 112X1 | PCBBiF | | 35 |
| Layer | 104X | PCBBiF: OCHD-003 | 1:0.04 | 10 |
| Electrode | 551X | ITSO | | 10 |
| Reflective | REFX | Ag | | 100 |
| film | | | | |

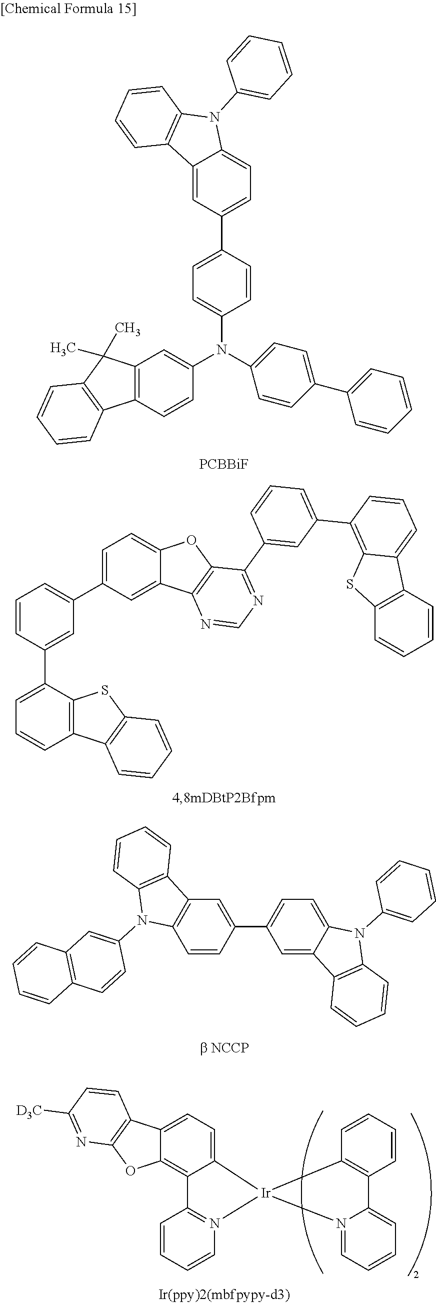

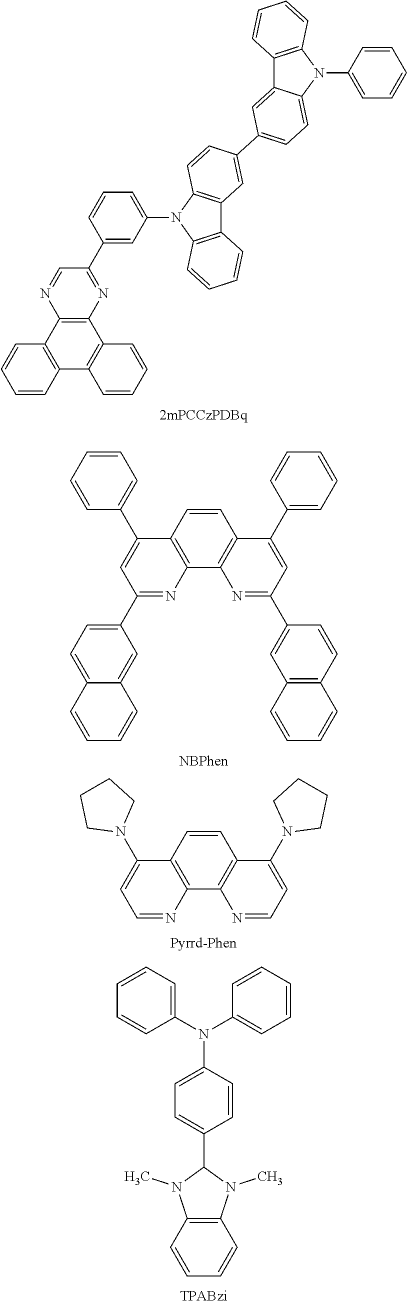

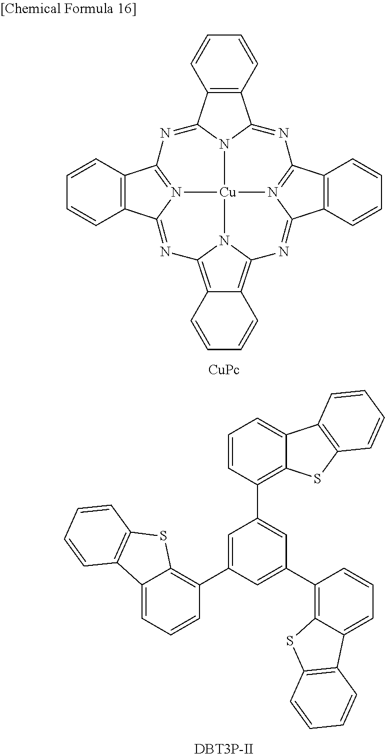

<<Method for Fabricating Light-Emitting Device 1>>

The light-emitting device 1 described in this example was fabricated using a method including the following steps.

[First Step]

A reflective film REFX was formed in a first step. Specifically, the reflective film REFX was formed by a sputtering method using silver (abbreviation: Ag) as a target.

The reflective film REFX contains Ag and has a thickness of 100 nm.

[Second Step]

In a second step, the electrode 551X was formed over the reflective film REFX. Specifically, the electrode 551X was formed by a sputtering method using indium oxide-tin oxide containing silicon or silicon oxide (abbreviation: ITSO) as a target.

The electrode 551X contains ITSO and has a thickness of 10 nm and an area of 4 mm² (2 mm×2 mm).

Next, a substrate over which the electrode 551X was formed was washed with water, baked at 200° C. for one hour, and then subjected to UV ozone treatment for 370 seconds. Then, the substrate was transferred into a vacuum evaporation apparatus where the pressure was reduced to approximately 10⁴ Pa, and vacuum baking was performed at 170° C. for 30 minutes in a heating chamber of the vacuum evaporation apparatus. Then, the substrate was cooled down for approximately 30 minutes.

[Third Step]

In a third step, the layer 104X was formed over the electrode 551X. Specifically, materials of the layer 104X were co-deposited by a resistance-heating method.

The layer 104X contains N-(1,1′-biphenyl-4-yl)-N-[4-(9-phenyl-9H-carbazol-3-yl)phenyl]-9,9-dimethyl-9H-fluoren-2-amine (abbreviation: PCBBiF) and an electron-accepting material (abbreviation: OCHD-003) at PCBBiF: OCHD-003=1:0.04 in a weight ratio and has a thickness of 10 nm. Note that OCHD-003 contains fluorine, and has a molecular weight of 672.

[Fourth Step]

In a fourth step, a layer 112X1 was formed over the layer 104X. Specifically, a material of the layer 112X1 was deposited by a resistance-heating method.

The layer 112X1 contains PCBBiF and has a thickness of 35 nm.

[Fifth Step]

In a fifth step, the layer 111X was formed over the layer 112X1. Specifically, materials of the layer 111X were co-deposited by a resistance-heating method.

The layer 111X contains 4,8-bis[3-(dibenzothiophen-4-yl)phenyl]-[1]benzofuro[3,2-d]pyrimidine (abbreviation: 4,8mDBtP2Bfpm), 9-(2-naphthyl)-9′-phenyl-9H, 9′H-3,3′-bicarbazole (abbreviation: ONCCP), and [2-d3-methyl-(2-pyridinyl-N)benzofuro[2,3-b]pyridine-KC]bis[2-(2-pyridinyl-xN)phenyl-KC]iridium(III) (abbreviation: Ir(ppy)2(mbfpypy-d3)) at 4,8mDBtP2Bfpm: PNCCP: Ir(ppy)2(mbfpypy-d3)=0.5:0.5:0.1 in a weight ratio and has a thickness of 40 nm.

[Sixth Step]

In a sixth step, a layer 113X11 was formed over the layer 111X. Specifically, a material of the layer 113X11 was deposited by a resistance-heating method.

The layer 113X11 contains 2-{3-[3-(N-phenyl-9H-carbazol-3-yl)-9H-carbazol-9-yl]phenyl}dibenzo[f,h]quinoxaline (abbreviation: 2mPCCzPDBq) and has a thickness of 10 nm.

[Seventh Step]

In a seventh step, a layer 113X12 was formed over the layer 113X11. Specifically, a material of the layer 113X12 was deposited by a resistance-heating method.

The layer 113X12 contains 2,9-di(naphthalen-2-yl)-4,7-diphenyl-1,10-phenanthroline (abbreviation: NBPhen) and has a thickness of 10 nm.

[Eighth Step]

In an eighth step, the layer 106X21 was formed over the layer 113X12. Specifically, a material of the layer 106X21 was deposited by a resistance-heating method.

The layer 106X21 contains 4,7-di-1-pyrrolidinyl-1,10-phenanthroline (abbreviation: Pyrrd-Phen) and has a thickness of 1 nm. Furthermore, Pyrrd-Phen is basic.

[Ninth Step]

In a ninth step, the layer 106X22 was formed over the layer 106X21. Specifically, materials of the layer 106X22 were co-deposited by a resistance-heating method.

The layer 106X22 contains NBPhen and 4-(1,3-dimethyl-2,3-dihydro-1H-benzimidazol-2-yl)-N,N-diphenylaniline (abbreviation: TPABzi) at NBPhen: TPABzi=0.9:0.1 in a weight ratio and has a thickness of 10 nm. NBPhen has an electron-accepting property and the lowest unoccupied molecular orbital (LUMO) level in −2.83 eV. TPABzi has an electron-donating property and the highest occupied molecular orbital (HOMO) level in −4.85 eV.

[Tenth Step]

In a tenth step, the layer 106X3 was formed over the layer 106X22. Specifically, a material of the layer 106X3 was deposited by a resistance-heating method.

Note that the layer 106X3 contains CuPc and has a thickness of 2 nm.

[Eleventh Step]

In an eleventh step, the layer 106X1 was formed over the layer 106X3. Specifically, materials of the layer 106X1 were co-deposited by a resistance-heating method.

Note that the layer 106X1 contains PCBBiF and OCHD-003 at PCBBiF: OCHD-003=1:0.15 in a weight ratio and has a thickness of 10 nm.

[Twelfth Step]

In a twelfth step, the layer 112X2 was formed over the layer 106X1. Specifically, a material of the layer 112X2 was deposited by a resistance-heating method.

Note that the layer 112X2 contains PCBBiF and has a thickness of 40 nm.

[Thirteenth Step]

In a thirteenth step, the layer 111X2 was formed over the layer 112X2. Specifically, materials of the layer 111X2 were co-deposited by a resistance-heating method.

Note that the layer 111X2 contains 4,8mDBtP2Bfpm, PNCCP, and Ir(ppy)2(mbfpypy-d3) at 4,8mDBtP2Bfpm: PNCCP: Ir(ppy)2(mbfpypy-d3)=0.5:0.5:0.1 in a weight ratio and has a thickness of 40 nm.

[Fourteenth Step]

In a fourteenth step, a layer 113X21 was formed over the layer 111X2. Specifically, a material of the layer 113X21 was deposited by a resistance-heating method.

The layer 113X21 contains 2mPCCzPDBq and has a thickness of 10 nm.

[Fifteenth Step]

In a fifteenth step, a layer 113X22 was formed over the layer 113X21. Specifically, a material of the layer 113X22 was deposited by a resistance-heating method.

The layer 113X22 contains NBPhen and has a thickness of 20 nm.

[Sixteenth Step]

In a sixteenth step, the layer 105X was formed over the layer 113X22. Specifically, a material of the layer 105X was deposited by a resistance-heating method.

The layer 105X contains lithium fluoride (abbreviation: LiF) and has a thickness of 1 nm.

[Seventeenth Step]

In a seventeenth step, the electrode 552X was formed over the layer 105X. Specifically, materials of the electrode 552X were co-deposited by a resistance-heating method.

The electrode 552X contains Ag and magnesium (abbreviation: Mg) at Ag: Mg=10:1 in a volume ratio and has a thickness of 15 nm.

[Eighteenth Step]

In an eighteenth step, a layer CAPX was formed over the electrode 552X. Specifically, a material of the layer CAPX was deposited by a resistance-heating method.

The layer CAPX contains 4,4′,4″-(benzene-1,3,5-triyl)tri(dibenzothiophene) (abbreviation: DBT3P-II) and has a thickness of 70 nm.

<<Operation characteristics of light-emitting device 1>>

When supplied with electric power, the light-emitting device 1 emitted the light ELX1 (see FIG. 19A). Operation characteristics of the light-emitting device 1 were measured at room temperature (see FIG. 20 to FIG. 24). Note that luminance, CIE chromaticity, and emission spectra were measured with a spectroradiometer (SR-UL1R manufactured by TOPCON TECHNOHOUSE CORPORATION).

Table 2 shows main initial characteristics of the fabricated light-emitting devices emitting light at a luminance of approximately 1000 cd/m². Furthermore, Table 3 shows the normalized luminance of the light-emitting devices emitting light at a constant current density of 50 mA/cm² after the elapse of 50 hours. Table 2 and Table 3 also show the characteristics of another light-emitting device having a structure described later.

TABLE 2

| | | | Current | | | Current |
|---|---|---|---|---|---|---|
| | Voltage | Current | density | Chromaticity | Chromaticity | efficiency |
| | (V) | (mA) | (mA/cm2) | x | y | (cd/A) |
| Light-emitting | 10.6 | 0.03 | 0.8 | 0.23 | 0.72 | 146.7 |
| device 1 | | | | | | |
| Light-emitting | 8.4 | 0.03 | 0.7 | 0.23 | 0.72 | 145.1 |
| device 2 | | | | | | |
| Comparative | 8.6 | 0.03 | 0.8 | 0.22 | 0.73 | 120.1 |
| device | | | | | | |

TABLE 3

| | Normalized luminance |
|---|---|
| | @ 50 hr |
| Light-emitting device 1 | 99% |
| Light-emitting device 2 | 98% |
| Comparative device | 133% |

The light-emitting device 1 and the light-emitting device 2 were found to have favorable characteristics. For example, in the light-emitting device 1, the layer 106X21 is in contact with the layer 106X22, the layer 106X21 contains Pyrrd-Phen, and the layer 106X22 contains NBPhen and TPABzi. Furthermore, in the light-emitting device 2, the layer 106X21 is in contact with the layer 106X22, the layer 106X21 contains NBPhen and TPABzi, and the layer 106X22 contains Pyrrd-Phen. At this time, interaction between Pyrrd-Phen and TPABzi improves the electron-donating property with respect to NBPhen, and charge separation easily occurs in the layer 106X2 in which the layer 106X21 and the layer 106X22 are stacked. Therefore, the light-emitting device 1 and the light-emitting device 2 exhibited higher current efficiency than a comparative device. Furthermore, the driving voltage of the light-emitting device 2 was lower than that of the comparative device. In addition, the normalized luminance after the elapse of 50 hours of the light-emitting device 1 and the light-emitting device 2 kept 99% and 98% of the initial luminance, respectively. The luminance of the comparative device increased by 133% of the initial luminance, which means the comparative device is an unstable element.

<<Structure of Light-Emitting Device 2>>

Table 4 shows the structure of the light-emitting device 2. Note that the light-emitting device 2 is different from the light-emitting device 1 in that NBPhen and TPABzi are used for the layer 106X21 instead of Pyrrd-Phen and Pyrrd-Phen is used for the layer 106X22 instead of NBPhen and TPABzi.

TABLE 4

| | Reference | | Composition | Thickness/ |
|---|---|---|---|---|
| Structure | numeral | Material | ratio | nm |
| Layer | CAPX | DBT3P-II | | 70 |
| Electrode | 552X | Ag: Mg | 10:1 | 15 |
| Layer | 105X | LiF | | 1 |
| Layer | 113X22 | NBPhen | | 20 |
| Layer | 113X21 | 2mPCCzPDBq | | 10 |
| | | 4,8mDBtP2Bfpm: | | |
| Layer | 111X2 | βNCCP: | 0.5:0.5:0.1 | 40 |
| | | Ir(ppy)2(mbfpypy-d3) | | |
| Layer | 112X2 | PCBBiF | | 40 |
| Layer | 106X1 | PCBBiF: OCHD-003 | 1:0.15 | 10 |
| Layer | 106X3 | CuPc | | 2 |
| Layer | 106X22 | Pyrrd-Phen | | 1 |
| Layer | 106X21 | NBPhen: TPABzi | 0.9:0.1 | 10 |
| Layer | 113X12 | NBPhen | | 10 |
| Layer | 113X11 | 2mPCCzPDBq | | 10 |
| | | 4,8mDBtP2Bfpm: | | |
| Layer | 111X | βNCCP: | 0.5:0.5:0.1 | 40 |
| | | Ir(ppy)2(mbfpypy-d3) | | |
| Layer | 112X1 | PCBBiF | | 35 |
| Layer | 104X | PCBBiF: OCHD-003 | 1:0.04 | 10 |
| Electrode | 551X | ITSO | | 10 |
| Reflective | REFX | Ag | | 100 |
| film | | | | |

<<Method for Fabricating Light-Emitting Device 2>>

The light-emitting device 2 described in this example was fabricated using a method including the following steps.

Note that the method for fabricating the light-emitting device 2 is different from the method for fabricating the light-emitting device 1 in that NBPhen and TPABzi were co-evaporated instead of Pyrrd-Phen in the eighth step and Pyrrd-Phen is deposited instead of NBPhen and TPABzi in the ninth step. Different portions will be described in detail below, and the above description is referred to for portions where a method similar to the above was employed.

[Eighth Step]

In the eighth step, the layer 106X21 was formed over the layer 113X12. Specifically, a material of the layer 106X21 was deposited by a resistance-heating method.

The layer 106X21 contains NBPhen and TPABzi at NBPhen: TPABzi=0.9:0.1 in a weight ratio and has a thickness of 10 nm.

[Ninth Step]

In the ninth step, the layer 106X22 was formed over the layer 106X21. Specifically, materials of the layer 106X22 were co-deposited by a resistance-heating method.

The layer 106X22 contains 4,7-di-1-pyrrolidinyl-1,10-phenanthroline (abbreviation: Pyrrd-Phen) and has a thickness of 1 nm.

<<Operation Characteristics of Light-Emitting Device 2>>

When supplied with electric power, the light-emitting device 2 emitted the light ELX1 and the light ELX2 (see FIG. 19A). Operation characteristics of the light-emitting device 2 were measured at room temperature (see FIG. 20 to FIG. 24).

<Light-Emitting Device 3>

The fabricated light-emitting device 3, which is described in this example, has a structure similar to that of the light-emitting device 550X (see FIG. 19B).

The light-emitting device 550X includes the electrode 551X, the electrode 552X, the unit 103X, the unit 103X2, and the intermediate layer 106X.

The unit 103X is located between the electrode 552X and the electrode 551X and contains the first light-emitting material EM1, and the unit 103X2 is located between the electrode 552X and the unit 103X and contains the second light-emitting material EM2.

The intermediate layer 106X is located between the unit 103X2 and the unit 103X and includes the layer 106X1 and the layer 106X2, and the layer 106X1 is located between the unit 103X2 and the layer 106X2.

The layer 106X1 contains an organic compound having a halogen group or a cyano group or a transition metal oxide.

The layer 106X2 contains the first organic compound AM2, the second organic compound DM, and the third organic compound BM. The first organic compound AM2 has the lowest unoccupied molecular orbital level in a range higher than or equal to −3.5 eV and lower than or equal to −2.0 eV, the second organic compound DM has the highest occupied molecular orbital level in a range higher than or equal to −5.0 eV and lower than or equal to −4.0 eV, and the third organic compound BM has the acid dissociation constant pKa higher than or equal to 1 and lower than or equal to 30.

<<Structure of Light-Emitting Device 3>>

Table 5 shows the structure of the light-emitting device 3. Structural formulae of materials used in the light-emitting device described in this example are shown below. Note that the light-emitting device 3 is different from the light-emitting device 1 in that the layer 112X1 has a thickness of 30 nm instead of a thickness of 35 nm; the layer 113X12 contains 2,2′-(1,3-phenylene)bis(9-phenyl-1,10-phenanthroline) (abbreviation: mPPhen2P) instead of NBPhen; between the layer 106X3 and the layer 113X12, the layer 106X2 is provided instead of the layer 106X21 and the layer 106X22; the layer 113X21 has a thickness of 20 nm instead of a thickness of 10 nm; the layer 113X22 contains mPPhen2P instead of NBPhen; and the layer 105X contains LiF and ytterbium (abbreviation: Yb) instead of LiF.

TABLE 5

| | Reference | | Composition | Thickness/ |
|---|---|---|---|---|
| Structure | numeral | Material | ratio | nm |
| Layer | CAPX | DBT3P-II | | 70 |
| Electrode | 552X | Ag: Mg | 1:0.1 | 15 |
| Layer | 105X | Lif Yb | 1:1 | 2 |
| Layer | 113X22 | mPPhen2P | | 20 |
| Layer | 113X21 | 2mPCCzPDBq | | 20 |
| | | 4,8mDBtP2Bfpm: | | |
| Layer | 111X2 | βNCCP: | 0.5:0.5:0.1 | 40 |
| | | Ir(ppy)2(mbfpypy-d3) | | |
| Layer | 112X2 | PCBBiF | | 40 |
| Layer | 106X1 | PCBBIF: OCHD-003 | 1:0.15 | 10 |
| Layer | 106X3 | CuPc | | 2 |
| | | mPPhen2P: | | |
| Layer | 106X2 | hpp2Py: | 0.45:0.45:0.2 | 10 |
| | | TPABzi | | |
| Layer | 113X12 | mPPhen2P | | 10 |
| Layer | 113X11 | 2mPCCzPDBq | | 10 |
| | | 4,8mDBtP2Bfpm: | | |
| Layer | 111X | βNCCP: | 0.5:0.5:0.1 | 40 |
| | | Ir(ppy)2(mbfpypy-d3) | | |
| Layer | 112X1 | PCBBiF | | 30 |
| Layer | 104X | PCBBiF: OCHD-003 | 1:0.03 | 10 |
| Electrode | 551X | ITSO | | 10 |
| Reflective | REFX | Ag | | 100 |
| film | | | | |

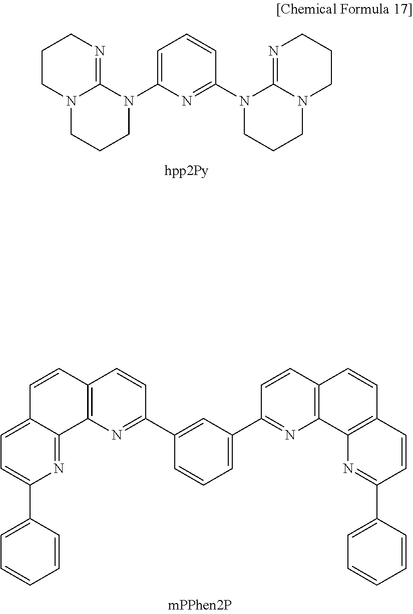 [SMILES: c1cc(N2CCCN3CCCN=C32)nc(N2CCCN3CCCN=C32)c1 ; c1ccc(-c2ccc3ccc4ccc(-c5cccc(-c6ccc7ccc8ccc(-c9ccccc9)nc8c7n6)c5)nc4c3n2)cc1]

<<Method for Fabricating Light-Emitting Device 3>>

The light-emitting device 3 described in this example was fabricated using a method including the following steps.

Note that the method for fabricating the light-emitting device 3 is different from the method for fabricating the light-emitting device 1 in that the layer 112X1 was deposited to have a thickness of 30 nm instead of a thickness of 35 nm in the fourth step; mPPhen2P was deposited instead of NBPhen in the seventh step; after the layer 113X12 was formed in the seventh step, the eighth step was skipped and the layer 106X2 was formed over the layer 113X12 in the ninth step; the layer 113X21 was deposited to have a thickness of 20 nm instead of a thickness of 10 nm in the fourteenth step; mPPhen2P was deposited instead of NBPhen in the fifteenth step; and Yb and LiF were co-evaporated, instead of LiF, to have a thickness of 2 nm in the sixteenth step. Different portions will be described in detail below, and the above description is referred to for portions where a method similar to the above was employed.

[Fourth Step]

In the fourth step, the layer 112X1 was formed over the layer 104X. Specifically, a material of the layer 112X1 was deposited by a resistance-heating method.

The layer 112X1 contains PCBBiF and has a thickness of 30 nm.

[Seventh Step]

In the seventh step, the layer 113X12 was formed over the layer 113X11. Specifically, a material of the layer 113X12 was deposited by a resistance-heating method.

Note that the layer 113X12 contains mPPhen2P and has a thickness of 10 nm.

[Ninth Step]

In the ninth step, the layer 106X2 was formed over the layer 113X12. Specifically, a material of the layer 106X2 was deposited by a resistance-heating method.

The layer 106X2 contains mPPhen2P, 1,1′-pyridine-2,6-diyl-bis(1,3,4,6,7,8-hexahydro-2H-pyrimido[1,2-a]pyrimidine) (abbreviation: hpp2Py), and TPABzi at mPPhen2P: hpp2Py: TPABzi=0.45:0.45:0.2 in a weight ratio and has a thickness of 10 nm. Furthermore, hpp2Py is basic.

[Fourteenth Step]

In the fourteenth step, the layer 113X21 was formed over the layer 111X2. Specifically, a material of the layer 113X21 was deposited by a resistance-heating method.

The layer 113X21 contains 2mPCCzPDBq and has a thickness of 20 nm.

[Fifteenth Step]

In the fifteenth step, the layer 113X22 was formed over the layer 113X21. Specifically, a material of the layer 113X22 was deposited by a resistance-heating method.

Note that the layer 113X22 contains mPPhen2P and has a thickness of 20 nm.

[Sixteenth Step]

In the sixteenth step, the layer 105X was formed over the layer 113X22. Specifically, a material of the layer 105X was deposited by a resistance-heating method.

The layer 105X contains Yb and LiF at Yb: LiF=1:1 in a volume ratio and has a thickness of 2 nm.

<<Operation Characteristics of Light-Emitting Device 3>>

When supplied with electric power, the light-emitting device 3 emitted the light ELX1 and the light ELX2 (see FIG. 19B). Operation characteristics of the light-emitting device 3 were measured at room temperature (see FIG. 26 to FIG. 30).

Table 6 shows main initial characteristics of the fabricated light-emitting device emitting light at a luminance of approximately 1000 cd/m².

TABLE 6

| | Voltage | Current | Current density | Chromaticity | Chromaticity | Current density |
|---|---|---|---|---|---|---|
| | (V) | (mA) | (mA/cm2) | x | y | (cd/A) |
| Light-emitting | 7.2 | 0.0077 | 0.19 | 0.30 | 0.68 | 268.8 |
| device 3 | | | | | | |

The light-emitting device 3 was found to have favorable characteristics. For example, in the light-emitting device 3, the layer 106X2 contains mPPhen2P, hpp2Py, and TPABzi. Furthermore, mPPhen2P has an electron-accepting property, hpp2Py is basic, and TPABzi has an electron-donating property. Therefore, the light-emitting device 3 exhibited high current efficiency.

(Reference Example)

The fabricated comparative device, which is described in this reference example, has a structure similar to that of the light-emitting device 550X (see FIG. 19B).

<<Structure of Comparative Device>>

Table 7 shows the structure of the comparative device. The comparative device is different from the light-emitting device 1 and the light-emitting device 2 in that between the layer 106X3 and the layer 113X12, the layer 106X2 is provided instead of the layer 106X21 and the layer 106X22.

TABLE 7

| | Reference | | Composition | Thickness/ |
|---|---|---|---|---|
| Structure | numeral | Material | ratio | nm |
| Layer | CAPX | DBT3P-II | | 70 |
| Electrode | 552X | Ag: Mg | 10:1 | 15 |
| Layer | 105X | DE | | 1 |
| Layer | 113X22 | NBPhen | | 20 |
| Layer | 113X21 | 2mPCCzPDBq | | 10 |
| | | 4,8mDBtP2Bfpm: | | |
| Layer | 111X2 | βNCCP: | 0.5:0.5:0.1 | 40 |
| | | Ir(ppy)2(mbfpypy-d3) | | |
| Layer | 112X2 | PCBBiF | | 40 |
| Layer | 106X1 | PCBBiF: OCHD-003 | 1:0.15 | 10 |
| Layer | 106X3 | CuPc | | 2 |
| Layer | 106X2 | NBPhen: TPABzi | 0.9:0.1 | 10 |
| Layer | 113X12 | NBPhen | | 10 |
| Layer | 113X11 | 2mPCCzPDBq | | 10 |
| | | 4,8mDBtP2Bfpm: | | |
| Layer | 111X | βNCCP: | 0.5:0.5:0.1 | 40 |
| | | Ir(ppy)2(mbfpypy-d3) | | |
| Layer | 112X1 | PCBBiF | | 35 |
| Layer | 104X | PCBBiF: OCHD-003 | 1:0.04 | 10 |
| Electrode | 551X | ITSO | | 10 |
| Reflective | REFX | Ag | | 100 |
| film | | | | |

<<Method for Fabricating Comparative Device>>

The comparative device described in this reference example was fabricated by a method including the following steps.

The method for fabricating the comparative device is different from the method for fabricating the light-emitting device 1 in that after the layer 113X12 was formed in the seventh step, the eighth step was skipped and the layer 106X2 was formed over the layer 113X12 in the ninth step. Different portions will be described in detail below, and the above description is referred to for portions where a method similar to the above was employed.

[Ninth Step]

In the ninth step, the layer 106X2 was formed over the layer 113X12. Specifically, materials of the layer 106X2 were co-deposited by a resistance-heating method.

The layer 106X2 contains NBPhen and TPABzi at NBPhen: TPABzi=0.9:0.1 in a weight ratio and has a thickness of 10 nm.

<<Operation Characteristics of Comparative Device>>

When supplied with electric power, the comparative device emitted the light ELX1 and the light ELX2 (see FIG. 19B). Operation characteristics of the comparative device were measured at room temperature (see FIG. 20 to FIG. 24).

This application is based on Japanese Patent Application Serial No. 2022-004270 filed with Japan Patent Office on Jan. 14, 2022, the entire contents of which are hereby incorporated by reference.

What is claimed is:

1. A light-emitting device comprising:
a first electrode;
a second electrode;
a first unit;
a second unit; and
a first intermediate layer,
wherein the first unit is located between the second electrode and the first electrode,
wherein the first unit comprises a first light-emitting material EM1,
wherein the second unit is located between the second electrode and the first unit,
wherein the second unit comprises a second light-emitting material EM2,
wherein the first intermediate layer is located between the second unit and the first unit,
wherein the first intermediate layer comprises a first layer and a second layer,
wherein the first layer is located between the second unit and the second layer,
wherein the first layer comprises an organic compound comprising a halogen group or a cyano group or a transition metal oxide,
wherein the second layer comprises a first organic compound AM2, a second organic compound DM, and a third organic compound BM,
wherein the first organic compound AM2 has a lowest unoccupied molecular orbital level in a range higher than or equal to −3.5 eV and lower than or equal to −2.0 eV,
wherein the second organic compound DM has a highest occupied molecular orbital level in a range higher than or equal to −5.0 eV and lower than or equal to −4.0 eV, and
wherein the third organic compound BM has an acid dissociation constant pKa higher than or equal to 1 and lower than or equal to 30.

2. A light-emitting device comprising:
a first electrode;
a second electrode;
a first unit;
a second unit; and
a first intermediate layer,
wherein the first unit is located between the second electrode and the first electrode,
wherein the first unit comprises a first light-emitting material EM1,
wherein the second unit is located between the second electrode and the first unit,
wherein the second unit comprises the second light-emitting material EM2,
wherein the first intermediate layer is located between the second unit and the first unit,
wherein the first intermediate layer comprises a first layer and a second layer,
wherein the first layer is located between the second unit and the second layer,
wherein the first layer comprises a fourth organic compound comprising a halogen group or a cyano group or a first transition metal oxide,
wherein the second layer comprises a first organic compound AM2, a second organic compound DM, and a third organic compound BM,
wherein the first organic compound AM2 has a lowest unoccupied molecular orbital level in a range higher than or equal to −3.5 eV and lower than or equal to −2.0 eV,
wherein the second organic compound DM has a highest occupied molecular orbital level in a range higher than or equal to −5.0 eV and lower than or equal to −4.0 eV, and
wherein the third organic compound BM has a structure represented by General Formula (G0): 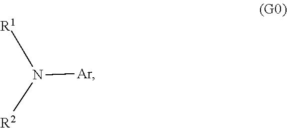
wherein:
Ar represents a substituted or unsubstituted heteroaryl group comprising nitrogen; and
R¹ and R² each independently represent a substituted or unsubstituted alkyl group having 1 to 12 carbon atoms, a substituted or unsubstituted cycloalkyl group having 3 to 12 carbon atoms, or a substituted or unsubstituted aliphatic amine having 1 to 12 carbon atoms.

3. The light-emitting device according to claim 2, wherein the third organic compound BM has the structure represented by General Formula (G0): 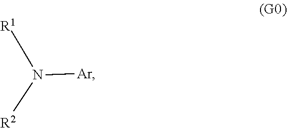
wherein Ar has a phenanthroline skeleton or a pyridine skeleton.

4. The light-emitting device according to claim 2, wherein R¹ and R² are bonded to each other to form a hetero ring.

5. The light-emitting device according to claim 2, wherein the third organic compound BM has the structure represented by General Formula (G0): 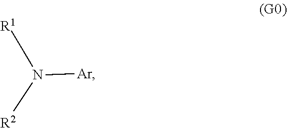
wherein R¹ and R² are bonded to each other to form a pyrrolidine skeleton, a piperidine skeleton, or a hexahydropyrimidopyrimidine group.

6. The light-emitting device according to claim 2, wherein the second organic compound DM has a dihydroimidazole group or a tetrahydroimidazole group.

7. The light-emitting device according to claim 2,
wherein the second layer comprises a third layer and a fourth layer,
wherein the fourth layer is located between the first layer and the third layer,
wherein the third layer comprises the first organic compound AM2 and the second organic compound DM, and
wherein the fourth layer comprises the third organic compound BM.

8. The light-emitting device according to claim 2,
wherein the second layer comprises a third layer and a fourth layer,
wherein the fourth layer is located between the first layer and the third layer,
wherein the third layer comprises the third organic compound BM, and
wherein the fourth layer comprises the first organic compound AM2 and the second organic compound DM.

9. The light-emitting device according to claim 2,
wherein the first layer comprises a fifth layer,
wherein the fifth layer is located between the first layer and the second layer, and
wherein the fifth layer comprises an electron-transport material.

10. A display apparatus comprising:
a first light-emitting device; and
a second light-emitting device,
wherein the first light-emitting device has the structure according to claim 2,
wherein the second light-emitting device is adjacent to the first light-emitting device,
wherein the second light-emitting device comprises a third electrode, a fourth electrode, and a second intermediate layer,
wherein a space is provided between the third electrode and the first electrode,
wherein the second intermediate layer is located between the fourth electrode and the third electrode,
wherein the second intermediate layer comprises a sixth layer and a seventh layer,
wherein the sixth layer is located between the fourth electrode and the seventh layer,
wherein the sixth layer comprises a fifth organic compound comprising a halogen group or a cyano group or a second transition metal oxide,
wherein a first region that is thinner than the first layer is provided between the sixth layer and the first layer, and
wherein the first region overlaps with the space.

11. The display apparatus according to claim 10,
wherein the seventh layer comprises the first organic compound AM2, the second organic compound DM, and the third organic compound BM,
wherein a second region that is thinner than the second layer is provided between the seventh layer and the second layer, and
wherein the second region overlaps with the space.

12. The display apparatus according to claim 10,
wherein the fourth organic compound and the fifth organic compound are the same, and
wherein the first transition metal oxide and the second transition metal oxide are the same.

13. A display apparatus comprising the light-emitting device according to claim 2 and a transistor or a substrate.

14. An electronic device comprising the display apparatus according to claim 10 and a sensor, an operation button, a speaker, or a microphone.

15. A light-emitting apparatus comprising the light-emitting device according to claim 2 and a transistor or a substrate.

16. A lighting device comprising the light-emitting apparatus according to claim 15 and a housing.
